(19) United States
(12) Patent Application Publication
(10) Pub. No.: US 2025/0329352 A1
(43) Pub. Date: Oct. 23, 2025

(54) SEMICONDUCTOR DEVICE AND MEMORY DEVICE

(71) Applicant: Semiconductor Energy Laboratory Co., Ltd., Atsugi-shi, Kanagawa-ken (JP)

(72) Inventors: Yuki OKAMOTO, Ebina (JP); Takanori MATSUZAKI, Atsugi (JP); Tatsuya ONUKI, Atsugi (JP); Toshiki HAMADA, Isehara (JP)

(21) Appl. No.: 18/867,503

(22) PCT Filed: Jun. 5, 2023
(86) PCT No.: PCT/IB2023/055745

§ 371 Date: Nov. 20, 2024

(30) Foreign Application Priority Data
Jun. 16, 2022 (JP) 2022-097223
Sep. 22, 2022 (JP) 2022-151378

(51) Int. Cl. G11C 5/06; G11C 5/10

(52) U.S. Cl. CPC G11C 5/063; G11C 5/10

(57) ABSTRACT

A novel semiconductor device is provided. A first circuit is electrically connected to a second circuit through a first wiring; the first circuit is electrically connected to a fourth circuit through each of a third wiring and a fourth wiring; the second circuit is electrically connected to a third circuit through a fifth wiring; the first circuit has a function of establishing or breaking electrical continuity among the first wiring, a second wiring, the third wiring, and the fourth wiring; the third circuit has a function of retaining a potential corresponding to first data; the second circuit has a function of supplying the potential corresponding to the first data from the first wiring to the fifth wiring, a function of retaining a potential corresponding to second data, and a function of amplifying a change in a potential of the fifth wiring and outputting the amplified change to the first wiring; and the fourth circuit has a function of outputting the potential corresponding to the first data or the second data in accordance with a potential difference between the third wiring and the fourth wiring.

### TECHNICAL FIELD

One embodiment of the present invention relates to a semiconductor device and a memory device.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Thus, specific examples of the technical field of one embodiment of the present invention disclosed in this specification and the like include a semiconductor device, a display apparatus, a light-emitting apparatus, a power storage device, an optical device, an imaging device, a lighting device, an arithmetic device, a control device, a memory device, an input device, an output device, an input/output device, a signal processing device, an electronic computer, an electronic appliance, driving methods thereof, and manufacturing methods thereof.

### BACKGROUND ART

In recent years, semiconductor devices have been developed and mainly used in LSIs, CPUs, memories, and the like, for example. A CPU is an aggregation of semiconductor elements; the CPU includes a semiconductor integrated circuit formed into a chip by processing a semiconductor wafer, and is provided with an electrode that is a connection terminal.

For example, a semiconductor circuit (IC chip) of an LSI, a CPU, a memory, or the like is mounted on a circuit board (e.g., a printed wiring board) to be used as one of components of a variety of electronic devices.

A technique in which a transistor is formed using a semiconductor thin film formed over a substrate having an insulating surface has been attracting attention. The transistor is used in a wide range of electronic devices such as an integrated circuit (IC) and an image display apparatus (also simply referred to as a display apparatus). A silicon-based semiconductor material is widely known as a semiconductor thin film applicable to the transistor and furthermore, an oxide semiconductor has been attracting attention as another material.

It is known that a transistor including an oxide semiconductor has an extremely low leakage current in a non-conduction state. For example, Patent Document 1 discloses a low-power-consumption CPU utilizing a feature of a low leakage current of the transistor including an oxide semiconductor. Furthermore, for example, Patent Document 2 discloses a memory device that can retain stored contents for a long time by utilizing a feature of a low leakage current of the transistor including an oxide semiconductor.

In recent years, demand for an integrated circuit with higher density has risen with reductions in size and weight of electronic appliances. Furthermore, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1]M. Oota et. al, “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be highly integrated. Another object is to provide a semiconductor device whose manufacturing cost can be reduced. Another object is to provide a semiconductor device whose power consumption can be reduced. Another object is to provide a semiconductor device whose operation speed can be increased. Another object is to provide a semiconductor device that can be downsized. Another object is to provide a novel semiconductor device. Another object is to provide a memory device including any one or more of the semiconductor devices listed above.

Note that the description of these objects does not preclude the existence of other objects. In one embodiment of the present invention, there is no need to achieve all these objects. Other objects will be apparent from the description of this specification, the drawings, the claims, or the like, and other objects can be derived from the description of this specification, the drawings, the claims, or the like.

### Means for Solving the Problems

(1)

One embodiment of the present invention is a semiconductor device including a first circuit, a second circuit, a third circuit, a fourth circuit, a first wiring, a second wiring, a third wiring, a fourth wiring, and a fifth wiring; the first circuit is electrically connected to the second circuit through the first wiring; the first circuit is electrically connected to the fourth circuit through each of the third wiring and the fourth wiring; the second circuit is electrically connected to the third circuit through the fifth wiring; the first circuit has a function of establishing or breaking electrical continuity among the first wiring, the second wiring, the third wiring, and the fourth wiring; the third circuit has a function of retaining a potential corresponding to first data; the second circuit has a function of supplying the potential corresponding to the first data from the first wiring to the fifth wiring, a function of retaining a potential corresponding to second data, and a function of amplifying a change in a potential of the fifth wiring and outputting the amplified change to the first wiring; and the fourth circuit has a function of outputting the potential corresponding to the first data or the second data in accordance with a potential difference between the third wiring and the fourth wiring.

(2)

In (1) described above, the first circuit can include a first transistor, a second transistor, a third transistor, a fourth transistor, and a fifth transistor; the first transistor can have a function of establishing or breaking electrical continuity between the first wiring and the second wiring; the second transistor can have a function of establishing or breaking electrical continuity between the first wiring and the third wiring; the third transistor can have a function of establishing or breaking electrical continuity between the second wiring and the fourth wiring; the fourth transistor can have a function of precharging the first wiring; and the fifth transistor can have a function of precharging the second wiring.

(3)

In (1) described above, the first circuit can include a first transistor, a second transistor, a third transistor, a first capacitor, and a second capacitor; the first transistor can have a function of establishing or breaking electrical continuity between the first wiring and the second wiring; the second transistor can have a function of establishing or breaking electrical continuity between the first wiring and the third wiring; the third transistor can have a function of establishing or breaking electrical continuity between the second wiring and the fourth wiring; the first capacitor can have a function of changing a potential of the first wiring; and the second capacitor can have a function of changing a potential of the second wiring.

(4)

In (1) described above, the first circuit can include a first transistor, a second transistor, and a third transistor; the first transistor can have a function of establishing or breaking electrical continuity between the first wiring and the second wiring; the second transistor can have a function of establishing or breaking electrical continuity between the first wiring and the third wiring; the third transistor can have a function of establishing or breaking electrical continuity between the second wiring and the fourth wiring; the fourth circuit can include a sixth transistor and a seventh transistor; the sixth transistor can have a function of precharging the third wiring; and the seventh transistor can have a function of precharging the fourth wiring.

(5)

In any one of (1) to (4) described above, the fourth circuit can be provided in a substrate; the first circuit and the second circuit can be provided in a first layer placed over the substrate; the third circuit can be provided in each of a plurality of second layers placed over the substrate; the substrate can include a Si transistor; and each of the first layer and the plurality of second layers can include an OS transistor.

(6)

One embodiment of the present invention is a memory device including the semiconductor device according to (5) described above and a fifth circuit; the fifth circuit is provided in each of the plurality of second layers; and the fifth circuit has a function of outputting a signal that controls an operation of the third circuit.

### Effect of the Invention

With one embodiment of the present invention, a semiconductor device that can be highly integrated can be provided. A semiconductor device whose manufacturing cost can be reduced can be provided. A semiconductor device whose power consumption can be reduced can be provided. A semiconductor device whose operation speed can be increased can be provided. A semiconductor device that can be downsized can be provided. A novel semiconductor device can be provided. A memory device including any one or more of the semiconductor devices listed above can be provided.

Note that the description of these effects does not preclude the existence of other effects. One embodiment of the present invention does not have to have all these effects. Other effects will be apparent from the description of this specification, the drawings, the claims, or the like, and other effects can be derived from the description of this specification, the drawings, the claims, or the like.

### BRIEF DESCRIPTION OF THE DRAWINGS

FIG. 1 is a circuit diagram illustrating a structure example of a semiconductor device.

FIG. 2 is a schematic diagram illustrating a structure example of a semiconductor device.

FIG. 3A is a schematic diagram illustrating a structure example of a semiconductor device. FIG. 3B is a circuit diagram illustrating the structure example of the semiconductor device.

FIGS. 4A to 4D are circuit diagrams illustrating structure examples of a semiconductor device.

FIG. 5A and FIG. 5B are circuit diagrams illustrating a structure example of a semiconductor device.

FIG. 6 is a timing chart illustrating an operation example of a semiconductor device.

FIG. 7 is a timing chart illustrating an operation example of a semiconductor device.

FIG. 8 is a block diagram illustrating a structure example of a semiconductor device.

FIG. 9A and FIG. 9B are schematic diagrams illustrating a structure example of a semiconductor device.

FIG. 10 is a schematic diagram illustrating a structure example of an electronic computer.

FIG. 11A is a flow chart illustrating an operation example of an electronic computer. FIG. 11B and FIG. 11C are schematic diagrams illustrating operation examples of an electronic computer.

FIG. 12 is a circuit diagram illustrating a structure example of a semiconductor device.

FIG. 13 is a timing chart illustrating an operation example of a semiconductor device.

FIG. 14 is a timing chart illustrating an operation example of a semiconductor device.

FIG. 15 is a circuit diagram illustrating a structure example of a semiconductor device.

FIG. 16A and FIG. 16B are circuit diagrams illustrating a structure example of a semiconductor device.

FIG. 17 is a timing chart illustrating an operation example of a semiconductor device.

FIG. 18 is a timing chart illustrating an operation example of a semiconductor device.

FIG. 19A and FIG. 19B are schematic diagrams illustrating a structure example of a memory device.

FIG. 20A and FIG. 20B are schematic diagrams illustrating a structure example of a memory device.

FIG. 21A is a circuit diagram illustrating a structure example of a memory device. FIG. 21B is a timing chart illustrating an operation example of the memory device.

FIG. 22A to FIG. 22E are circuit diagrams each illustrating a structure example of a memory circuit.

FIG. 23A and FIG. 23B are planar layout views each illustrating a structure example of a memory device.

FIG. 24A is a top view illustrating an example of a semiconductor device. FIG. 24B to FIG. 24D are cross-sectional views illustrating the example of the semiconductor device.

FIG. 25A and FIG. 25B are schematic diagrams illustrating an example of a semiconductor device.

FIG. 26A and FIG. 26B are diagrams illustrating examples of electronic components.

FIG. 27A to FIG. 27E are schematic diagrams illustrating examples of a memory device.

FIG. 28A to FIG. 28H are diagrams illustrating examples of electronic appliances.

FIG. 29A and FIG. 29B are diagrams illustrating examples of electronic appliances.

FIG. 30 is a diagram illustrating an example of a device for space.

FIG. 31 is a diagram illustrating an example of a storage system that can be used in a data center.

FIG. 32 is a cross-sectional view illustrating an example of a semiconductor device.

FIG. 33 is a diagram illustrating transistor characteristics used to estimate an operation of a semiconductor chip.

FIG. 34 is a diagram illustrating transistor characteristics used to estimate an operation of a semiconductor chip.

FIG. 35 is a diagram illustrating transistor characteristics used to estimate an operation of a semiconductor chip.

### MODE FOR CARRYING OUT THE INVENTION

In this specification and the like, a semiconductor device refers to a device that utilizes semiconductor characteristics, and means a circuit including a semiconductor element (e.g., a transistor, a diode, or a photodiode) or a device including the circuit, for example. The semiconductor device also means all devices that can function by utilizing semiconductor characteristics. For example, an integrated circuit, a chip including an integrated circuit, and an electronic component including a chip in a package are examples of the semiconductor device. Moreover, for example, a memory device, a display apparatus, a light-emitting apparatus, a lighting device, an electronic device, and the like themselves may be semiconductor devices and may each include a semiconductor device.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit (e.g., a step-up circuit and a step-down circuit) or a level shifter circuit for changing the potential level of a signal); a voltage source; a current source; a switch circuit; an amplifier circuit (e.g., a circuit that can increase signal amplitude, the current amount, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, it can be expressed as “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit structure is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: the wiring and the electrode. Thus, electrical connection in this specification and the like includes, in its category, such a case where one conductive film has functions of a plurality of components.

In this specification and the like, as a “resistor”, a circuit element, a wiring, or the like having a resistance value higher than 0Ω can be used, for example. Accordingly, in this specification and the like, examples of the “resistor” include a wiring having a resistance value, a transistor in which a current flows between its source and drain, a diode, and a coil. Thus, the term “resistor” can be replaced with the terms “resistance”, “load”, “region having a resistance value”, or the like. Conversely, the terms “resistance”, “load”, and “region having a resistance value” can be replaced with the term “resistor”, or the like. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In the case where a wiring is used as a resistor, the resistance value of the resistor is sometimes determined depending on the length of the wiring. Alternatively, a conductor with resistivity different from that of a conductor used as a wiring is sometimes used as a resistor. Alternatively, in the case where a semiconductor is used as a resistor, the resistance value of the resistor is sometimes determined by doping a semiconductor with an impurity.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Thus, in this specification and the like, a “capacitor” is not limited to only a circuit element that has a pair of electrodes and a dielectric between the electrodes. A “capacitor” includes, for example, parasitic capacitance generated between wirings, gate capacitance generated between a gate and one of a source and a drain of a transistor, and the like. The term “capacitor”, “parasitic capacitance”, “gate capacitance”, or the like can be replaced with the term “capacitance” and the like, for example. Conversely, the term “capacitance” can be replaced with the term “capacitor”, “parasitic capacitance”, “gate capacitance”, or the like, for example. The term “a pair of electrodes” of a “capacitor” can be replaced with “a pair of conductors”, “a pair of conductive regions”, “a pair of regions”, or the like, for example. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

A transistor in this specification and the like has three terminals called a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. In the transistor, a current can flow through the channel formation region between the source and the drain. The channel formation region refers to a region through which a current mainly flows. The gate is a control terminal for controlling the amount of current flowing through the channel formation region between the source and the drain. Two terminals functioning as the source and the drain are input/output terminals of the transistor.

Note that one of the two input/output terminals serves as the source and the other serves as the drain depending on the conductivity type (n-channel type or p-channel type) of the transistor and the levels of potentials supplied to the three terminals of the transistor. In some cases, functions of the source and the drain are replaced with each other when the direction of current flow is changed in circuit operation, for example. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relationship of a transistor.

Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, each of the gates may be referred to as a first gate, a second gate, or a third gate, for example, in this specification and the like.

In this specification and the like, for example, a transistor with a multi-gate structure having two or more gate electrodes can be used as the transistor. In a transistor having the multi-gate structure, channel formation regions are connected in series; accordingly, a plurality of transistors are connected in series. Thus, in the transistor having the multi-gate structure, the amount of off-state current can be reduced, and the withstand voltage of the transistor can be increased (the reliability can be improved). Alternatively, in the transistor having the multi-gate structure, a drain-source current does not change very much even if a drain-source voltage changes at the time of operation in a saturation region, so that a flat slope of voltage-current characteristics can be obtained. The transistor having the flat slope of the voltage-current characteristics enables an ideal current source circuit or an active load having an extremely high resistance value. As a result, the transistor having the flat slope of the voltage-current characteristics enables, for example, a differential circuit, a current mirror circuit, or the like having high characteristics.

In this specification and the like, the case where a single circuit element is illustrated in a circuit diagram may indicate a case where the circuit element includes a plurality of circuit elements. For example, the case where a single resistor is illustrated in a circuit diagram may indicate a case where two or more resistors are electrically connected to each other in series. As another example, the case where a single capacitor is illustrated in a circuit diagram may indicate a case where two or more capacitors are electrically connected to each other in parallel. As another example, the case where a single transistor is illustrated in a circuit diagram may indicate a case where two or more transistors are electrically connected to each other in series and their gates are electrically connected to each other. Similarly, as another example, the case where a single switch is illustrated in a circuit diagram may indicate a case where the switch includes two or more transistors which are electrically connected to each other in series or in parallel and whose gates are electrically connected to each other.

In this specification and the like, a “node” can be referred to as a “terminal”, a “wiring”, an “electrode”, a “conductive layer”, a “conductor”, an “impurity region”, or the like depending on the circuit structure, the device structure, or the like, for example. Furthermore, a “terminal”, a “wiring”, or the like can be referred to as a “node”, for example.

In this specification and the like, “voltage” and “potential” can be replaced with each other as appropriate. The term “voltage” refers to a potential difference from a reference potential. When the reference potential is a ground potential, for example, “voltage” can be replaced with “potential”. Note that the ground potential does not necessarily mean 0 V. Moreover, potentials are relative values. That is, a potential supplied to a wiring, a potential applied to a circuit and the like, or a potential output from a circuit and the like, are changed with a change of the reference potential.

In this specification and the like, the terms “high-level potential” (also referred to as “H potential” or “H”) and “low-level potential” (also referred to as “L potential” or “L”) do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

In this specification and the like, “current” means a charge transfer (electrical conduction). For example, the description “electrical conduction of positively charged particles occurs” can be rephrased as “electrical conduction of negatively charged particles occurs in the opposite direction”. Thus, unless otherwise specified, “current” in this specification and the like refers to a charge transfer phenomenon (electrical conduction) accompanied by carrier movement. Examples of a carrier here include an electron, a hole, an anion, a cation, and a complex ion. The type of carrier differs depending on current-flowing systems (e.g., a semiconductor, a metal, an electrolyte solution, or a vacuum). For example, the “direction of current” in a wiring or the like refers to the direction in which a positive carrier moves, and the amount of current is expressed as a positive value. In other words, the direction in which a negative carrier moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A” and the like, for example. The description “current is input to element A” and the like can be rephrased as “current is output from element A” and the like, for example.

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, or the like. Furthermore, for example, a “first” component in one embodiment in this specification and the like can be omitted in other embodiments, the scope of claims, or the like.

In this specification and the like, for example, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the terms for describing arrangement in this specification and the like are not limited to those and can be replaced with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180 degrees. Moreover, the expression “an insulator located over (on) a top surface of a conductor” can be replaced with the expression “an insulator located on a left surface (or a right surface) of a conductor” when the direction of a drawing illustrating these components is rotated by 90 degrees.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, components arranged in a matrix and their positional relationship are sometimes described using a term such as “row” or “column”, for example. The positional relationship between components is changed as appropriate in accordance with a direction in which each component is described. Thus, for example, the terms such as “row” and “column” are not limited to those described in this specification and the like and can be replaced with another term as appropriate depending on the situation. For example, the term “row direction” can be replaced with the term “column direction” when the direction of the diagram is rotated by 90 degrees.

Furthermore, the term “overlap”, for example, in this specification and the like does not limit a state such as the stacking order of components. For example, the expression “electrode B overlapping with insulating layer A” does not necessarily mean the state where the electrode B is formed over the insulating layer A. The expression “electrode B overlapping with insulating layer A”, for example, does not exclude the state where the electrode B is formed under the insulating layer A and the state where the electrode B is formed on the right side (or the left side) of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is placed between the insulating layer A and the electrode B.

In this specification and the like, the term “film”, “layer”, or the like can be, for example, interchanged with each other depending on the situation, in some cases. For example, the term “conductive layer” can be changed into the term “conductive film” in some cases. For another example, the term “insulating film” can be changed into the term “insulating layer” in some cases. Alternatively, for example, the term “film”, “layer”, or the like is not used and can be interchanged with another term depending on the situation, in some cases. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In addition, in this specification and the like, for example, the term such as “electrode”, “wiring”, or “terminal” does not limit the function of a component. For example, an “electrode” is used as part of a wiring in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Thus, for example, an “electrode” can be part of a “wiring” or a “terminal”. Furthermore, a “terminal” can be part of a “wiring” or an “electrode”. Moreover, the term “electrode”, “wiring”, “terminal”, or the like is sometimes replaced with the term “region”, for example.

In addition, in this specification and the like, for example, the terms such as “wiring”, “signal line”, and “power supply line” can be interchanged with each other depending on the situation, in some cases. For example, the term “wiring” can be changed into the term “signal line” in some cases. For another example, the term “wiring” can be changed into the term “power supply line” or the like in some cases. Conversely, for example, the term “signal line”, “power supply line”, or the like can be changed into the term “wiring” in some cases. Furthermore, for example, the term “power supply line” or the like can be changed into the term “signal line” or the like in some cases. Conversely, for example, the term “signal line” or the like can be changed into the term “power supply line” or the like in some cases. Moreover, the term “potential” that is applied to a wiring can be changed into the term “signal” or the like depending on the situation, for example. Conversely, for example, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether a current flows therethrough or not. Alternatively, a switch has a function of selecting and changing a current path. For example, an electrical switch or a mechanical switch can be used as the switch. That is, a switch can be any element capable of controlling a current, and is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact” in some cases.

Examples of an electrical switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case of using a transistor as a switch, a “conducting state” or “on state” of the transistor refers to a state where a source electrode and a drain electrode of the transistor can be regarded as being electrically short-circuited or a state where a current can be made to flow between the source electrode and the drain electrode. Furthermore, a “non-conduction state” or “off state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically, and selects a conduction or non-conduction state with the movement of the electrode.

In this specification and the like, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

Note that in this specification and the like, the expression “level or substantially level” indicates having the same level from a reference surface (e.g., a flat surface such as a substrate surface) in a cross-sectional view. For example, in a manufacturing process of the semiconductor device, planarization treatment (typically, CMP treatment) causes exposure of the surface(s) of a single layer or a plurality of layers in some cases. In this case, the surfaces on which the CMP treatment has been performed are at the same level as a reference surface. Note that a plurality of layers having the surfaces on which the CMP treatment has been performed are not level with each other in the strict sense in some cases, depending on a treatment apparatus, a treatment method, or a material of the treated surfaces on which the CMP treatment is performed. This case is also regarded as being “level or substantially level” in this specification and the like. For example, the expression “level or substantially level” also includes the case where two layers (here, given as a first layer and a second layer) whose levels with respect to the reference surface are different from each other are provided to have a difference between the top-surface level of the first layer and the top-surface level of the second layer of less than or equal to 20 nm.

Note that in this specification and the like, the expression “end portions are aligned or substantially aligned” means that at least outlines of stacked layers partly overlap with each other in a top view. For example, the case of processing the upper layer and the lower layer with use of the same mask pattern or mask patterns that are partly the same in a manufacturing process of a semiconductor device is included. However, in some cases, the outlines do not exactly overlap with each other and the outline of the upper layer is located inside the outline of the lower layer or the outline of the upper layer is located outside the outline of the lower layer; such a case is also represented by the expression “end portions are aligned or substantially aligned” in this specification and the like.

Note that in this specification and the like, for example, the terms “identical”, “the same”, “equal”, “uniform”, and the like (including synonyms of these words) used in describing calculation values and measurement values or in describing objects, methods, events, and the like that can be converted into calculation values or measurement values, allow for a margin of error of ±20% unless otherwise specified.

In this specification and the like, an impurity in a semiconductor refers to, for example, an element other than a main component of a semiconductor layer. For example, an element with a concentration of lower than 0.1 atomic % is an impurity. When an impurity is contained in a semiconductor, for example, the density of defect states in a semiconductor is increased, carrier mobility is decreased, or crystallinity is decreased in some cases. In the case where the semiconductor is an oxide semiconductor, examples of an impurity that changes the characteristics of the semiconductor include Group 1 elements, Group 2 elements, Group 13 elements, Group 14 elements, Group 15 elements, or transition metals other than the main components of the oxide semiconductor. Specific examples include hydrogen (included also in water), lithium, sodium, silicon, boron, phosphorus, carbon, and nitrogen. In addition, oxygen vacancies (also referred to as Vo) are formed in an oxide semiconductor in some cases by entry of impurities, for example. Moreover, in the case where the semiconductor is a silicon layer, examples of an impurity which changes characteristics of the semiconductor include oxygen, Group 1 elements except hydrogen, Group 2 elements, Group 13 elements, and Group 15 elements.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like, for example. For example, in the case where a metal oxide is used in a semiconductor layer of a transistor, the metal oxide is referred to as an oxide semiconductor in some cases. That is, when a metal oxide is used as a material that can be used for a channel formation region of a transistor that has at least one of an amplifying function, a rectifying function, and a switching function, the metal oxide can be referred to as a metal oxide semiconductor. In addition, the term “OS transistor” can also be referred to as a transistor containing a metal oxide or an oxide semiconductor.

In this specification and the like, a metal oxide containing nitrogen is also collectively referred to as a metal oxide in some cases. A metal oxide containing nitrogen may be referred to as a metal oxynitride.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined with each other as appropriate.

Embodiments described in this specification are described with reference to the drawings. Note that the embodiments can be implemented in many different modes. Thus, it will be readily understood by those skilled in the art that the modes and details can be changed in various ways without departing from the spirit and scope thereof. Therefore, the present invention should not be interpreted as being limited to the description in the embodiments. As for the drawings illustrating the embodiments, in the structures of the invention, the same reference numerals are used in common for the same portions or portions having similar functions in different drawings, and repeated description thereof is omitted in some cases. Furthermore, the same hatching pattern is used for the portions having similar functions throughout the drawings, and the portions are not especially denoted by reference numerals in some cases. Moreover, some components are omitted in a perspective view, a top view (also referred to as a “plan view”), and the like for easy understanding of the drawings in some cases. In the drawings, some hidden lines are omitted in some cases. In the drawings, for example, a hatching pattern or the like is omitted in some cases.

In addition, in the drawings and the like in this specification, the size, the layer thickness, or the region is exaggerated for clarity in some cases. Thus, the drawings are not necessarily limited to the drawings with the illustrated size, aspect ratio, and the like, for example. Note that the drawings schematically illustrate ideal examples, and embodiments of the present invention are not limited to shapes, values, and the like illustrated in the drawings, for example.

For example, the drawings and the like in this specification can include variation in signal, voltage, or current due to noise or variation in signal, voltage, or current due to difference in timing.

For example, in the actual manufacturing process, a layer, a resist mask, or the like might be unintentionally reduced in size by treatment such as etching, which might not be reflected in the drawings and the like in this specification for easy understanding.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numeral, and in particular need to be distinguished from each other, an identification sign such as “A”, “b”, “_1”, “[n]”, or “[m, n]” is sometimes added to the reference numeral, for example.

### Embodiment 1

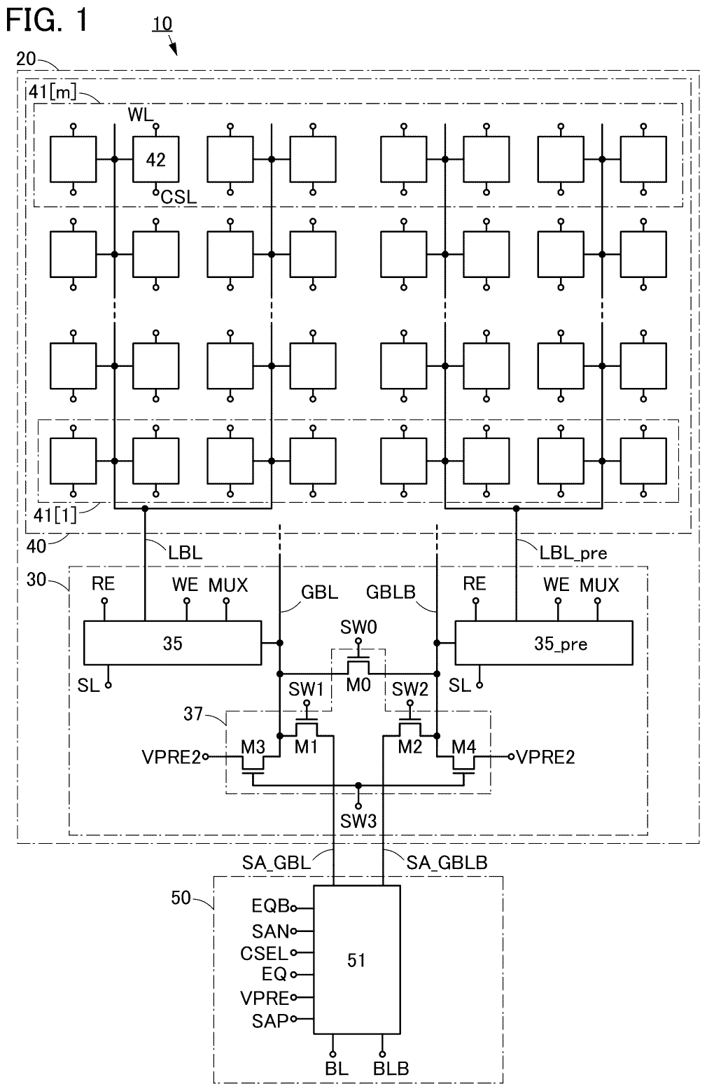

Structure examples of a semiconductor device according to one embodiment of the present invention are described with reference to FIG. 1 to FIG. 5.

Note that a semiconductor device refers to a device that utilizes semiconductor characteristics, and means a circuit including a semiconductor element (e.g., a transistor, a diode, or a photodiode) or a device including such a circuit. The semiconductor device described in this embodiment or the like can favorably function as a memory device, for example. For example, the semiconductor device can be favorably used as an electronic computer including the memory device.

### Structure Example of Semiconductor Device

FIG. 1 is a circuit diagram illustrating a structure example of a semiconductor device 10 according to one embodiment of the present invention.

The semiconductor device 10 includes a substrate 50 and a layer 20. As the substrate 50, an insulating substrate or a semiconductor substrate containing any of a variety of materials can be used. As the substrate 50, a substrate containing silicon can be used, for example. For example, the substrate 50 can include a transistor including silicon in a channel formation region (a Si transistor). The layer 20 includes a variety of materials such as a conductor, a semiconductor, and an insulator, for example, and includes a variety of elements such as a capacitor and a transistor. For example, the layer 20 can include a transistor including an oxide semiconductor in a channel formation region (an OS transistor).

The layer 20 includes a layer 30 and a layer 40. The layer 40 includes layers 41[1] to 41[m]. Note that m is an integer greater than or equal to 2.

The layer 40 includes a plurality of memory cells 42 in each of the layer 41[1] to the layer 41[m]. Each of the plurality of memory cells 42 is electrically connected to a local bit line LBL. The memory cell 42 has a function of storing data by retaining a potential corresponding to the data. Data can be written to or read from the memory cell 42 through the local bit line LBL.

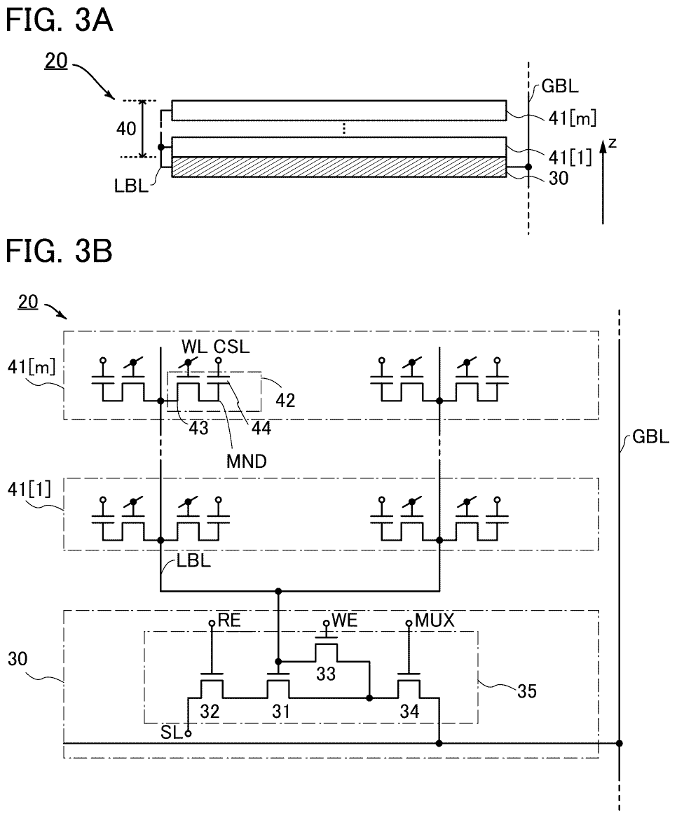

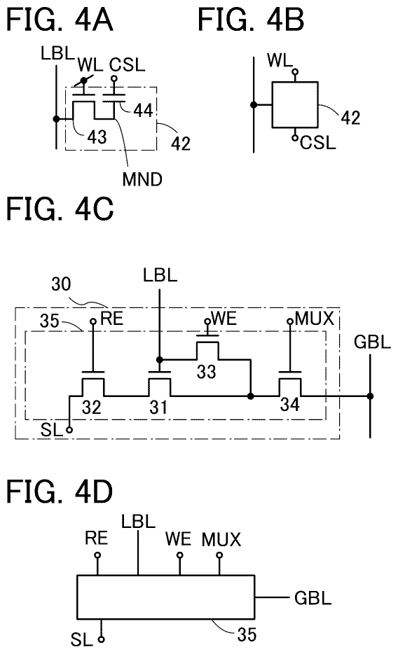

The memory cell 42 includes one transistor and one capacitor (see FIG. 3B and FIG. 4A). One of a source and a drain of the transistor is electrically connected to one terminal of the capacitor. In the memory cell 42, a transistor having an extremely low off-state current is preferably used as the transistor. An OS transistor can be used as the transistor, for example. A memory cell structure using such an OS transistor can be referred to as a DOSRAM (registered trademark). The DOSRAM is an abbreviation for a Dynamic Oxide Semiconductor RAM (Random Access Memory). When an OS transistor having an extremely low off-state current is used in the DOSRAM, data can be stored for a long time. A DOSRAM can be formed using one OS transistor and one capacitor, so that high density of memory cells can be achieved.

In an OS transistor, an oxide semiconductor where a channel is formed has a band gap of 2 eV or more; thus, the OS transistor has a feature of an extremely low off-state current (current flowing between a source and a drain when the transistor is in an off state). The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of the OS transistor is lower than that of the Si transistor by approximately ten orders of magnitude.

A semiconductor layer of the OS transistor preferably includes at least one of indium and zinc. The semiconductor layer of the OS transistor preferably includes indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin.

It is particularly preferable to use an oxide containing indium (In), gallium (Ga), and zinc (Zn) (also referred to as “IGZO”) for the semiconductor layer. Alternatively, an oxide containing indium (In), aluminum (Al), and zinc (Zn) (also referred to as “IAZO”) may be used for the semiconductor layer. Further alternatively, an oxide containing indium (In), aluminum (Al), gallium (Ga), and zinc (Zn) (also referred to as “IAGZO”) may be used for the semiconductor layer.

When the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. The atomic ratio of In may be smaller than the atomic ratio of M in the In-M-Zn oxide. Examples of the atomic ratio of the metal elements in such an In-M-Zn oxide include In:M:Zn=1:3:2 or a composition in the neighborhood thereof and In:M:Zn=1:3:4 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where the content ratio of each element is as follows: Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where the content ratio of each element is as follows: Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where the content ratio of each element is as follows: Ga is greater than 0.1 and less than or equal to 2 and Zn is greater than 0.1 and less than or equal to 2 with In being 1.

Since the OS transistor has an extremely low off-state current in the memory cell using the OS transistor, charge accumulated in the capacitor included in the memory cell can be retained for a long time. Thus, when a potential corresponding to the amount of charge retained in the capacitor is used as data in the memory cell, the data can be kept stored for a long period. That is, in the memory cell, data once written can be stored for a long period, and thus the frequency of data refresh can be decreased. With the memory cell, therefore, power consumption of the semiconductor device or the memory device using the memory cell can be reduced.

In addition, data writing to the memory cell using the OS transistor and data reading therefrom are performed by charging or discharging of charge; thus, a substantially unlimited number of times of data writing or data reading are possible. Unlike a magnetic memory, a resistive random access memory, or the like, the memory cell using the OS transistor has no structure change at the atomic level and thus exhibits high rewrite endurance. Furthermore, unlike in a flash memory, unstableness due to an increase in electron trap centers is not observed in the memory cell using the OS transistor even when writing is repeated; thus, the memory cell using the OS transistor is excellent in stability.

The memory cell using the OS transistor can be freely placed over a silicon substrate or the like where a Si transistor is provided, for example; thus, integration can be easily achieved. Furthermore, the OS transistor used in the memory cell can be fabricated with a manufacturing apparatus similar to that for the Si transistor and thus can be fabricated at low cost.

The OS transistor can be a four-terminal semiconductor element including a back gate (back gate electrode) in addition to a gate (gate electrode), a source (source electrode), and a drain (drain electrode). A current flowing between the source and the drain in the four-terminal OS transistor can be independently controlled in accordance with potentials supplied to the gate and the back gate. Furthermore, the OS transistor has electrical characteristics superior to those of a Si transistor in a high-temperature environment. Specifically, the ratio between an on-state current and an off-state current of the OS transistor is large even at a high temperature higher than or equal to 125° C. and lower than or equal to 150° C.; thus, a favorable switching operation can be performed.

The layer 30 includes a sensing circuit 35, a sensing circuit 35_pre, and a switching circuit 37.

The sensing circuit 35 is electrically connected to the plurality of memory cells 42 included in the layer 40 through the local bit line LBL. The sensing circuit 35 is electrically connected to the switching circuit 37 through a global bit line GBL. The sensing circuit 35 has, in the case where data is written to the memory cell 42, a function of supplying a potential corresponding to the data from the global bit line GBL to the local bit line LBL. The sensing circuit 35 has, in the case where data is read from the memory cell 42, a function of amplifying a change in the potential of the local bit line LBL and outputting the amplified change to the global bit line GBL. Note that the sensing circuit 35 can be formed using an OS transistor.

Although not illustrated, the layer 30 includes a plurality of sensing circuits 35. The global bit line GBL is electrically connected to each of a plurality of the local bit lines LBL through a corresponding one of the plurality of sensing circuits 35. The semiconductor device 10 has a function of selecting any one of the plurality of sensing circuits 35 and writing or reading data to/from one memory cell 42 selected from the plurality of memory cells 42 electrically connected to the selected sensing circuit 35.

The threshold voltage of the transistor included in the sensing circuit 35 may vary among the plurality of sensing circuits 35. In particular, the variation in the threshold voltage of the transistor having a function of converting a slight potential change of the local bit line LBL into a current greatly affects the operation of the sensing circuit 35. When such a variation affects the operation of the sensing circuit 35, data from the memory cell 42 might not be properly read in the semiconductor device 10. The sensing circuit 35 may have a function of performing correction so as to reduce the influence of the variation in the threshold voltage on data reading. With such a correction function, the semiconductor device 10 can improve the reliability of the read data.

The sensing circuit 35_pre has a structure similar to that of the sensing circuit 35. Therefore, for the description of the sensing circuit 35_pre, the above description of the sensing circuit 35 can be referred to as appropriate by replacing the global bit line GBL with a global bit line GBLB and replacing the local bit line LBL with a local bit line LBL_pre.

The sensing circuit 35, the global bit line GBL, the local bit line LBL, and the plurality of memory cells 42 electrically connected to the local bit line LBL pair off with the sensing circuit 35_pre, the global bit line GBLB, the local bit line LBL_pre, and the plurality of memory cells 42 electrically connected to the local bit line LBL_pre.

The memory cells 42 connected to the local bit line LBL are memory cells to/from which data is written or read. The memory cells 42 connected to the local bit line LBL_pre are memory cells to/from which data is not written or read. The local bit line LBL_pre is precharged to a predetermined potential and keeps retaining the potential. Note that the memory cells 42 connected to the local bit line LBL_pre may be memory cells to/from which data is written or read, and the memory cells 42 connected to the local bit line LBL may be memory cells to/from which data is not written or read. In this case, the local bit line LBL is precharged to a predetermined potential and keeps retaining the potential.

The switching circuit 37 is electrically connected to the sensing circuit 35 through the global bit line GBL. The switching circuit 37 is electrically connected to the sensing circuit 35_pre through the global bit line GBLB. The switching circuit 37 is electrically connected to a driver circuit 51 included in the substrate 50 through each of a global bit line SA_GBL and a global bit line SA_GBLB. The switching circuit 37 has a function of establishing or breaking electrical continuity among the global bit line GBL, the global bit line GBLB, the global bit line SA_GBL, and the global bit line SA_GBLB. The switching circuit 37 has a function of precharging each of the global bit line GBL and the global bit line GBLB to a predetermined potential.

The switching circuit 37 includes a transistor M0, a transistor M1, a transistor M2, a transistor M3, and a transistor M4. Note that as the transistors included in the switching circuit 37, transistors with extremely low off-state currents are preferably used. For example, OS transistors can be used as the transistors included in the switching circuit 37.

One of a source and a drain of the transistor M0 is electrically connected to the global bit line GBL. The other of the source and the drain of the transistor M0 is electrically connected to the global bit line GBLB. The transistor M0 has a function of establishing or breaking electrical continuity between the global bit line GBL and the global bit line GBLB in accordance with a signal SW0.

One of a source and a drain of the transistor M1 is electrically connected to the global bit line GBL. The other of the source and the drain of the transistor M1 is electrically connected to the global bit line SA_GBL. The transistor M1 has a function of establishing or breaking electrical continuity between the global bit line GBL and the global bit line SA_GBL in accordance with a signal SW1.

One of a source and a drain of the transistor M2 is electrically connected to the global bit line GBLB. The other of the source and the drain of the transistor M2 is electrically connected to the global bit line SA_GBLB. The transistor M2 has a function of establishing or breaking electrical continuity between the global bit line GBLB and the global bit line SA_GBLB in accordance with a signal SW2.

One of a source and a drain of the transistor M3 is electrically connected to the global bit line GBL. The other of the source and the drain of the transistor M3 is electrically connected to a terminal to which a potential VPRE2 is supplied. The transistor M3 has a function of precharging the global bit line GBL to the potential VPRE2 in accordance with a signal SW3.

One of a source and a drain of the transistor M4 is electrically connected to the global bit line GBLB. The other of the source and the drain of the transistor M4 is electrically connected to a terminal to which the potential VPRE2 is supplied. The transistor M4 has a function of precharging the global bit line GBLB to the potential VPRE2 in accordance with the signal SW3.

The substrate 50 includes the driver circuit 51.

The driver circuit 51 is electrically connected to the switching circuit 37 included in the layer 30 through each of the global bit line SA_GBL and the global bit line SA_GBLB. The driver circuit 51 has, in the case of writing data, a function of supplying a potential corresponding to the data to each of the global bit line SA_GBL and the global bit line SA_GBLB. The driver circuit 51 has, in the case of reading data, a function of outputting a potential corresponding to the data in accordance with a potential difference between the global bit line SA_GBL and the global bit line SA_GBLB. The driver circuit 51 can be formed using a Si transistor whose channel is formed in the substrate 50.

The Si transistor has higher operation speed than the OS transistor. By electrically connecting a gate of an n-channel Si transistor and a gate of a p-channel Si transistor, a CMOS circuit (e.g., a circuit that operates complementarily, a CMOS logic gate, a CMOS logic circuit, or the like) can be formed. Thus, when the driver circuit 51 included in the substrate 50 is formed using Si transistors, operation speed can be increased and power consumption in a steady state can be reduced.

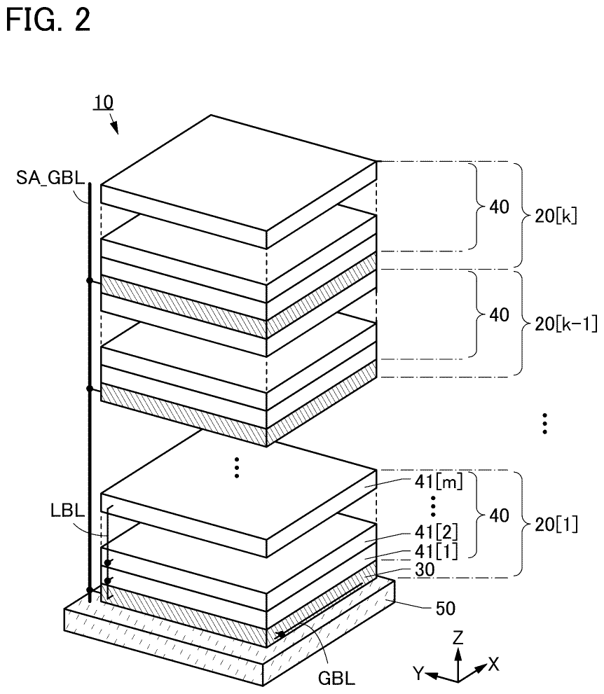

FIG. 2 is a schematic diagram illustrating a structure example of the semiconductor device 10 of one embodiment of the present invention.

As illustrated in FIG. 2, the semiconductor device 10 includes the substrate 50 and one or a plurality of the layers 20 (layers 20[1] to 20[k]). Note that k is an integer greater than or equal to 2. As the substrate 50, an insulating substrate or a semiconductor substrate including a variety of materials can be used. For example, as the substrate 50, a substrate including silicon can be used. Each of the layer 20[1] to the layer 20[k] can include a variety of materials such as a conductor, a semiconductor, and an insulator, for example. Each of the layer 20[1] to the layer 20[k] can be provided with a variety of elements such as a capacitor and a transistor, for example.

Note that in the schematic diagram illustrated in FIG. 2, the X direction, the Y direction, and the Z direction are defined to describe the arrangement of the layers included in the semiconductor device 10. The Z direction refers to a direction perpendicular or substantially perpendicular to the plane of the substrate 50. “Substantially perpendicular” indicates a state where the angle formed by two targeted elements is greater than or equal to 85 degrees and less than or equal to 95 degrees. In this embodiment and the like, the Z direction is sometimes referred to as a perpendicular direction for easy understanding. Note that the plane of the substrate 50 corresponds to a plane formed in the X direction, which is defined as the direction perpendicular or substantially perpendicular to the Z direction, and the Y direction, which is defined as the direction perpendicular or substantially perpendicular to both the X direction and the Z direction. In this embodiment and the like, for easy understanding, the X direction is referred to as the depth direction and the Y direction is referred to as the horizontal direction in some cases.

The layers 20[1] to 20[k] can be placed to be stacked in the perpendicular direction (the Z direction) over the substrate 50. Each of the layers 20[1] to 20[k] includes the layer 30 and the layer 40.

As illustrated in FIG. 2, the layer 41[1] to the layer 41[m] included in the layer 40 can be provided to be stacked in the perpendicular direction. Thus, the semiconductor device 10 of one embodiment of the present invention can improve the density (memory density) of the plurality of memory cells 42. The layer 41[1] to the layer 41[m] can be formed in the perpendicular direction by employing the same manufacturing process repeatedly. Thus, the semiconductor device 10 of one embodiment of the present invention can reduce the manufacturing cost of the plurality of memory cells 42.

As illustrated in FIG. 2, the layer 30 and the layer 40 (the layer 41[1] to the layer 41[m]) can be placed to be stacked in the perpendicular direction over the substrate 50. Thus, in the semiconductor device 10 of one embodiment of the present invention, the lengths of wirings such as the local bit line LBL and the global bit line SA_GBL can be shortened, for example. That is, in the semiconductor device 10 of one embodiment of the present invention, the signal transmission distance between two circuits connected with the wirings is shortened, whereby the parasitic resistance and the parasitic capacitance of the wirings can be reduced. Thus, the semiconductor device 10 of one embodiment of the present invention can achieve a reduction in power consumption and a reduction in signal delay.

Furthermore, a reduction in the parasitic capacitance of the local bit line LBL in the semiconductor device 10 of one embodiment of the present invention enables an operation even when the electrostatic capacitance of the capacitor included in the memory cell 42 is reduced. Therefore, the area occupied by the memory cell 42 can be reduced. Thus, the semiconductor device 10 of one embodiment of the present invention can be downsized.

Furthermore, the semiconductor device 10 of one embodiment of the present invention can amplify a slight change in the potential of the local bit line LBL by including the sensing circuit 35 in the layer 30. Thus, a sense amplifier 55 included in the substrate 50 can be downsized. Therefore, the semiconductor device 10 of one embodiment of the present invention can be downsized.

In the semiconductor device 10 of one embodiment of the present invention, OS transistors with extremely low off-state currents can be used as the transistors provided in the layer 30 and the layer 40. Thus, the memory cell 42 can reduce the frequency of refresh of stored data. Therefore, power consumption of the semiconductor device 10 of one embodiment of the present invention can be reduced. In the semiconductor device 10 of one embodiment of the present invention, the layer 41[1] to the layer 41[m] where the OS transistors are provided can be provided to be stacked in the perpendicular direction. Thus, the layer 41[1] to the layer 41[m] can be formed by employing the same manufacturing process repeatedly. Thus, the manufacturing cost of the semiconductor device 10 of one embodiment of the present invention can be reduced. In the semiconductor device 10 of one embodiment of the present invention, the layer 41[1] to the layer 41[m] where the memory cells 42 are provided can be stacked in the perpendicular direction. Thus, the memory density of the plurality of memory cells 42 can be increased. Therefore, the semiconductor device 10 of one embodiment of the present invention can be downsized. In the semiconductor device 10 of one embodiment of the present invention, an OS transistor with a smaller variation in electrical characteristics than a Si transistor can be used even under a high-temperature environment. Thus, the semiconductor device 10 of one embodiment of the present invention can be excellent in reliability.

FIG. 3A is a schematic diagram of the layer 20 corresponding to any one of the layer to the layer 20[k] illustrated in FIG. 2.

The layer 20 illustrated in FIG. 3A includes the layer 41[1] to the layer 41[m] in which the memory cells 42 are provided in the perpendicular direction (the Z direction) over the layer 30. With this structure, the distance between the layers, that is, the layer 30 and the layer 41[1] to the layer 41[m], can be short. Accordingly, the length of the local bit line LBL can be shortened, so that the parasitic capacitance can be reduced. The layer 41[1] to the layer 41[m] are formed in the perpendicular direction by employing the same manufacturing process repeatedly, which can reduce the manufacturing cost.

FIG. 3B is a diagram that illustrates the components of the layer 20 illustrated in FIG. 3A using circuit symbols.

Each of the layer 41[1] to the layer 41[m] includes the plurality of memory cells 42. The memory cell 42 includes a transistor 43 and a capacitor 44. One of a source and a drain of the transistor 43 is electrically connected to one terminal (electrode) of the capacitor 44. The other of the source and the drain of the transistor 43 is electrically connected to the local bit line LBL. A gate of the transistor 43 is electrically connected to a word line WL. The other terminal (electrode) of the capacitor 44 is electrically connected to a wiring CSL to which a given fixed potential is supplied. Note that a region where the one of the source and the drain of the transistor 43 and the one terminal of the capacitor 44 are electrically connected to each other is referred to as a node MND in some cases. The transistor 43 has a function of establishing or breaking electrical continuity between the local bit line LBL and the node MND in accordance with a potential supplied to the word line WL.

It is preferable to use a transistor having an extremely low off-state current as the transistor 43. For example, an OS transistor can be used as the transistor 43. The capacitor 44 has a structure in which an insulator is sandwiched between conductors serving as electrodes. As the conductors forming the electrodes, a semiconductor layer or the like to which conductivity is imparted as well as metal can be used, for example. As the structure of the capacitor 44, a structure in which the capacitor 44 is placed above or below the transistor 43 so as to overlap with the transistor 43 and a structure in which part of a semiconductor layer, an electrode, or the like included in the transistor 43 is used as the one electrode of the capacitor 44 can be given, for example.

When the transistor 43 is brought into a non-conduction state, the memory cell 42 can retain charge accumulated in the capacitor 44 for a long period. The memory cell 42 can store binary data when the potential of the node MND corresponding to the amount of charge retained in the capacitor 44 is made to correspond to “1” or “0”, for example. In the case where data is written to the memory cell 42, the transistor 43 is brought into a conduction state, so that a potential corresponding to data can be supplied from the local bit line LBL to the node MND. In the case where data is read from the memory cell 42, the transistor 43 is brought into a conduction state, so that charge retained in the node MND can be extracted to the local bit line LBL.

Note that reading of data from the memory cell 42 means extraction of the charge retained in the node MND to the local bit line LBL and thus changes the potential of the node MND. In other words, by reading data from the memory cell 42, stored data is destructed. That is, reading of data from the memory cell 42 is destructive reading. Therefore, the memory cell 42 needs writing back (refresh) of data after data reading.

The layer 30 includes the sensing circuit 35. The sensing circuit 35 includes a transistor 31, a transistor 32, a transistor 33, and a transistor 34. One of a source and a drain of the transistor 31 is electrically connected to one of a source and a drain of the transistor 33 and one of a source and a drain of the transistor 34. The other of the source and the drain of the transistor 31 is electrically connected to one of a source and a drain of the transistor 32. A gate of the transistor 31 is electrically connected to the other of the source and the drain of the transistor 33 and the local bit line LBL. The other of the source and the drain of the transistor 32 is electrically connected to a wiring SL. The other of the source and the drain of the transistor 34 is electrically connected to the global bit line GBL. The transistor 31 has a function of flowing a current between the source and the drain in accordance with the potential of the local bit line LBL. The transistor 32 has a function of establishing or breaking electrical continuity between the source and the drain in accordance with a signal RE supplied to the gate. The transistor 33 has a function of establishing or breaking electrical continuity between the source and the drain in accordance with a signal WE supplied to the gate. The transistor 34 has a function of establishing or breaking electrical continuity between the source and the drain in accordance with a signal MUX supplied to the gate.

As each of the transistor 31 to the transistor 34, a transistor with an extremely low off-state current is preferably used. For example, an OS transistor can be used as each of the transistor 31 to the transistor 34.

The sensing circuit 35 has a function of changing the potential of the global bit line GBL by supplying a current corresponding to the potential of the local bit line LBL from the global bit line GBL through the transistor 34, the transistor 31, and the transistor 32 to the wiring SL. In addition, the sensing circuit 35 has a function of transmitting the potential of the global bit line GBL through the transistor 34 and the transistor 33 to the local bit line LBL. Furthermore, the sensing circuit 35 has a function of changing the potential of the gate of the transistor 31 to a potential corresponding to the threshold voltage of the transistor 31 by discharging charge accumulated in the gate of the transistor 31 through the transistor 33, the transistor 31, and the transistor 32 to the wiring SL. With this function, the sensing circuit 35 can perform correction so as to reduce the influence of the threshold voltage of the transistor 31.

Note that the sensing circuit 35 may include a capacitor. In this case, it is preferable that one terminal of the capacitor be electrically connected to the local bit line LBL and the other terminal of the capacitor be electrically connected to a wiring to which a given fixed potential is supplied.

When an OS transistor with an extremely low off-state current is used as the transistor 33 in the sensing circuit 35, charge accumulated in the local bit line LBL can be retained for a long period while the transistor 33 is in the non-conduction state. Thus, the sensing circuit 35 can store binary data when a potential corresponding to the amount of charge retained in the local bit line LBL is made to correspond to “1” or “0”, for example. That is, the sensing circuit 35 can have a function of a memory. In the case where the sensing circuit 35 functioning as a memory writes data to the local bit line LBL, the transistor 33 is brought into a conduction state, whereby a potential corresponding to data can be supplied from the global bit line GBL to the local bit line LBL. In the case where the sensing circuit 35 functioning as a memory reads data stored in the local bit line LBL, a potential corresponding to the data is supplied to the gate of the transistor 31 and thus a current corresponding to the data flows between the source and the drain; by utilizing this, reading of data can be performed.

Note that reading of data by the sensing circuit 35 functioning as a memory does not change charge retained in the local bit line LBL. In other words, the sensing circuit 35 functioning as a memory does not destruct stored data by reading data. That is, reading of data by the sensing circuit 35 functioning as a memory is non-destructive reading.

Here, as a non-destructive read memory using an OS transistor, there is a memory called a NOSRAM (registered trademark). NOSRAM is an abbreviation for a Nonvolatile Oxide Semiconductor RAM (Random Access Memory). Thus, the sensing circuit 35 can be regarded as a memory that performs an operation like a NOSRAM.

FIG. 4A is a circuit diagram of the memory cell 42 and corresponds to a circuit diagram of the memory cell 42 illustrated in FIG. 3B. FIG. 4B illustrates a circuit block corresponding to the circuit diagram, and corresponds to a circuit block of the memory cell 42 illustrated in FIG. 1.

FIG. 4C is a circuit diagram of the sensing circuit 35 and corresponds to a circuit diagram of the sensing circuit 35 illustrated in FIG. 3B. FIG. 4D illustrates a circuit block corresponding to the circuit diagram, and corresponds to a circuit block of the sensing circuit 35 illustrated in FIG. 1.

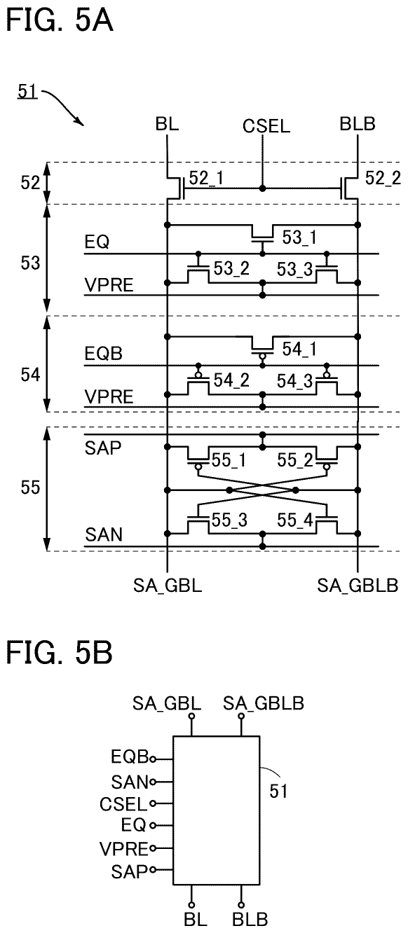

FIG. 5A is a circuit diagram illustrating the driver circuit 51 provided in the substrate 50 with circuit symbols. The driver circuit 51 includes a switch circuit 52, a precharge circuit 53, a precharge circuit 54, and the sense amplifier 55. Each of the switch circuit 52, the precharge circuit 53, the precharge circuit 54, and the sense amplifier 55 is electrically connected to the global bit line SA_GBL and the global bit line SA_GBLB. The switch circuit 52 is electrically connected to a bit line BL and a bit line BLB. The driver circuit 51 has a function of controlling writing or reading of data to/from the memory cells 42.

The switch circuit 52 has a function of establishing or breaking electrical continuity between a wiring pair of the global bit line SA_GBL and the global bit line SA_GBLB and a wiring pair of the bit line BL and the bit line BLB in accordance with a signal CSEL. Specifically, the switch circuit 52 includes a transistor 52_1 and a transistor 52_2. Each of the transistor 52_1 and the transistor 52_2 is an n-channel transistor. The transistor 52_1 has a function of establishing or breaking electrical continuity between the global bit line SA_GBL and the bit line BL in accordance with the signal CSEL. The transistor 52_2 has a function of establishing or breaking electrical continuity between the global bit line SA_GBLB and the bit line BLB in accordance with the signal CSEL.

The precharge circuit 53 has a function of precharging the global bit line SA_GBL and the global bit line SA_GBLB to a potential VPRE in accordance with a signal EQ. Specifically, the precharge circuit 53 includes a transistor 53_1, a transistor 532, and a transistor 53_3. Each of the transistor 53_1, the transistor 532, and the transistor 53_3 is an n-channel transistor. The transistor 53_1 has a function of establishing or breaking electrical continuity between the global bit line SA_GBL and the global bit line SA_GBLB in accordance with the signal EQ. The transistor 53_2 has a function of precharging the global bit line SA_GBL to the potential VPRE in accordance with the signal EQ. The transistor 53_3 has a function of precharging the global bit line SA_GBLB to the potential VPRE in accordance with the signal EQ.

The precharge circuit 54 has a function of precharging the global bit line SA_GBL and the global bit line SA_GBLB to the potential VPRE in accordance with a signal EQB. Specifically, the precharge circuit 54 includes a transistor 54_1, a transistor 542, and a transistor 54_3. Each of the transistor 54_1, the transistor 542, and the transistor 54_3 is a p-channel transistor. The transistor 54_1 has a function of establishing or breaking electrical continuity between the global bit line SA_GBL and the global bit line SA_GBLB in accordance with the signal EQB. The transistor 54_2 has a function of precharging the global bit line SA_GBL to the potential VPRE in accordance with the signal EQB. The transistor 54_3 has a function of precharging the global bit line SA_GBLB to the potential VPRE in accordance with the signal EQB.

The sense amplifier 55 has a function of outputting a potential corresponding to one of binary data to the global bit line SA_GBL and outputting a potential corresponding to the other of the binary data to the global bit line SA_GBLB by supplying a predetermined potential to a wiring SAP and a wiring SAN. The sense amplifier 55 includes a transistor 55_1, a transistor 552, a transistor 55_3, and a transistor 55_4. Each of the transistor 55_1 and the transistor 55_2 is a p-channel transistor. Each of the transistor 55_3 and the transistor 55_4 is an n-channel transistor. The transistor 55_1 and the transistor 55_3 form an inverter in which the global bit line SA_GBLB is the input, the global bit line SA_GBL is the output, the wiring SAP is the high potential power supply line, and the wiring SAN is the low potential power supply line. The transistor 55_2 and the transistor 55_4 form an inverter in which the global bit line SA_GBL is the input, the global bit line SA_GBLB is the output, the wiring SAP is the high potential power supply line, and the wiring SAN is the low potential power supply line.

FIG. 5B illustrates a circuit block corresponding to the circuit diagram of the driver circuit 51 illustrated in FIG. 5A, and corresponds to the circuit block of the driver circuit 51 illustrated in FIG. 1.

### Operation Example of Semiconductor Device

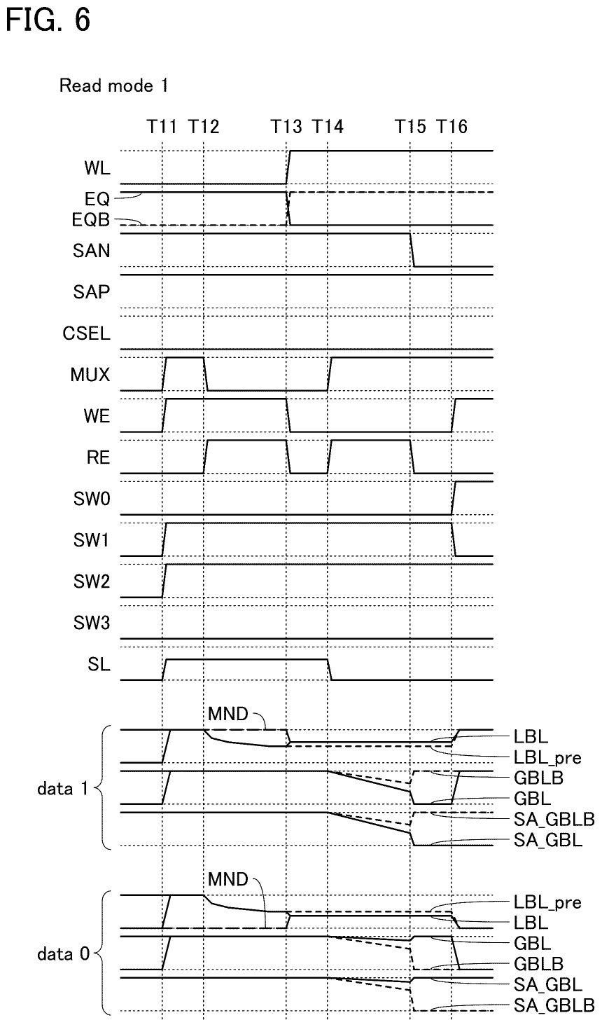

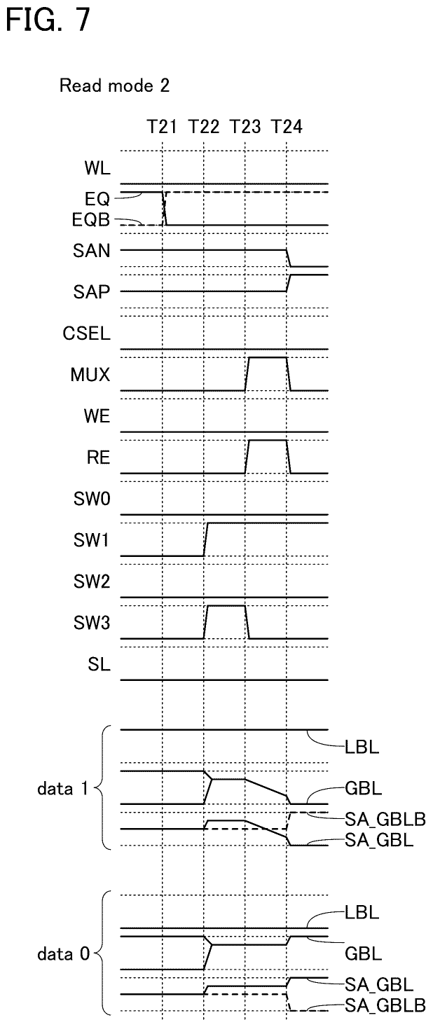

Next, operation examples of the semiconductor device 10 are described with reference to FIG. 6 and FIG. 7.

Examples of the method for driving the semiconductor device 10 of one embodiment of the present invention include a read mode 1 and a read mode 2. The read mode 1 is a mode in which data stored in the memory cell 42 (a potential retained in the node MND) is read by the sense amplifier 55 included in the driver circuit 51 through the sensing circuit 35 and the switching circuit 37. The read mode 2 is a mode in which the potential retained in the local bit line LBL is read by the sense amplifier 55 included in the driver circuit 51 through the sensing circuit 35 and the switching circuit 37. In other words, the read mode 2 is a mode in which, when the sensing circuit 35 functions as a memory, data stored in the local bit line LBL is read by the sense amplifier 55 included in the driver circuit 51 through the sensing circuit 35 and the switching circuit 37.

Note that in the following description of the operation example, a potential corresponding to “1” of binary data is a high power supply potential VDD (hereinafter, sometimes abbreviated as VDD), and a potential corresponding to “0” of binary data is a low power supply potential VSS (hereinafter, sometimes abbreviated as VSS). VDD is a potential higher than at least the threshold voltage of the transistor with respect to VSS. Note that VSS may be the ground potential GND, for example. In the following description of the operation example, the potential of the signal is set to an H level or an L level. The H level is a potential which, when being supplied to a gate of an n-channel transistor, makes the transistor in the conduction state and, when being supplied to a gate of a p-channel transistor, makes the transistor in the non-conduction state. The L level is a potential which, when being supplied to a gate of an n-channel transistor, makes the transistor in the non-conduction state and, when being supplied to a gate of a p-channel transistor, makes the transistor in the conduction state. The H level can be, for example, a potential equal to or higher than VDD. The L level can be, for example, a potential equal to or lower than VSS.

Note that the H level or the L level does not necessarily have the same potential among a plurality of signals supplied to the semiconductor device 10. The plurality of signals supplied to the semiconductor device 10 may have different H-level or L-level potentials from one another in accordance with the threshold voltages of the transistors to which the signals are supplied. For example, the H-level or L-level potential of a signal supplied to a gate of a Si transistor provided in the substrate 50 and that of a signal supplied to gates of OS transistors provided in the layer 30 and the layer 40 may be different from each other. For example, in the case where the threshold voltages of the OS transistors are higher than the threshold voltage of the Si transistor, the H level of the signal supplied to the gates of the OS transistors can be higher than the H level of the signal supplied to the gate of the Si transistor. For example, in this embodiment and the like, the H levels of the signal supplied to the word line WL, the signal MUX, the signal WE, the signal RE, the signal SW0, the signal SW1, the signal SW2, and the signal SW3 can each be a potential higher than the H levels of the signal EQ, the signal EQB, and the signal CSEL. Note that in the following description of the operation example, in order to simplify the description, the potentials of all the signals are assumed to have the H level or the L level.

An operation example in each of the read mode 1 and the read mode 2 is described below with reference to timing charts illustrated in FIG. 6 and FIG. 7. The timing charts in FIG. 6 and FIG. 7 illustrate the potentials (the H level or the L level) of the signal supplied to the word line WL, the signal MUX, the signal WE, the signal RE, the signal SW0, the signal SW1, the signal SW2, the signal SW3, the signal EQ, the signal EQB, and the signal CSEL at each operation time. In addition, the potentials supplied to the wiring SL, the wiring SAP, and the wiring SAN are also illustrated. In addition, changes in the potentials of the node MND of the memory cell 42, the local bit line LBL, the local bit line LBL_pre, the global bit line GBL, the global bit line GBLB, the global bit line SA_GBL, and the global bit line SA_GBLB in the case where data “1” (data 1) is read and the case where data “0” (data 0) is read are also illustrated.

In this specification and the like, for example, the description “a signal is set to the H level (or the L level) at Time T11” does not necessarily mean that the potential of the signal becomes constant at the H level (or the L level) at the moment in time. For example, even when the potential of a signal gradually changes due to the parasitic resistance, parasitic capacitance, or the like of a wiring and becomes constant at the H level (or the L level) with some signal delay, the expression “the signal is set to the H level (or the L level) at Time T11” is used. Thus, for example, the expression “Time T11” can be replaced with the expression “approximately Time T11” or “substantially Time T11”. Note that the same applies to the time other than Time T11. In the drawings of timing charts, signals in the state whose potentials gradually change before becoming constant at the H level (or the L level) with signal delay are shown by oblique lines. Note that the signal delay time is, for example, less than 100 nanoseconds, preferably less than 10 nanoseconds, further preferably less than 1 nanosecond, still further preferably less than 0.1 nanoseconds. The signal delay time may be different among the signals.

### [Read Mode 1]

FIG. 6 is a timing chart illustrating an operation example of the semiconductor device 10 in the read mode 1. Time T11 to Time T13 are a period for correcting the threshold voltage. Time T13 to Time T16 are a period for reading data. The period after Time T16 is a period for writing back (refreshing) data.

Immediately before Time T11, the signal supplied to the word line WL, the signal MUX, the signal WE, and the signal RE are each set to the L level. The potential of the wiring SL is a predetermined potential (e.g., VSS). The signal SW0, the signal SW1, the signal SW2, and the signal SW3 are each set to the L level. The signal EQ is set to the H level, and the signal EQB is set to the L level. The signal CSEL is set to the L level. The potential of the wiring SAP and the potential of the wiring SAN are each set to VDD. The potential VPRE and the potential VPRE2 are each set to VDD. The potential of the wiring CSL is set to a given fixed potential (e.g., VSS). At this time, the global bit line SA_GBL and the global bit line SA_GBLB are each precharged to VDD. The global bit line GBL and the global bit line GBLB are each in an electrically floating state, and the potentials thereof are VDD or VSS. The local bit line LBL and the local bit line LBL_pre are each in an electrically floating state and retain VDD or VSS. In addition, the node MND of the memory cell 42 retains VDD (a potential corresponding to data “1”) or VSS (a potential corresponding to data “0”). Note that in the description of the operations from Time T11 to Time T16, in the case where the potentials of the wirings and the signals are not particularly specified, the potentials at the previous time are maintained.

At Time T11, the signal SW1 and the signal SW2 are set to the H level. The signal MUX and the signal WE are set to the H level. Then, the global bit line GBL and the global bit line GBLB are each precharged to VDD. Furthermore, the local bit line LBL and the local bit line LBL_pre are each precharged to VDD. In addition, the potential of the wiring SL becomes a predetermined potential between VDD and VSS. The predetermined potential affects the amount of current flowing through the transistor 31 during the operation at Time T14 described later. Thus, the predetermined potential is determined so that the current amount can become an appropriate value.

At Time T12, the signal MUX is set to the L level and the signal RE is set to the H level. Then, the potentials of the local bit line LBL and the local bit line LBL_pre are each decreased to “the potential of the wiring SL+the threshold voltage of the transistor 31” by the discharging to the wiring SL through the transistors 31 included in the sensing circuit 35 and the sensing circuit 35_pre.

At Time T13, the signal WE and the signal RE are set to the L level. Then, the local bit line LBL and the local bit line LBL_pre are each brought into an electrically floating state. Accordingly, potentials corresponding to the threshold voltages of the transistors 31 included in the sensing circuit 35 and the sensing circuit 35_pre are retained in the local bit line LBL and the local bit line LBL_pre, respectively. Accordingly, correction is performed so that the amount of current flowing through the transistors 31 during the operation at Time T14 described later is not affected by the threshold voltages of the transistors 31. Such correction can improve the reliability of the read data in the semiconductor device 10 of one embodiment of the present invention.

At Time T13, the signal EQ is set to the L level and the signal EQB is set to the H level. This stops precharging of the global bit line SA_GBL and the global bit line GBL and precharging of the global bit line SA_GBLB and the global bit line GBLB. Thus, the global bit line SA_GBL, the global bit line GBL, the global bit line SA_GBLB, and the global bit line GBLB are each brought into an electrically floating state.

At Time T13, the signal supplied to the word line WL that is connected to the memory cell 42 electrically connected to the local bit line LBL is set to the H level. Then, charge sharing is performed between the local bit line LBL and the node MND. Thus, the potential of the local bit line LBL changes in accordance with data stored in the memory cell 42 (i.e., in accordance with the potential retained in the node MND). Accordingly, the potential of the local bit line LBL becomes equal to the potential of the node MND.

Specifically, for example, in the case where the data stored in the memory cell 42 is “1” (data 1) (i.e., the potential retained in the node MND is VDD), when the signal supplied to the word line WL is set to the H level, the potential of the local bit line LBL increases and the potential of the node MND decreases. Accordingly, the potential of the local bit line LBL becomes equal to the potential of the node MND. Alternatively, for example, in the case where the data stored in the memory cell 42 is “0” (data 0) (i.e., the potential retained at the node MND is VSS), when the signal supplied to the word line WL is set to the H level, the potential of the local bit line LBL decreases and the potential of the node MND increases. Accordingly, the potential of the local bit line LBL becomes equal to the potential of the node MND.

At Time T13, the signal supplied to the word line WL that is connected to the memory cell 42 electrically connected to the local bit line LBL_pre remains at the L level. In other words, charge sharing by the local bit line LBL_pre is not performed. Thus, the potential of the local bit line LBL does not change.

Note that the potential of the node MND is changed by charge sharing. That is, data stored in the memory cell 42 is destructed. That is, the read mode 1 is destructive reading. Thus, data is written back by the operation at Time T16 described later.

At Time T14, the signal MUX and the signal RE are set to the H level. The potential of the wiring SL becomes equal to the potential immediately before Time T11 (e.g., VSS). Then, a current flows through the transistor 31 included in the sensing circuit 35 and the transistor 31 included in the sensing circuit 35_pre in accordance with the potentials of the local bit line LBL and the local bit line LBL_pre. Accordingly, the potentials of the global bit line SA_GBL, the global bit line GBL, the global bit line SA_GBLB, and the global bit line GBLB decrease gradually. At this time, the difference between the potential of the local bit line LBL and the potential of the local bit line LBL_pre causes a difference between the amount of current flowing through the transistor 31 included in the sensing circuit 35 and the amount of current flowing through the transistor 31 included in the sensing circuit 35_pre. This difference in the current amount corresponds to the potential of the local bit line LBL changed due to charge sharing in the above-described operation at Time T13. That is, the speed at which the potentials of the global bit line SA_GBL and the global bit line GBL decrease is changed in accordance with the potential of the local bit line LBL. Thus, the potential of the local bit line LBL can be converted into a potential difference between the global bit line SA_GBL and the global bit line SA_GBLB.

Specifically, for example, when the data stored in the memory cell 42 is “1” (data 1), the amount of current flowing through the transistor 31 included in the sensing circuit 35 is larger than the amount of current flowing through the transistor 31 included in the sensing circuit 35_pre. Therefore, the speed at which the potentials of the global bit line SA_GBL and the global bit line GBL decrease is higher than the speed at which the potentials of the global bit line SA_GBLB and the global bit line GBLB decrease. This makes the potential of the global bit line SA_GBL lower than the potential of the global bit line SA_GBLB. Alternatively, for example, in the case where the data stored in the memory cell 42 is “0” (data 0), the amount of current flowing through the transistor 31 included in the sensing circuit 35 is smaller than the amount of current flowing through the transistor 31 included in the sensing circuit 35_pre. Therefore, the speed at which the potentials of the global bit line SA_GBL and the global bit line GBL decrease is lower than the speed at which the potentials of the global bit line SA_GBLB and the global bit line GBLB decrease. This makes the potential of the global bit line SA_GBL higher than the potential of the global bit line SA_GBLB.

At Time T15, the signal RE is set to the L level. The potential of the wiring SAN is set to VSS. Then, by the operation of the sense amplifier 55, a potential difference between the global bit line SA_GBL and the global bit line SA_GBLB generated by the above-described operation at Time T14 is amplified. Thus, the potentials of the global bit line SA_GBL and the global bit line SA_GBLB are each determined to be either VDD or VSS. That is, reading of data stored in the memory cell 42 is completed.

Specifically, for example, in the case where the data stored in the memory cell 42 is “1” (data 1), the potential of the global bit line SA_GBL becomes VSS and the potential of the global bit line SA_GBLB becomes VDD. Alternatively, for example, in the case where the data stored in the memory cell 42 is “0” (data 0), the potential of the global bit line SA_GBL becomes VDD and the potential of the global bit line SA_GBLB becomes VSS.

At Time T16, the signal SW0 is set to the H level and the signal SW1 is set to the L level. In addition, the signal WE is set to the H level. Then, an operation of writing back data to the memory cell 42 in accordance with data read from the memory cell 42 is performed. That is, the potentials of the global bit line GBL and the local bit line LBL become equal to the potential of the global bit line SA_GBLB determined by the operation at Time T15. Furthermore, the potential is written back to the memory cell 42.

Specifically, for example, in the case where the data stored in the memory cell 42 is “1” (data 1), the potential of the global bit line SA_GBLB immediately before Time T16 is VDD. Thus, the potentials of the global bit line GBL and the local bit line LBL become VDD. Furthermore, VDD is written back to the memory cell 42. Alternatively, for example, in the case where the data stored in the memory cell 42 is “0” (data 0), the potential of the global bit line SA_GBLB immediately before Time T16 is VSS. Thus, the potentials of the global bit line GBL and the local bit line LBL become VSS. Furthermore, VSS is written back to the memory cell 42.

Note that in the case where data is written to the memory cell 42, the semiconductor device 10 is operated in a manner similar to that at Time T16 described above, for example. For example, in the case where data “1” is written to the memory cell 42, VDD is supplied to the global bit line SA_GBLB to perform the operation similar to that at Time T16. Alternatively, for example, in the case where data “0” is written to the memory cell 42, VSS is supplied to the global bit line SA_GBLB to perform the operation similar to that at Time T16.

### [Read Mode 2]

FIG. 7 is a timing chart illustrating an operation example of the semiconductor device 10 in the read mode 2. Time T21 to Time T24 are a period for reading data. Note that in the read mode 2, data stored in the memory cell 42 is not related to data reading. In addition, the potential of the local bit line LBL_pre is not related to data reading either. Therefore, FIG. 7 does not illustrate the potentials of the node MND and the local bit line LBL_pre. In addition, the potential of the global bit line GBLB is not illustrated.

Immediately before Time T21, the signal supplied to the word line WL, the signal MUX, the signal WE, and the signal RE are each set to the L level. The potential of the wiring SL is a predetermined potential (e.g., VSS). The signal SW0, the signal SW1, the signal SW2, and the signal SW3 are each set to the L level. The signal EQ is set to the H level, and the signal EQB is set to the L level. The signal CSEL is set to the L level. The potential of the wiring SAP and the potential of the wiring SAN are each set to (VDD−VSS)/2. The potential VPRE is set to (VDD−VSS)/2 and the potential VPRE2 is set to a potential that exceeds (VDD−VSS)/2 but does not exceed VDD (e.g., VDD). The potential of the wiring CSL is set to a given fixed potential (e.g., VSS). At this time, the global bit line SA_GBL and the global bit line SA_GBLB are each precharged to (VDD−VSS)/2. The global bit line GBL and the global bit line GBLB are each in an electrically floating state, and the potentials thereof are VDD or VSS. The local bit line LBL is in an electrically floating state and retains VDD (a potential corresponding to data “1”) or VSS (a potential corresponding to data “0”). Note that in the description of the operations from Time T21 to Time T24, in the case where the potentials of the wirings and the signals are not particularly specified, the potentials at the previous time are maintained.

At Time T21, the signal EQ is set to the L level and the signal EQB is set to the H level. This stops precharging of the global bit line SA_GBL and the global bit line SA_GBLB. Thus, the global bit line SA_GBL and the global bit line SA_GBLB are each brought into an electrically floating state.

At Time T22, the signal SW1 and the signal SW3 are set to the H level. Then, the global bit line SA_GBL and the global bit line GBL are precharged to a potential between VDD and (VDD−VSS)/2. That is, the potential of the global bit line SA_GBL becomes higher than the potential of the global bit line SA_GBLB.

At Time T23, the signal SW3 is set to the L level. This stops precharging of the global bit line SA_GBL and the global bit line GBL. Then, the signal MUX and the signal RE are set to the H level. Then, each of the potentials of the global bit line SA_GBL and the global bit line GBL changes in accordance with the potential of the local bit line LBL. Thus, the potential of the local bit line LBL can be converted into a potential difference between the global bit line SA_GBL and the global bit line SA_GBLB.

Specifically, for example, in the case where the data stored in the sensing circuit 35 functioning as a memory is “1” (data 1) (i.e., the potential retained in the local bit line LBL is VDD), when a current flows through the transistor 31 included in the sensing circuit 35, each of the potentials of the global bit line SA_GBL and the global bit line GBL decreases gradually. This makes the potential of the global bit line SA_GBL lower than the potential of the global bit line SA_GBLB. Alternatively, for example, in the case where the data stored in the sensing circuit 35 functioning as a memory is “0” (data 0) (i.e., the potential retained in the local bit line LBL is VSS), when the transistor 31 included in the sensing circuit 35 is in the non-conduction state, the potentials of the global bit line SA_GBL and the global bit line GBL are each maintained. Thus, the potential of the global bit line SA_GBL is kept higher than the potential of the global bit line SA_GBLB.

Note that the potential of the local bit line LBL does not change by the operation at Time T23. That is, the data stored in the sensing circuit 35 functioning as a memory is not destructed. That is, the read mode 2 is non-destructive reading.

At Time T24, the signal MUX and the signal RE are set to the L level. The potential of the wiring SAN is set to VSS, and the potential of the wiring SAP is set to VDD. Then, by the operation of the sense amplifier 55, a potential difference between the global bit line SA_GBL and the global bit line SA_GBLB generated by the above-described operation at Time T23 is amplified. Thus, the potentials of the global bit line SA_GBL and the global bit line SA_GBLB are each determined to be either VDD or VSS. That is, reading of data stored in the sensing circuit 35 functioning as a memory is completed.

Specifically, for example, in the case where the data stored in the sensing circuit 35 functioning as a memory is “1” (data 1), the potential of the global bit line SA_GBL becomes VSS and the potential of the global bit line SA_GBLB becomes VDD. Alternatively, for example, in the case where the data stored in the sensing circuit 35 functioning as a memory is “0” (data 0), the potential of the global bit line SA_GBL becomes VDD and the potential of the global bit line SA_GBLB becomes VSS.

Note that in the case where data is written to the sensing circuit 35 functioning as a memory, the signal supplied to the word line WL is set to the L level and the semiconductor device 10 is operated in a manner similar to that at Time T16 described above, for example. For example, in the case where data “1” is written to the sensing circuit 35 functioning as a memory, the signal supplied to the word line WL is set to the L level and VDD is supplied to the global bit line SA_GBLB to perform the operation similar to that at Time T16. Alternatively, for example, in the case where data “0” is written to the sensing circuit 35 functioning as a memory, the signal supplied to the word line WL is set to the L level and VSS is supplied to the global bit line SA_GBLB to perform the operation similar to that at Time T16.

The read mode 1 is a mode in which data stored in the memory cell 42 is read. The area occupied by the memory cell 42 is smaller than that of the sensing circuit 35 functioning as a memory. Furthermore, the memory cells can be provided to be stacked, leading to high memory density. The read mode 2 is a mode in which data stored in the sensing circuit 35 functioning as a memory is read. In the read mode 2, a period in which the threshold voltage is corrected and a period in which data is written back are unnecessary, and thus data is read more quickly than in the read mode 1. In addition, energy (access energy) necessary for reading is low. In the semiconductor device 10 of one embodiment of the present invention, the read mode 1 and the read mode 2 can be used separately as appropriate depending on the situation or the purpose. In the semiconductor device 10 of one embodiment of the present invention, since the read mode 1 and the read mode 2 are used separately as appropriate depending on the situation or the purpose, high-speed data reading and a reduction in power consumption can be achieved.

In the semiconductor device 10 of one embodiment of the present invention, when reading in the read mode 1 is completed, a potential corresponding to the data read from the memory cell 42 is retained in the local bit line LBL. That is, the data previously read from the memory cell 42 is stored in the sensing circuit 35 functioning as a memory. Thus, in the case where data is to be read from the same memory cell 42 again, data is read in the read mode 2. This enables quick data reading. In addition, energy (access energy) necessary for reading can be reduced. Thus, the semiconductor device 10 can achieve high-speed data reading and a reduction in power consumption.

When the method for driving the semiconductor device 10 of one embodiment of the present invention includes the read mode 1 and the read mode 2 as described above, the semiconductor device 10 can be suitably used in an electronic computer, for example. For example, the plurality of memory cells 42 provided in each of the layer 41[1] to the layer 41[m] can be used as the main memory included in the electronic computer, and the plurality of sensing circuits 35 provided in the layer 30 can be used as the cache memory included in the electronic computer. In this case, the read mode 1 corresponds to a mode in which the main memory is accessed, and the read mode 2 corresponds to a mode in which the cache memory is accessed.

An example in which the semiconductor device 10 of one embodiment of the present invention is used in an electronic computer is described in detail later.

### Structure Example of Memory Device

The semiconductor device of one embodiment of the present invention can be suitably used in a memory device. Here, a memory device of one embodiment of the present invention in which the semiconductor device 10 described above is used is described. Note that for portions where the semiconductor device 10 is used in the memory device described below, the above description can be referred to as appropriate; thus, the description is omitted in some cases by using the same reference numerals in the drawings and the like.

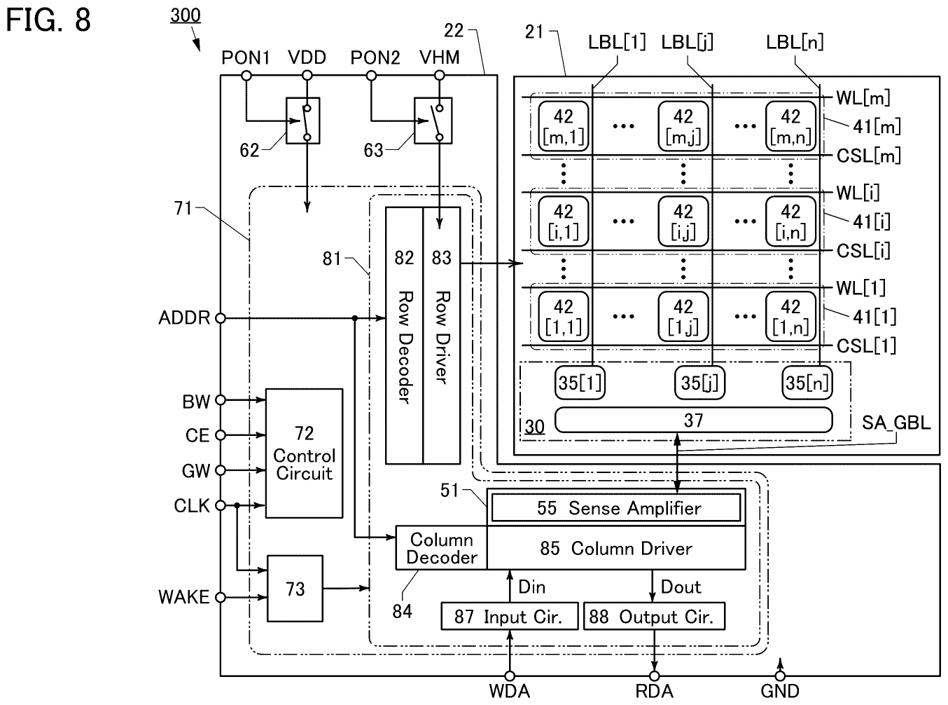

FIG. 8 is a block diagram illustrating a structure example of a memory device 300 of one embodiment of the present invention. The memory device 300 using the semiconductor device 10 illustrated in FIG. 8 includes a memory array 21 and a driver circuit 22. The memory array 21 includes the plurality of sensing circuits 35 and the switching circuit 37 provided in the layer 30 and the plurality of memory cells 42 provided in the layer 41[1] to the layer 41[m]. The driver circuit 22 is provided in the substrate 50 (not illustrated).

In the memory array 21 illustrated in FIG. 8, m×n memory cells 42 placed in a matrix of m rows and n columns are provided, for example. Note that m and n are each an integer greater than or equal to two. Furthermore, the memory array 21 is provided with n sensing circuits 35 which are placed in respective columns, for example.

In FIG. 8, the memory cell 42 in the first row and the first column is referred to as a memory cell 42[1, 1], and the memory cell 42 in the m-th row and the n-th column is referred to as a memory cell 42[m, n]. In this embodiment and the like, a given row is denoted as an i-th row in some cases. A given column is denoted as a j-th column in some cases. Thus, i is an integer greater than or equal to one and less than or equal to m, and j is an integer greater than or equal to one and less than or equal to n. In this embodiment and the like, the memory cell 42 in the i-th row and the j-th column is referred to as a memory cell 42[i,j]. Note that in this embodiment and the like, “i+a” (a is a positive or negative integer) is not below one and does not exceed m. Similarly, “j+a” is not below one and does not exceed n.

In FIG. 8, the sensing circuit 35 provided in the first column is denoted as the sensing circuit 35[1], the sensing circuit 35 provided in the j-th column is denoted as the sensing circuit 35[j], and the sensing circuit 35 provided in the n-th column is denoted as the sensing circuit 35[n].

The memory array 21 includes m word lines WL extending in the row direction, m wirings CSL extending in the row direction, and n local bit lines LBL extending in the column direction. In this embodiment and the like, the first wiring WL provided in the first row is denoted as the word line WL[1], and the m-th word line WL provided in the m-th row is denoted as the word line WL[m]. Similarly, the first wiring CSL provided in the first row is denoted as the wiring CSL[1], and the m-th wiring CSL provided in the m-th row is denoted as the wiring CSL[m]. Similarly, the first local bit line LBL provided in the first column is denoted as the local bit line LBL[1], and the n-th local bit line LBL provided in the n-th column is denoted as the local bit line LBL[n].

The n memory cells 42 provided in the i-th row are electrically connected to the word line WL in the i-th row (the word line WL[i]) and the wiring CSL in the i-th row (the wiring CSL[i]). The m memory cells 42 provided in the j-th column are electrically connected to the local bit line LBL in the j-th column (the local bit line LBL[j]).

The sensing circuit 35 provided in the j-th column (the sensing circuit 35[j]) is electrically connected to the local bit line LBL in the j-th column (the local bit line LBL[j]). The switching circuit 37 is electrically connected to the n sensing circuits 35 through the global bit line GBL (not illustrated). The switching circuit 37 is electrically connected to the driver circuit 51 including the sense amplifier 55, which is included in the driver circuit 22, through the global bit line SA_GBL.

The driver circuit 22 includes a PSW 62 (power switch), a PSW 63, and a peripheral circuit 71. The peripheral circuit 71 includes a peripheral circuit 81, a control circuit 72, and a voltage generation circuit 73.

Note that part of the peripheral circuit 71 may be provided in the layer 30.

In the memory device 300, each circuit, each signal, and each voltage can be appropriately selected as needed. Another circuit or another signal may be added. Each of a signal BW, a signal CE, a signal GW, a signal CLK, a signal WAKE, a signal ADDR, a signal WDA, a signal PON1, and a signal PON2 is a signal input from the outside. A signal RDA is a signal output to the outside.

The signal CLK is a clock signal. The signal BW, the signal CE, and the signal GW are control signals. The signal CE is a chip enable signal. The signal GW is a global write enable signal. The signal BW is a byte write enable signal. The signal ADDR is an address signal. The signal WDA is write data. The signal RDA is read data. The signal PON1 and the signal PON2 are power gating control signals. Note that the signal PON1 and the signal PON2 may be generated in the control circuit 72.

The control circuit 72 is a logic circuit having a function of controlling the entire operation of the memory device 300. For example, the control circuit performs a logical operation on the signal CE, the signal GW, and the signal BW to determine an operation mode of the memory device 300 (e.g., write operation or read operation (e.g., the read mode 1 or the read mode 2)). Alternatively, the control circuit 72 generates a control signal for the peripheral circuit 81 so that the operation mode is executed.

The voltage generation circuit 73 has a function of generating a negative voltage. The signal WAKE has a function of controlling the input of the signal CLK to the voltage generation circuit 73. For example, when an H-level signal is supplied as the signal WAKE, the signal CLK is input to the voltage generation circuit 73, and the voltage generation circuit 73 generates a negative voltage.

The peripheral circuit 81 is a circuit for writing or reading data to/from the memory cells 42. The peripheral circuit 81 is a circuit that outputs a variety of signals for controlling the sensing circuits 35 and the switching circuit 37. The peripheral circuit 81 includes a row decoder 82 (Row Decoder), a column decoder 84 (Column Decoder), a row driver 83 (Row Driver), a column driver 85 (Column Driver), an input circuit 87 (Input Cir.), an output circuit 88 (Output Cir.), and the driver circuit 51 including a sense amplifier 55 (Sense Amplifier).

The row decoder 82 and the column decoder 84 have a function of decoding the signal ADDR. The row decoder 82 is a circuit for specifying a row to be accessed. The column decoder 84 is a circuit for specifying a column to be accessed. The row driver 83 has a function of selecting the word line WL specified by the row decoder 82. The column driver 85 has a function of writing data to the memory cells 42, a function of reading data from the memory cells 42, a function of retaining the read data, or the like, for example.

The input circuit 87 has a function of retaining the signal WDA. Data retained by the input circuit 87 is output to the column driver 85. Data output from the input circuit 87 is data (data Din) to be written to the memory cells 42. Data (data Dout) read from the memory cells 42 by the column driver 85 is output to the output circuit 88. The output circuit 88 has a function of retaining the data Dout. In addition, the output circuit 88 has a function of outputting the data Dout to the outside of the memory device 300. Data output from the output circuit 88 is the signal RDA.

The PSW 62 has a function of controlling supply of VDD to the peripheral circuit 71. The PSW 63 has a function of controlling supply of a potential VHM to the row driver 83. Here, the high power supply potential of the memory device 300 is VDD and the low power supply potential thereof is the ground potential GND (or may be VSS). In addition, the potential VHM is a high power supply potential used to set the word line to the H level and is higher than VDD. The PSW 62 is controlled to be in the on state or the off state by the signal PON1. The PSW 63 is controlled to be in the on state or the off state by the signal PON2. The number of power domains to which VDD is supplied is one in the peripheral circuit 71 in FIG. 8 but can be more than one. In that case, a power switch is provided for each power domain in the driver circuit 22.

As in the above description of the semiconductor device 10, the layer 30 and the layer 41[1] to the layer 41[m] can each be placed to be stacked in the perpendicular direction over the substrate 50.

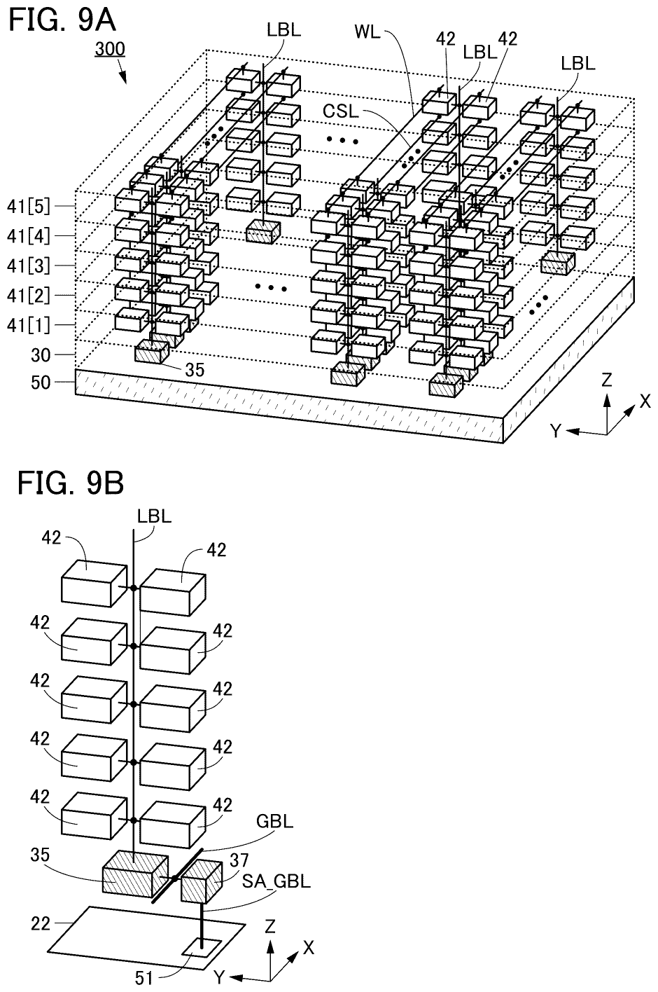

FIG. 9A is a perspective view illustrating the memory device 300 in which the layer 30 and five (m=5) layers 41[1] to 41[5] are placed to be stacked in the perpendicular direction over the substrate 50, for example. FIG. 9A illustrates the plurality of memory cells 42 placed in each of the layer 41[1] to the layer 41[5]. In addition, the plurality of sensing circuits 35 placed in the layer 30 are illustrated. In addition, the word lines WL and the wirings CSL extending in the X direction and the local bit lines LBL extending in the Z direction (the perpendicular direction over the substrate 50 where the driver circuit 22 is provided) are illustrated. For easy viewing of the drawing, the word line WL and the wiring CSL are partly omitted.

FIG. 9B is a schematic view illustrating a structure example of the sensing circuit 35 and the plurality of memory cells 42 which are electrically connected to one of the plurality of local bit lines LBL illustrated in FIG. 9A. FIG. 9B illustrates the switching circuit 37 and the driver circuit 51 provided in the driver circuit 22. The switching circuit 37 is electrically connected to the sensing circuit 35 through the global bit line GBL. The switching circuit 37 is electrically connected to the driver circuit 51 through the global bit line SA_GBL. Note that the structure in which the plurality of memory cells 42 are electrically connected to one local bit line LBL as illustrated in FIG. 9B is also referred to as a “memory string”.

Note that the local bit line LBL is provided in contact with the semiconductor layer of the transistor included in the memory cell 42. Alternatively, the local bit line LBL is provided in contact with a region functioning as a source or a drain in the semiconductor layer of the transistor included in the memory cell 42. Alternatively, the local bit line LBL is provided in contact with a conductor provided in contact with the region functioning as the source or the drain in the semiconductor layer of the transistor included in the memory cell 42. That is, the local bit line LBL is a wiring for electrically connecting, in the perpendicular direction, the sensing circuit 35 and the other of the source and the drain of the transistor included in each of the plurality of memory cells 42 provided in the layer 41[1] to the layer 41[5].

In the memory device 300 of one embodiment of the present invention, by using the above-described semiconductor device 10, the plurality of sensing circuits 35 and the switching circuit 37 and the plurality of memory cells 42 can be placed to be stacked in the perpendicular direction over the driver circuit 22 including the sense amplifier 55. This enables an improvement in memory density, a reduction in manufacturing cost, a reduction in power consumption, a reduction in signal delay, and a reduction in size of the memory device 300 of one embodiment of the present invention, for example.

With the use of the semiconductor device 10 described above, the method for driving the memory device 300 of one embodiment of the present invention can include the read mode 1 and the read mode 2. By including the read mode 1 and the read mode 2 described above, the memory device 300 of one embodiment of the present invention can be suitably used in an electronic computer, for example.

### Structure Example of Electronic Computer

The semiconductor device according to one embodiment of the present invention can be suitably used for an electronic computer. The memory device of one embodiment of the present invention can be suitably used for an electronic computer. Here, an example in which the semiconductor device 10 described above is used for an electronic computer is described. Note that for portions where the semiconductor device 10 is used in the electronic computer described below, the above description can be referred to as appropriate; thus, the description is omitted in some cases by using the same reference numerals in the drawings and the like.

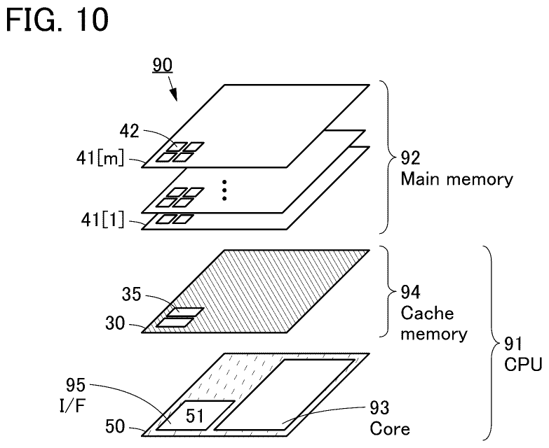

FIG. 10 is a schematic diagram illustrating an electronic computer 90 of one embodiment of the present invention. The electronic computer 90 includes a processor 91 (CPU) and a main memory 92 (Main memory). The processor 91 includes a core 93 (Core), a cache memory 94 (Cache memory), and an interface 95 (I/F).

The processor 91 has a function of accessing the cache memory 94 and storing (also referred to as loading) an instruction or data stored in the cache memory 94 in a register (not illustrated) included in the core 93 through the interface 95. The processor 91 has a function of performing a predetermined arithmetic operation on the basis of an instruction or data stored in the register. In addition, the processor 91 has a function of accessing the main memory 92 and reading the desired instruction or data stored in the main memory 92 to the cache memory 94 in the case where the instruction or data stored in the register by loading is not the instruction or data desired by the core 93 (also referred to as a cache error).

In the electronic computer 90 that is an example to which the above-described semiconductor device 10 is applied, the plurality of memory cells 42 included in the semiconductor device 10 can be used for the main memory 92, the sensing circuits 35 functioning as the plurality of memories included in the semiconductor device 10 can be used for the cache memory 94, and the driver circuit 51 included in the semiconductor device 10 can be used for the interface 95.

Accordingly, as illustrated in FIG. 10, the core 93 and the interface 95 are provided in the substrate 50, the cache memory 94 is provided in the layer 30, and the main memory 92 is provided in each of the layer 41[1] to the layer 41[m]. Furthermore, the layer 30 in which the cache memory 94 is provided and the layer 41[1] to the layer 41[m] in which the main memory 92 is provided are each placed to be stacked in the perpendicular direction over the substrate 50 in which the core 93 and the interface 95 are provided.

As described above, the structure of the memory cell 42 can be referred to as a DOSRAM. Instead of a DRAM (Dynamic Random Access Memory) typically used as a main memory, a DOSRAM can be used as a main memory. Although a DOSRAM is formed using one transistor and one capacitor as in a DRAM, data can be stored for a long period by using an OS transistor with an extremely low off-state current as the transistor. Thus, the refresh cycle of the DOSRAM can be significantly reduced as compared with that of the DRAM. For example, the refresh cycle of the DRAM is shorter than or equal to milliseconds, and the refresh cycle of the DOSRAM is approximately longer than one hour and shorter than one year. The DOSRAM can be placed in a plurality of layers over a silicon substrate provided with a sense amplifier, for example. Owing to these features, the DOSRAM can operate at higher speed and consume lower access energy (energy consumed by data writing or data reading) than the DRAM.

As described above, when the sensing circuit 35 functions as a memory, the sensing circuit 35 can be regarded as a NOSRAM. The NOSRAM is a nonvolatile memory that stores data by retaining charge for a long period with the use of the feature of an OS transistor with an extremely low off-state current. Furthermore, the NOSRAM has features such as no limitation on the number of rewriting times in principle and the capability of multilevel data writing. Instead of an SRAM (Static Random Access Memory) typically used as a cache memory, a NOSRAM can be used as a cache memory. The NOSRAM can be freely placed in a layer over the silicon substrate provided with the core of the processor, for example, and thus can be easily integrated.

In other words, the electronic computer 90 can have a structure in which a layer provided with a NOSRAM (the sensing circuit 35) functioning as a cache memory is placed over the silicon substrate provided with the core of the processor, and the plurality of layers provided with the DOSRAM (the memory cells 42) functioning as a main memory are further placed.

### Operation Example of Electronic Computer

Next, an operation example of the electronic computer 90 of one embodiment of the present invention is described. The electronic computer 90 can employ the above-described method for driving the semiconductor device 10 as a driving method.

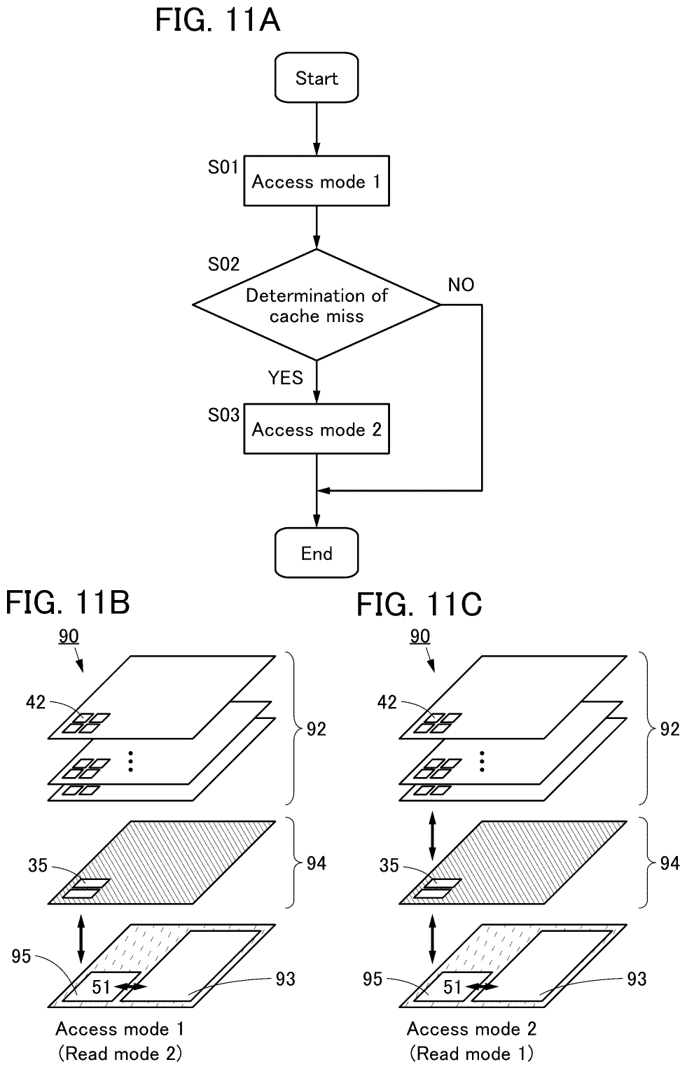

FIG. 11A is a flow chart illustrating an example of the operation of the electronic computer 90. The electronic computer 90 needs to load a desired instruction or desired data into the register included in the core 93 in order to perform a predetermined arithmetic operation. The flow chart illustrated in FIG. 11A shows a method for driving the electronic computer 90 at the time of loading a desired instruction or desired data into the register included in the core 93. As illustrated in FIG. 11A, the electronic computer 90 carries out Step S01, Step S02, and Step S03. When loading of a desired instruction or desired data is started (START), Step S01 is performed first.

In Step S01, the cache memory 94 is accessed in an access mode 1. FIG. 11B is a diagram schematically illustrating an operation state of the electronic computer 90 in the access mode 1. That is, the electronic computer 90 loads an instruction or data stored in the cache memory 94 into the register included in the core 93 through the interface 95. Note that the access mode 1 corresponds to the above-described read mode 2 of the semiconductor device 10 (see FIG. 7 as appropriate). That is, the electronic computer 90 reads data stored in the sensing circuit 35 functioning as a memory. Next, Step S02 is performed.

In Step S02, whether a cache error occurs in the instruction or data loaded into the register included in the core 93 in Step S01 is determined (Determination of cache miss). In the case where “YES” is determined in Step S02, that is, in the case where the instruction or data stored in the register included in the core 93 is not the instruction or data that the core 93 desires (cache error), Step S03 is performed. In the case where “NO” is determined in Step S02, that is, in the case where the instruction or data stored in the register included in the core 93 is the instruction or data that the core 93 desires (cache hit), loading of the instruction or data is completed (END). After that, although not illustrated, a predetermined arithmetic operation is performed on the basis of the instruction or data stored in the register.

In Step S03, the main memory 92 is accessed in an access mode 2. FIG. 11C is a diagram schematically illustrating an operation state of the electronic computer 90 in the access mode 2. That is, the electronic computer 90 loads a desired instruction or data stored in the main memory 92 into the register included in the core 93 through the cache memory 94 and the interface 95 to complete loading of the instruction or data (end). After that, although not illustrated, a predetermined arithmetic operation is performed on the basis of the instruction or data stored in the register. Note that the access mode 2 corresponds to the above-described read mode 1 of the semiconductor device 10 (see FIG. 6 as appropriate). That is, the electronic computer 90 reads data stored in the memory cell 42.

Note that the electronic computer 90 of one embodiment of the present invention is not limited to the above structure example. For example, the electronic computer 90 may include a primary cache memory provided in the substrate 50 and a secondary cache memory provided in the layer 30, instead of the cache memory 94. In this case, for example, in the electronic computer 90, an SRAM may be used as the primary cache memory and the sensing circuits 35 functioning as the plurality of memories included in the semiconductor device 10 may be used as the secondary cache memory; and the above-described operation example may be suitably used. For example, the electronic computer 90 may include a primary cache memory to a p-th cache memory (p is an integer greater than or equal to 2) provided in the substrate 50 and a (p+1)-th cache memory provided in the layer 30. In this case, for example, in the electronic computer, an SRAM may be used as each of the primary cache memory to the p-th cache memory, and the sensing circuits 35 functioning as the plurality of memories included in the semiconductor device 10 may be used as the p-th cache memory; and the above-described operation example may be suitably used. For example, the electronic computer 90 may include a storage-class memory in addition to the above-described components. In that case, the electronic computer 90 may use, for example, the plurality of memory cells 42 included in the semiconductor device 10 as the storage-class memory, and the above-described operation example may be suitably used.

The electronic computer 90 of one embodiment of the present invention can achieve, for example, an improvement in memory density, a reduction in manufacturing cost, a reduction in power consumption, a reduction in signal delay, a reduction in size, or the like by employing the above-described structure of the semiconductor device 10 and the above-described method for driving the semiconductor device 10.

Note that the semiconductor device of one embodiment of the present invention is not limited to the semiconductor device 10 described above. Furthermore, the memory device of one embodiment of the present invention is not limited to the memory device 300 described above. Moreover, the electronic computer of one embodiment of the present invention is not limited to the electronic computer 90 described above. At least part of the structure examples, the operation examples, the drawings corresponding thereto, and the like described in this embodiment as an example can be combined with the other structure examples, the other operation examples, the other drawings, the other embodiments or example described in this specification and the like, and the like as appropriate.

### Embodiment 2

In this embodiment, a semiconductor device 10A of one embodiment of the present invention is described. The semiconductor device 10A is a variation example of the semiconductor device 10 described in Embodiment 1. Thus, in order to avoid repeated description, differences of the semiconductor device 10A from the semiconductor device 10 are mainly described. Note that the above description of the semiconductor device 10 can be referred to as appropriate.

### Structure Example of Semiconductor Device

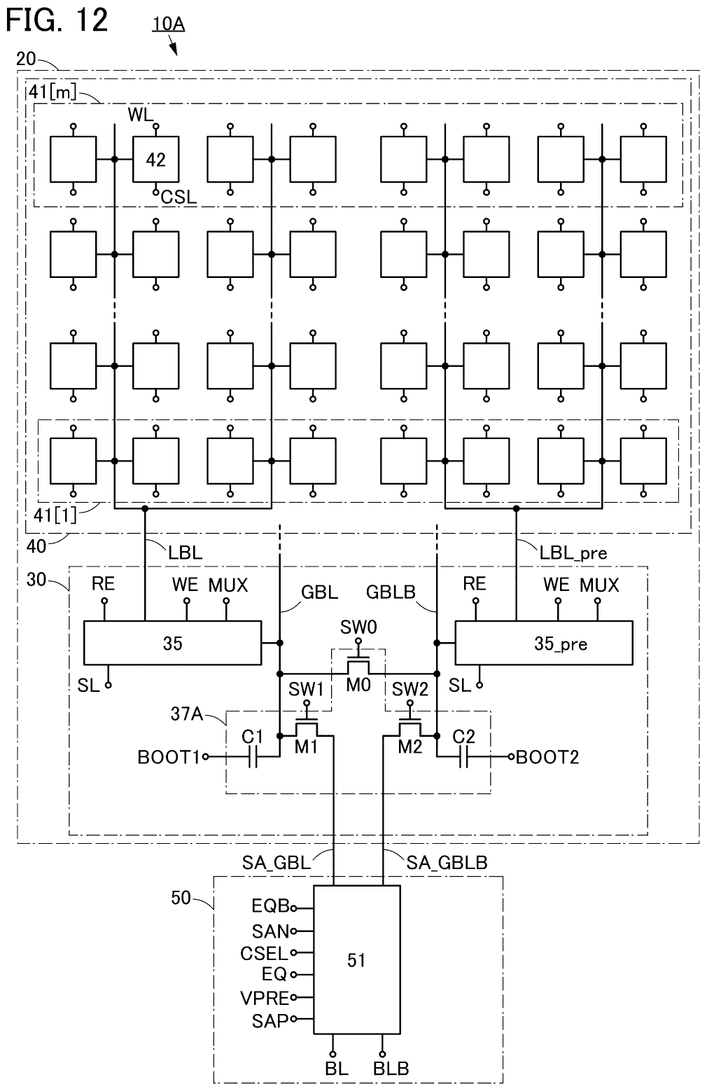

FIG. 12 is a circuit diagram illustrating a structure example of the semiconductor device 10A of one embodiment of the present invention.

The semiconductor device 10A is different from the semiconductor device 10 in including a switching circuit 37A instead of the switching circuit 37. The switching circuit 37A is different from the switching circuit 37 in including a capacitor C1 and a capacitor C2 instead of the transistor M3 and the transistor M4.

The switching circuit 37A is electrically connected to the sensing circuit 35 through the global bit line GBL. The switching circuit 37A is electrically connected to the sensing circuit 35_pre through the global bit line GBLB. The switching circuit 37A is electrically connected to the driver circuit 51 included in the substrate 50 through each of the global bit line SA_GBL and the global bit line SA_GBLB. The switching circuit 37A has a function of establishing or breaking electrical continuity among the global bit line GBL, the global bit line GBLB, the global bit line SA_GBL, and the global bit line SA_GBLB. The switching circuit 37A has a function of changing each of the global bit line GBL and the global bit line GBLB.

The switching circuit 37A includes the transistor M0, the transistor M1, the transistor M2, the capacitor C1, and the capacitor C2. Note that as the transistors included in the switching circuit 37A, transistors with extremely low off-state currents are preferably used. For example, OS transistors can be used as the transistors included in the switching circuit 37A.

One of the source and the drain of the transistor M0 is electrically connected to the global bit line GBL. The other of the source and the drain of the transistor M0 is electrically connected to the global bit line GBLB. The transistor M0 has a function of establishing or breaking electrical continuity between the global bit line GBL and the global bit line GBLB in accordance with the signal SW0.

One of the source and the drain of the transistor M1 is electrically connected to the global bit line GBL. The other of the source and the drain of the transistor M1 is electrically connected to the global bit line SA_GBL. The transistor M1 has a function of establishing or breaking electrical continuity between the global bit line GBL and the global bit line SA_GBL in accordance with the signal SW1.

One of the source and the drain of the transistor M2 is electrically connected to the global bit line GBLB. The other of the source and the drain of the transistor M2 is electrically connected to the global bit line SA_GBLB. The transistor M2 has a function of establishing or breaking electrical continuity between the global bit line GBLB and the global bit line SA_GBLB in accordance with the signal SW2.

One terminal of the capacitor C1 is electrically connected to the global bit line GBL. The other terminal of the capacitor C1 is electrically connected to a terminal to which a signal BOOT1 is supplied. The capacitor C1 has a function of changing the potential of the global bit line GBL in accordance with the signal BOOT1.

One terminal of the capacitor C2 is electrically connected to the global bit line GBLB. The other terminal of the capacitor C2 is electrically connected to a terminal to which a signal BOOT2 is supplied. The capacitor C2 has a function of changing the potential of the global bit line GBLB in accordance with the signal BOOT2.

### Operation Example of Semiconductor Device

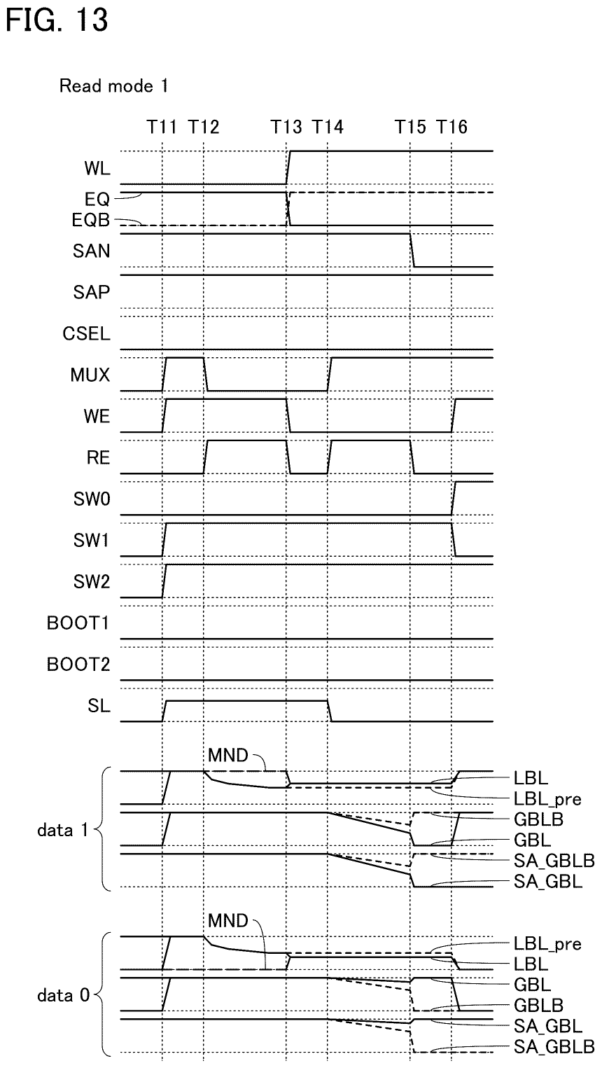

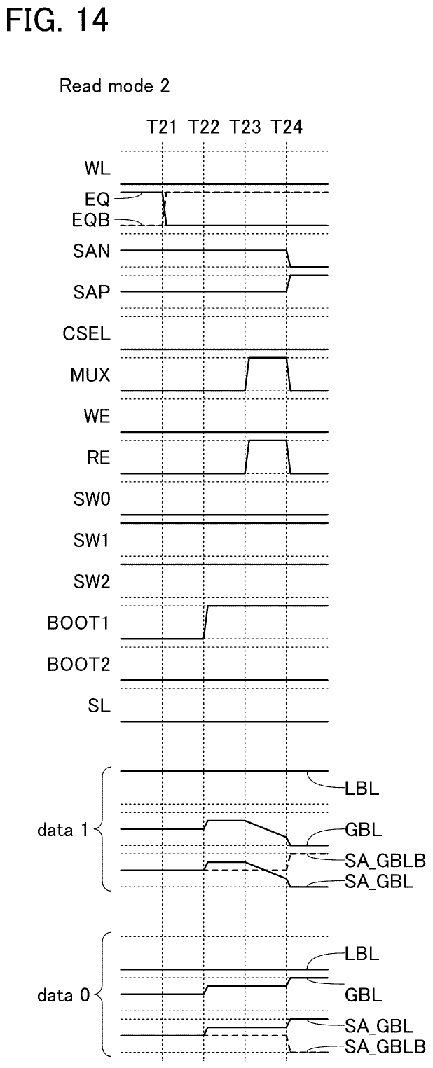

Next, operation examples of the semiconductor device 10A are described with reference to FIG. 13 and FIG. 14.

Examples of the method for driving the semiconductor device 10A of one embodiment of the present invention include the read mode 1 and the read mode 2, in a manner similar to that of the above-described semiconductor device 10.

An operation example in each of the read mode 1 and the read mode 2 is described below with reference to timing charts illustrated in FIG. 13 and FIG. 14. The timing charts illustrated in FIG. 13 and FIG. 14 are different from the timing charts illustrated in FIG. 6 and FIG. 7 in illustrating the potentials (the H level or the L level) of the signal BOOT1 and the signal BOOT2 instead of illustrating the potential of the signal SW3.

### [Read Mode 1]

FIG. 13 is a timing chart illustrating an operation example of the semiconductor device 10A in the read mode 1.

Immediately before Time T11 and at each of Time T11 to Time T13, the signal BOOT1 and the signal BOOT2 are in the L level. Signals other than the signal BOOT1 and the signal BOOT2 are similar to those in the timing chart illustrated in FIG. 6. Therefore, the above description of the read mode 1 of the semiconductor device 10 can be referred to as appropriate for the read mode 1 of the semiconductor device 10A; thus, the description thereof is omitted.

### [Read Mode 2]

FIG. 14 is a timing chart illustrating an operation example of the semiconductor device 10A in the read mode 2. Time T21 to Time T24 are a period for reading data. Note that in the read mode 2, data stored in the memory cell 42 is not related to data reading. In addition, the potential of the local bit line LBL_pre is not related to data reading either. Therefore, FIG. 14 does not illustrate the potentials of the node MND and the local bit line LBL_pre. In addition, the potential of the global bit line GBLB is not illustrated.

Immediately before Time T21, the signal supplied to the word line WL, the signal MUX, the signal WE, and the signal RE are each set to the L level. The potential of the wiring SL is a predetermined potential (e.g., VSS). The signal SW0 is set to the L level, and the signal SW1 and the signal SW2 are each set to the H level. The signal BOOT1 and the signal BOOT2 are each set to the L level. The signal EQ is set to the H level, and the signal EQB is set to the L level. The signal CSEL is set to the L level. The potential of the wiring SAP and the potential of the wiring SAN are each set to (VDD−VSS)/2. The potential VPRE is set to (VDD−VSS)/2. The potential of the wiring CSL is set to a given fixed potential (e.g., VSS). At this time, the global bit line SA_GBL, the global bit line GBL, the global bit line SA_GBLB, and the global bit line GBLB are each precharged to (VDD−VSS)/2. The local bit line LBL is in an electrically floating state and retains VDD (a potential corresponding to data “1”) or VSS (a potential corresponding to data “0”). Note that in the description of the operations from Time T21 to Time T24, in the case where the potentials of the wirings and the signals are not particularly specified, the potentials at the previous time are maintained.

At Time T21, the signal EQ is set to the L level and the signal EQB is set to the H level. This stops precharging of the global bit line SA_GBL and the global bit line GBL and precharging of the global bit line SA_GBLB and the global bit line GBLB. Thus, the global bit line SA_GBL, the global bit line GBL, the global bit line SA_GBLB, and the global bit line GBLB are each brought into an electrically floating state.

At Time T22, the signal BOOT1 is set to the H level. Then, the potentials of the global bit line SA_GBL and the global bit line GBL are increased by capacitive coupling through the capacitor C1. That is, the potential of the global bit line SA_GBL becomes higher than the potential of the global bit line SA_GBLB.

At Time T23, the signal MUX and the signal RE are set to the H level. Then, each of the potentials of the global bit line SA_GBL and the global bit line GBL changes in accordance with the potential of the local bit line LBL. Thus, the potential of the local bit line LBL can be converted into a potential difference between the global bit line SA_GBL and the global bit line SA_GBLB.

At Time T24, the signal MUX and the signal RE are set to the L level. The potential of the wiring SAN is set to VSS, and the potential of the wiring SAP is set to VDD. Then, by the operation of the sense amplifier 55, a potential difference between the global bit line SA_GBL and the global bit line SA_GBLB generated by the above-described operation at Time T23 is amplified. Thus, the potentials of the global bit line SA_GBL and the global bit line SA_GBLB are each determined to be either VDD or VSS. That is, reading of data stored in the sensing circuit 35 functioning as a memory is completed.

The semiconductor device 10A has a structure in which the transistor M3 and the transistor M4 in the semiconductor device 10 are replaced with the capacitor C1 and the capacitor C2. Accordingly, the semiconductor device 10A can have improved area efficiency. At Time T22, the semiconductor device 10A changes the potentials of the global bit line SA_GBL and the global bit line GBL not by precharging but by capacitive coupling. Therefore, unlike the semiconductor device 10, the semiconductor device 10A does not need to generate the potential VPRE2. Thus, power consumption and the size of a circuit that supplies a potential to the semiconductor device 10A (e.g., a voltage generation circuit) can be reduced.

The semiconductor device of one embodiment of the present invention is not limited to the semiconductor device 10A described above. At least part of the structure examples, the operation examples, the drawings corresponding thereto, and the like described in this embodiment as an example can be combined with the other structure examples, the other operation examples, the other drawings, the other embodiments or example described in this specification and the like, and the like as appropriate.

### Embodiment 3

In this embodiment, a semiconductor device 10B of one embodiment of the present invention is described. The semiconductor device 10B is a variation example of the semiconductor device 10 described in Embodiment 1. Thus, in order to avoid repeated description, differences of the semiconductor device 10B from the semiconductor device 10 are mainly described. Note that the above description of the semiconductor device 10 can be referred to as appropriate.

### Structure Example of Semiconductor Device

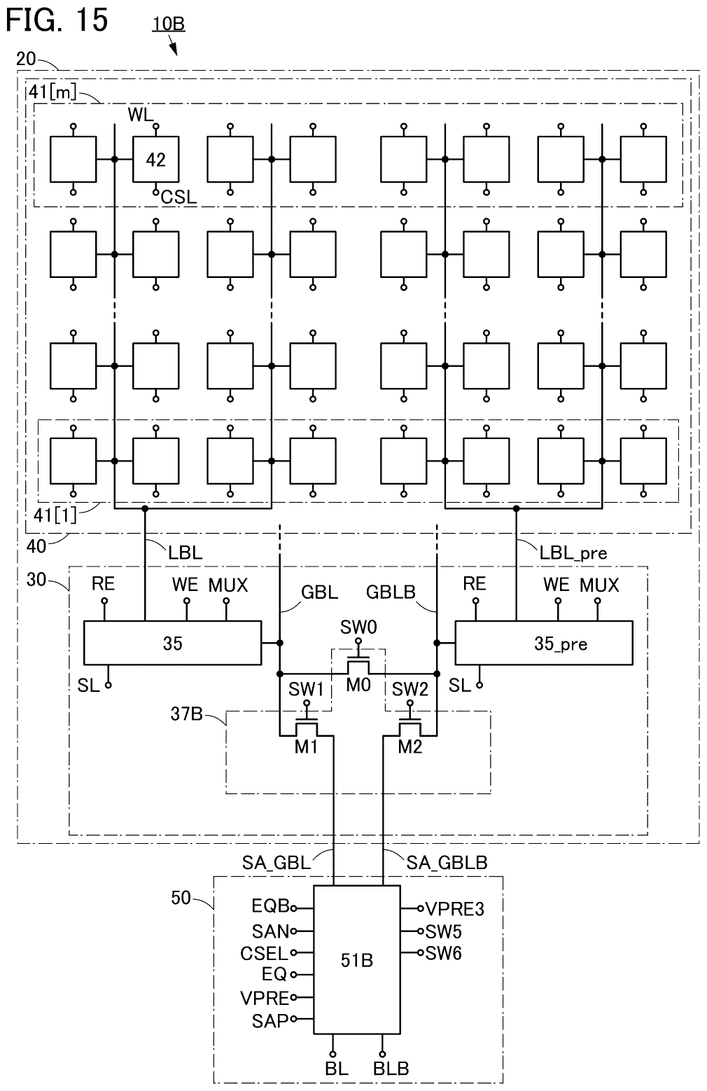

FIG. 15 is a circuit diagram illustrating a structure example of the semiconductor device 10B of one embodiment of the present invention.

The semiconductor device 10B is different from the semiconductor device 10 in including a switching circuit 37B instead of the switching circuit 37. The switching circuit 37B is different from the switching circuit 37 in not including the transistor M3 and the transistor M4. In addition, the semiconductor device 10B is different from the semiconductor device 10 in including a driver circuit 51B instead of the driver circuit 51.

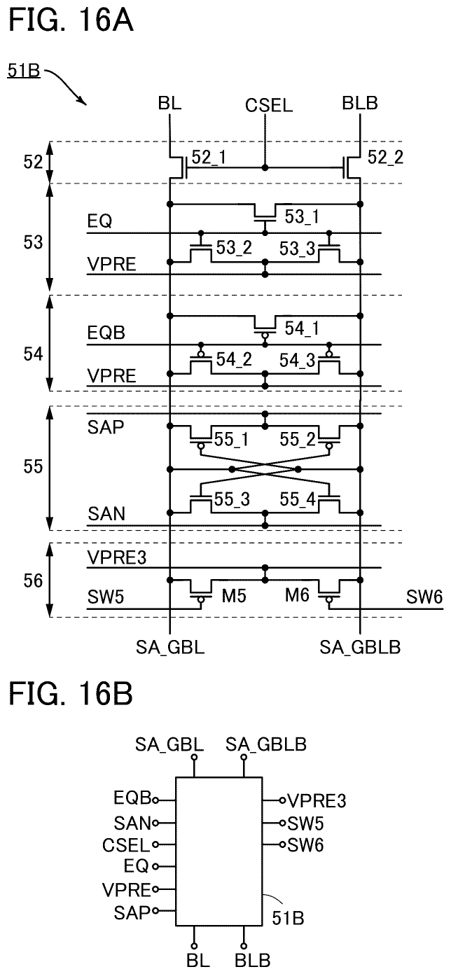

FIG. 16A is a circuit diagram illustrating the driver circuit 51B provided in the substrate 50 with circuit symbols. The driver circuit 51B includes a precharge circuit 56 in addition to the above-described components of the driver circuit 51. The precharge circuit 56 is electrically connected to the global bit line SA_GBL and the global bit line SA_GBLB. The driver circuit 51B has a function of precharging each of the global bit line SA_GBL and the global bit line SA_GBLB to a predetermined potential, in addition to the above-described function of the driver circuit 51.

The precharge circuit 56 has a function of precharging the global bit line SA_GBL to a potential VPRE3 in accordance with a signal SW5. Furthermore, the precharge circuit 56 has a function of precharging the global bit line SA_GBLB to the potential VPRE3 in accordance with a signal SW6.

Specifically, the precharge circuit 56 includes a transistor M5 and a transistor M6. Each of the transistor M5 and the transistor M6 is a p-channel transistor.

One of a source and a drain of the transistor M5 is electrically connected to the global bit line SA_GBL. The other of the source and the drain of the transistor M5 is electrically connected to a terminal to which the potential VPRE3 is supplied. The transistor M5 has a function of precharging the global bit line SA_GBL to the potential VPRE3 in accordance with the signal SW5.

One of a source and a drain of the transistor M6 is electrically connected to the global bit line SA_GBLB. The other of the source and the drain of the transistor M6 is electrically connected to the terminal to which the potential VPRE3 is supplied. The transistor M6 has a function of precharging the global bit line SA_GBLB to the potential VPRE3 in accordance with the signal SW6.

FIG. 16B illustrates a circuit block corresponding to the circuit diagram of the driver circuit 51B described with reference to FIG. 16A and corresponds to the circuit block of the driver circuit 51B illustrated in FIG. 15.

### Operation Example of Semiconductor Device

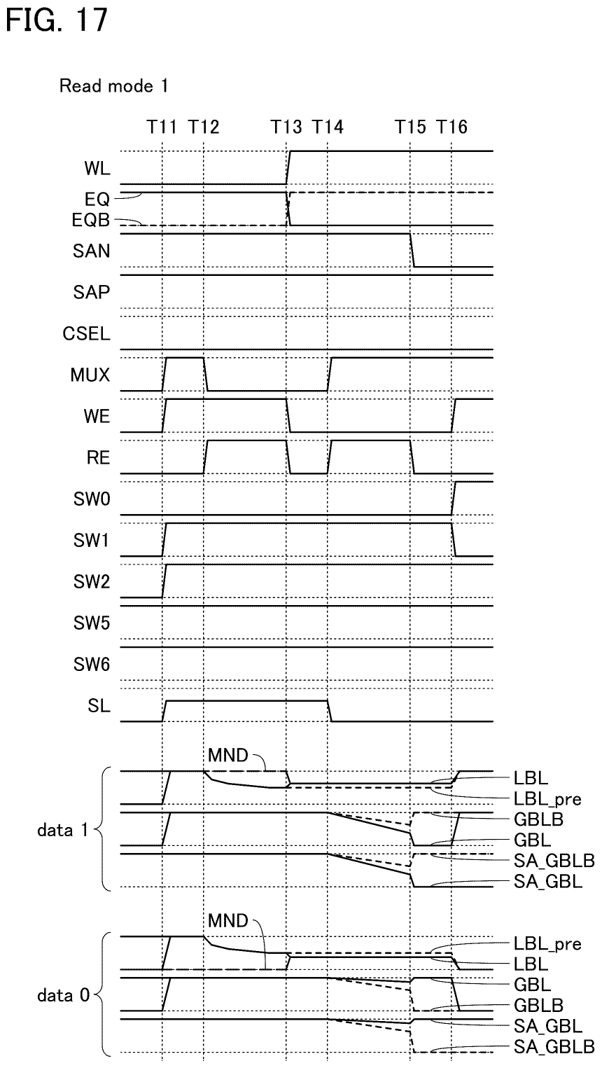

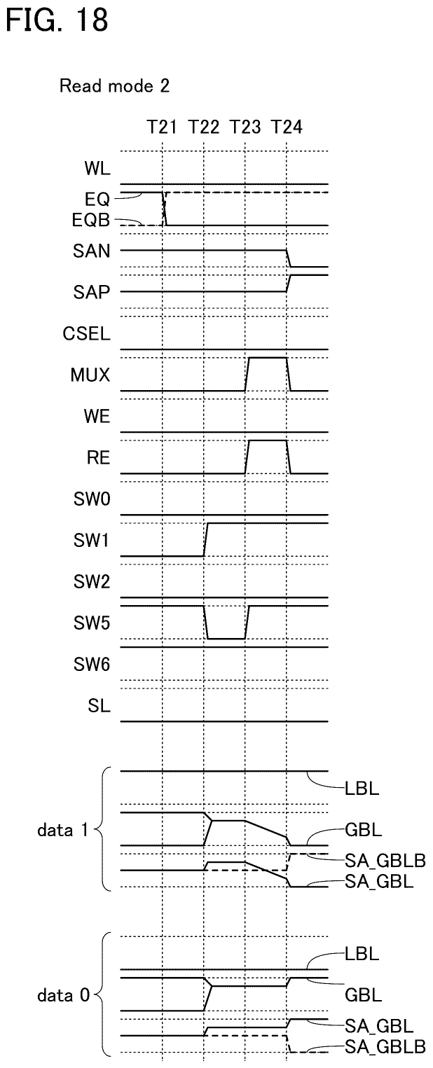

Next, operation examples of the semiconductor device 10B are described with reference to FIG. 17 and FIG. 18.

Examples of the method for driving the semiconductor device 10B of one embodiment of the present invention include the read mode 1 and the read mode 2, in a manner similar to that of the above-described semiconductor device 10.

An operation example in each of the read mode 1 and the read mode 2 is described below with reference to timing charts illustrated in FIG. 17 and FIG. 18. The timing charts illustrated in FIG. 17 and FIG. 18 are different from the timing charts illustrated in FIG. 6 and FIG. 7 in illustrating the potentials (the H level or the L level) of the signal SW5 and the signal SW6 instead of illustrating the potential of the signal SW3.

### [Read Mode 1]

FIG. 17 is a timing chart illustrating an operation example of the semiconductor device 10B in the read mode 1.

Immediately before Time T11 and at each of Time T11 to Time T13, the signal SW5 and the signal SW6 are in the H level. Signals other than the signal SW5 and the signal SW6 are similar to those in the timing chart illustrated in FIG. 6. Therefore, the above description of the read mode 1 of the semiconductor device 10 can be referred to as appropriate for the read mode 1 of the semiconductor device 10B; thus, the description thereof is omitted.

### [Read Mode 2]

FIG. 18 is a timing chart illustrating an operation example of the semiconductor device 10B in the read mode 2. Time T21 to Time T24 are a period for reading data. Note that in the read mode 2, data stored in the memory cell 42 is not related to data reading. In addition, the potential of the local bit line LBL_pre is not related to data reading either. Therefore, FIG. 18 does not illustrate the potentials of the node MND and the local bit line LBL_pre. In addition, the potential of the global bit line GBLB is not illustrated.

Immediately before Time T21, the signal supplied to the word line WL, the signal MUX, the signal WE, and the signal RE are each set to the L level. The potential of the wiring SL is a predetermined potential (e.g., VSS). The signal SW0, the signal SW1, and the signal SW2 are each set to the L level. The signal SW5 and the signal SW6 are each set to the H level. The signal EQ is set to the H level, and the signal EQB is set to the L level. The signal CSEL is set to the L level. The potential of the wiring SAP and the potential of the wiring SAN are each set to (VDD−VSS)/2. The potential VPRE is set to (VDD−VSS)/2 and the potential VPRE3 is set to a potential that exceeds (VDD−VSS)/2 but does not exceed VDD (e.g., VDD). The potential of the wiring CSL is set to a given fixed potential (e.g., VSS). At this time, the global bit line SA_GBL and the global bit line SA_GBLB are each precharged to (VDD−VSS)/2. The global bit line GBL and the global bit line GBLB are each in an electrically floating state, and the potentials thereof are VDD or VSS. The local bit line LBL is in an electrically floating state and retains VDD (a potential corresponding to data “1”) or VSS (a potential corresponding to data “0”). Note that in the description of the operations from Time T21 to Time T24, in the case where the potentials of the wirings and the signals are not particularly specified, the potentials at the previous time are maintained.

At Time T21, the signal EQ is set to the L level and the signal EQB is set to the H level. This stops precharging of the global bit line SA_GBL and the global bit line SA_GBLB. Thus, the global bit line SA_GBL and the global bit line SA_GBLB are each brought into an electrically floating state.

At Time T22, the signal SW1 is set to the H level. The signal SW5 is set to the L level. Then, the global bit line SA_GBL and the global bit line GBL are precharged to a potential between VDD and (VDD−VSS)/2. That is, the potential of the global bit line SA_GBL becomes higher than the potential of the global bit line SA_GBLB.

At Time T23, the signal SW5 is set to the H level. This stops precharging of the global bit line SA_GBL and the global bit line GBL. Then, the signal MUX and the signal RE are set to the H level. Then, each of the potentials of the global bit line SA_GBL and the global bit line GBL changes in accordance with the potential of the local bit line LBL. Thus, the potential of the local bit line LBL can be converted into a potential difference between the global bit line SA_GBL and the global bit line SA_GBLB.

At Time T24, the signal MUX and the signal RE are set to the L level. The potential of the wiring SAN is set to VSS, and the potential of the wiring SAP is set to VDD. Then, by the operation of the sense amplifier 55, a potential difference between the global bit line SA_GBL and the global bit line SA_GBLB generated by the above-described operation at Time T23 is amplified. Thus, the potentials of the global bit line SA_GBL and the global bit line SA_GBLB are each determined to be either VDD or VSS. That is, reading of data stored in the sensing circuit 35 functioning as a memory is completed.

The semiconductor device 10B can be regarded as having a structure in which the transistor M3 and the transistor M4 each being the OS transistor provided in the layer 30 in the semiconductor device 10 are replaced with the transistor M5 and the transistor M6 each being the Si transistor provided in the substrate 50. Accordingly, the semiconductor device 10B can have improved area efficiency.

The semiconductor device of one embodiment of the present invention is not limited to the semiconductor device 10B described above. At least part of the structure examples, the operation examples, the drawings corresponding thereto, and the like described in this embodiment as an example can be combined with the other structure examples, the other operation examples, the other drawings, the other embodiments or example described in this specification and the like, and the like as appropriate.

### Embodiment 4

In this embodiment, a memory device of one embodiment of the present invention is described. The memory device described in this embodiment can suitably use at least part of the semiconductor device 10, the semiconductor device 10A, the semiconductor device 10B, or the memory device 300 described above in Embodiment 1 to Embodiment 3. Therefore, the above description can be referred to as appropriate.

### Structure Example A of Memory Device

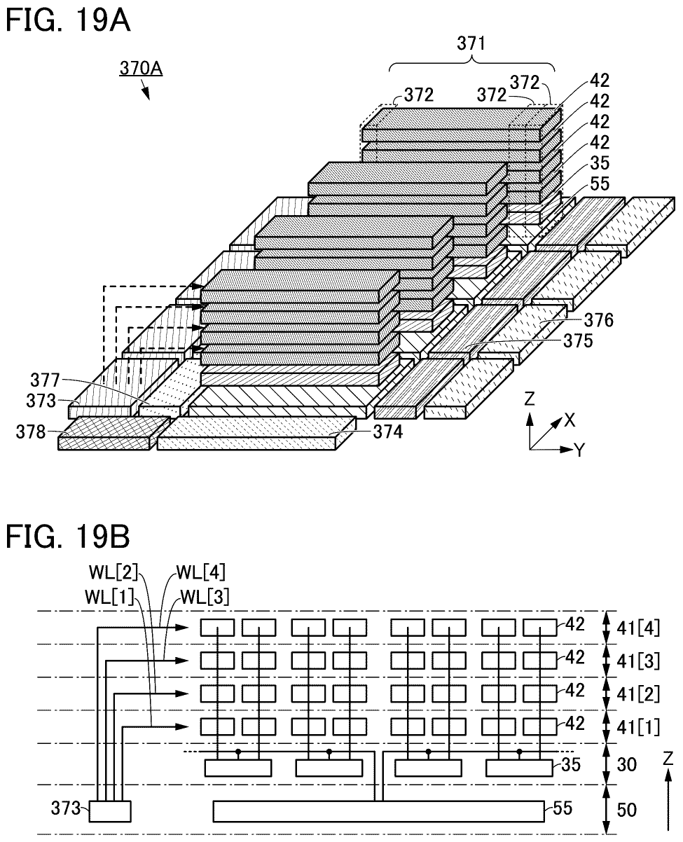

FIG. 19A and FIG. 19B are schematic diagrams illustrating a structure example of a memory device 370A of one embodiment of the present invention.

Note that in the schematic diagram illustrated in FIG. 19A, the X direction, the Y direction, and the Z direction are defined to describe the arrangement of components included in the memory device 370A. The X direction, the Y direction, and the Z direction are perpendicular or substantially perpendicular to each other. In addition, the components included in the memory device 370A are illustrated apart from each other for easy understanding of the arrangement of the components.

The memory device 370A can include one or a plurality of memory array portions 371. FIG. 19A illustrates an example where four memory array portions 371 are arranged in the X direction in the memory device 370A.

The memory array portion 371 can include one or a plurality of memory portions 372. FIG. 19A illustrates an example where the plurality of memory portions 372 are arranged in the Y direction in the memory array portion 371.

Note that the memory device 300 described above (see FIG. 9A) can be suitably provided in the memory array portion 371. In that case, at least part of the semiconductor device 10 (see FIG. 1), the semiconductor device 10A (see FIG. 12), or the semiconductor device 10B (see FIG. 15) described above can be suitably provided in the memory portion 372.

That is, by using the semiconductor device 10 illustrated in FIG. 1 to FIG. 5, the memory portion 372 can include, for example, the sense amplifier 55 provided in the substrate 50, the sensing circuit 35 provided in the layer 30 stacked in the Z direction over the substrate 50, and the memory cells 42 provided in each of the plurality of layers (the layer 41[1] to the layer 41[m](m is an integer greater than or equal to 2)) stacked in the Z direction over the layer 30. In other words, in each of the layer 41[1] to the layer 41[m] stacked in the Z direction in the memory portion 372, the plurality of memory cells 42 are arranged in a matrix in the X direction and the Y direction. FIG. 19A illustrates an example including four layers in which the memory cells 42 are provided (the layer 41[1] to the layer 41[4]).

Note that the memory portion 372 may or may not be provided with the switching circuit 37 in the layer 30. In the case where the switching circuit 37 is not provided in the memory portion 372, for example, the global bit line SA_GBL and the global bit line GBL are short-circuited and the global bit line SA_GBLB and the global bit line GBLB are short-circuited in the semiconductor device 10 illustrated in FIG. 1.

In some cases, the sensing circuit 35 need not be provided in the memory portion 372. In the case where the sensing circuit 35 is not provided in the memory portion 372, for example, the global bit line GBL and the local bit line LBL are short-circuited and the global bit line GBLB and the local bit line LBL_pre are short-circuited in the semiconductor device 10 illustrated in FIG. 1.

As illustrated in FIG. 19A, the memory device 370A includes word line driver portions 373, a column driver portion 374, sense amplifier driver portions 375, sensing circuit driver portions 376, data sense amplifier portions 377, and a memory controller portion 378, around the memory array portions 371. FIG. 19A illustrates an example where four word line driver portions 373, four sense amplifier driver portions 375, four sensing circuit driver portions 376, and four data sense amplifier portions 377 are provided for the four corresponding memory array portions 371. Note that one word line driver portion 373, one sense amplifier driver portion 375, one sensing circuit driver portion 376, and one data sense amplifier portion 377 may be provided for the four memory array portions 371, for example.

The word line driver portions 373, the column driver portion 374, the sense amplifier driver portions 375, the sensing circuit driver portions 376, the data sense amplifier portions 377, and the memory controller portion 378 can each be provided in the substrate 50 and can each be formed using a Si transistor whose channel is formed in the substrate 50.

The word line driver portion 373 has a function of selecting any one of the layer 41[1] to the layer 41[m] stacked in the Z direction, selecting any one of the plurality of memory cells 42 arranged in the X direction, and supplying a signal to the word line WL corresponding to the selected memory cell 42. The operation of writing or reading data to/from the memory cell 42 is controlled by the signal supplied to the word line WL.

FIG. 19A illustrates the signal supply from the word line driver portion 373 to the word lines WL corresponding to the memory cells 42 provided in the layer 41[1] to the layer 41[4] with dashed arrows. FIG. 19B illustrates the signal supply from the word line driver portion 373 to the word lines WL corresponding to the memory cells 42 provided in the layer 41[1] to the layer 41[4] with solid arrows, with the word lines shown with the reference numerals WL[1] to WL[4]. That is, the word line driver portion 373 can select any one of the layer 41[1] to the layer 41[4] and supply a signal to the corresponding one of the word line WL[1] to the word line WL[4]. For example, in the case where the layer 41[1] is selected, a signal is supplied to the corresponding word line WL[1]. Similarly, in the case where the layer 41[4] is selected, for example, a signal is supplied to the corresponding word line WL[4].

The column driver portion 374 has a function of selecting any one of the plurality of semiconductor devices 10 arranged in the Y direction. For example, the column driver portion 374 can output the signal CSEL in the above-described semiconductor device 10. That is, the column driver portion 374 can supply the signal CSEL to any one of the plurality of semiconductor devices 10 arranged in the Y direction to select the corresponding semiconductor device 10.

The sense amplifier driver portion 375 has a function of controlling the operation of the sense amplifier 55. For example, the sense amplifier driver portion 375 can output the signal EQ and the signal EQB in the above-described semiconductor device 10. In addition, the sense amplifier driver portion 375 can control the potentials supplied to the wiring SAP and the wiring SAN.

The sensing circuit driver portion 376 has a function of controlling the operation of the sensing circuit 35. For example, the sensing circuit driver portion 376 can output the signal MUX, the signal WE, and the signal RE in the above-described semiconductor device 10. In addition, the sensing circuit driver portion 376 can control the potential supplied to the wiring SL.

The data sense amplifier portion 377 has a function of writing or reading data to/from the memory cell 42 selected by the word line driver portion 373 and the column driver portion 374.

The memory controller portion 378 has a function of controlling the operation of each of the word line driver portion 373, the column driver portion 374, the sense amplifier driver portion 375, the sensing circuit driver portion 376, the data sense amplifier portion 377, and the memory controller portion 378.

### Structure Example B of Memory Device

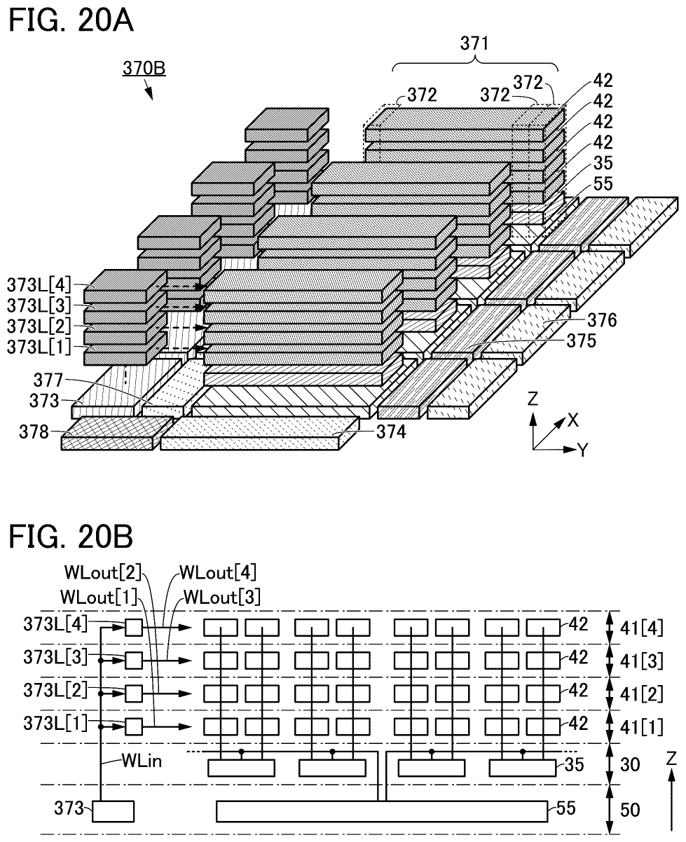

FIG. 20A and FIG. 20B are schematic views illustrating a structure example of a memory device 370B of one embodiment of the present invention. The memory device 370B is a variation example of the above-described memory device 370A. Thus, in order to avoid repeated description, differences of the memory device 370B from the memory device 370A are mainly described. Note that the above description of the memory device 370A can be referred to as appropriate.

In the memory device 370B, in addition to the above-described structure of the memory device 370A, a layer selection driver portion 373L[1] to a layer selection driver portion 373L[m] are provided in the layer 41[1] to the layer 41[m], respectively. The layer selection driver portion 373L[1] to the layer selection driver portion 373L[m] are placed to overlap with each other over the word line driver portion 373 in the Z direction. Note that FIG. 20A and FIG. 20B illustrate an example where the layer selection driver portion 373L[1] to the layer selection driver portion 373L[4] are provided in the layer 41[1] to the layer 41[4], respectively.

The word line driver portion 373 has a function of selecting any one of the layer 41[1] to the layer 41[m] stacked in the Z direction with the use of the layer selection driver portion 373L[1] to the layer selection driver portion 373L[m], selecting any one of the plurality of memory cells 42 arranged in the X direction, and supplying a signal to the word line WL corresponding to the selected memory cell 42.

That is, a signal for selecting any one of the plurality of memory cells 42 arranged in the X direction is output from the word line driver portion 373 and input to each of the layer selection driver portion 373L[1] to the layer selection driver portion 373L[m]. In addition, the signal is output from any one of the layer selection driver portion 373L[1] to the layer selection driver portion 373L[m].

FIG. 20A illustrates the signal supply from the word line driver portion 373 to each of the layer selection driver portion 373L[1] to the layer selection driver portion 373L[4] that are respectively provided in the layer 41[1] to the layer 41[4] with solid arrows, with the word line WLin shown with the reference numeral. FIG. 20B illustrates the signal supply from the layer selection driver portion 373L[1] to the layer selection driver portion 373L[4] to the word lines WL corresponding to the memory cells 42 provided in their respective layers 41[1] to 41[4] with solid arrows, with the word lines shown with the reference numerals WLout[1] to WLout[4]. That is, the word line driver portion 373 can supply a signal, via any one of the layer selection driver portion 373L[1] to the layer selection driver portion 373L[4] provided respectively in the layer 41[1] to the layer 41[4], to the corresponding one of the word line WLout[1] to the word line WLout[4].

### [Layer Selection Driver]

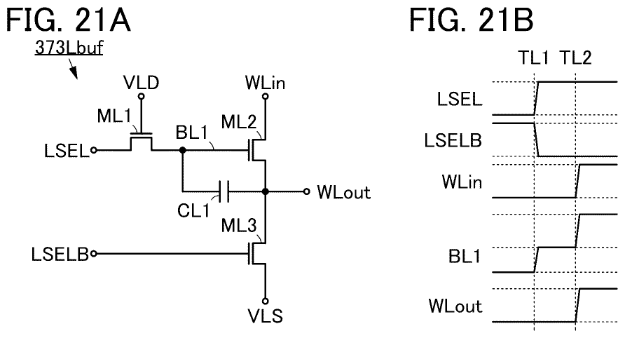

FIG. 21A is a circuit diagram illustrating a structure example of a layer selection driver 373Lbuf Each of the layer selection driver portion 373L[1] to the layer selection driver portion 373L[m] includes one or a plurality of layer selection drivers 373Lbuf.

The layer selection driver 373Lbuf includes a transistor ML1, a transistor ML2, a transistor ML3, and a capacitor CL1. Each of the transistor ML1 to the transistor ML3 is an OS transistor.

A gate of the transistor ML2 is electrically connected to one of a source and a drain of the transistor ML1 and one terminal of the capacitor CL1. One of a source and a drain of the transistor ML2 is electrically connected to one of a source and a drain of the transistor ML3, the other terminal of the capacitor CL1, and the word line WLout. The other of the source and the drain of the transistor ML2 is electrically connected to the word line WLin. A gate of the transistor ML1 is electrically connected to a wiring to which a potential VLD is supplied. The other of the source and the drain of the transistor ML1 is electrically connected to a wiring to which a signal LSEL is supplied. A gate of the transistor ML3 is electrically connected to a wiring to which a signal LSELB is supplied. The other of the source and the drain of the transistor ML3 is electrically connected to a wiring to which a potential VLS is supplied. Note that a region where the gate of the transistor ML2, the one of the source and the drain of the transistor ML1, and the one terminal of the capacitor CL1 are electrically connected to one another is referred to as a node BL1 in some cases.

Note that the structure of the layer selection driver 373Lbuf is not limited to the structure example illustrated in FIG. 21A. For example, the other terminal of the capacitor CL1 may be electrically connected to the other of the source and the drain of the transistor ML2. Alternatively, the capacitor CL1 may be omitted, for example. In that case, the parasitic capacitance between the gate of the transistor ML2 and the one of the source and the drain of the transistor ML2 can function as the capacitor CL1.

The layer selection driver 373Lbuf has a function of outputting, to the word line WLout, either a signal supplied to the word line WLin or the potential VLS in accordance with the signal LSEL and the signal LSELB.

FIG. 21B is a timing chart illustrating an operation example of the layer selection driver 373Lbuf.

The timing chart in FIG. 21B illustrates the potentials (H level and L level) of the signal LSEL, the signal LSELB, and the signal supplied to the word line WLin at each operation time. In addition, changes in the potentials of the node B1 and the word line WLout are illustrated.

Note that in the following description of the operation example, the potential VLD is assumed to be equal to the H level of the signal LSEL and the signal LSELB. The potential VLS is assumed to be equal to the L level of the signal LSEL and the signal LSELB.

Immediately before Time TL1, the signal LSEL is set to the L level and the signal LSELB is set to the H level. At this time, since the transistor ML1 is in a conduction state, the potential of the node BL1 becomes the L level. Thus, the transistor ML2 is in a non-conduction state and the transistor ML3 is in a conduction state. Thus, the potential of the word line WLout becomes the L level (potential VLS) regardless of whether the signal supplied to the word line WLin is at the H level or the L level.

At Time TL1, the signal LSEL is brought to the H level and the signal LSELB is brought to the L level. At this time, the potential of the node BL1 increases to a potential obtained by subtracting the threshold voltage of the transistor ML1 from the H level (the potential VLD), and the transistor ML1 is brought to a non-conduction state. Then, the transistor ML2 is brought to a conduction state and the transistor ML3 is brought to a non-conduction state. Thus, the potential of the word line WLout becomes the L level (the signal supplied to the word line WLin at Time TL1).

At Time TL2, the signal supplied to the word line WLin is brought to the H level. Then, a current flows from the word line WLin to the word line WLout through the transistor ML2, whereby the potential of the word line WLout increases. At this time, since the transistor ML1 is in the non-conduction state, the potential of the node BL1 also increases owing to capacitive coupling by the capacitor CL1. Thus, a potential difference between the gate and the source of the transistor ML2 is maintained, that is, the conduction state of the transistor ML2 is maintained. Thus, the potential of the word line WLout becomes the H level (the signal supplied to the word line WLin at Time TL2).

In this manner, the layer selection driver 373Lbuf forms a bootstrap circuit provided with the capacitor CL1 between the gate and the source of the transistor ML2, whereby the conduction state of the transistor ML2 is maintained when the signal supplied to the word line WLin becomes the H level; thus, the H level can be output to the word line WLout. Note that the capacitor CL1 is sometimes referred to as a “bootstrap capacitor”.

The memory device 370B can control the signal LSEL and the signal LSELB supplied to the layer selection driver 373Lbuf included in each of the layer selection driver portion 373L[1] to the layer selection driver portion 373L[m] to select any one of the layer selection driver portion 373L[1] to the layer selection driver portion 373L[m] and output the signal supplied to the word line WLin to the word line WLout.

For example, when the signal LSEL and the signal LSELB supplied to the layer selection driver 373Lbuf included in the layer selection driver portion 373L[1] are set to the H level and the L level, respectively, and the signals LSEL and the signals LSELB supplied to the layer selection drivers 373Lbuf included in the layer selection driver portion 373L[2] to the layer selection driver portion 373L[m] are set to the L level and the H level, respectively, the signal supplied from the word line driver portion 373 to the word line WLin is output to the word line WLout[1] through the layer selection driver 373Lbuf included in the layer selection driver portion 373L[1].

The memory device 370B has an effect superior to that of the memory device 370A in the following point, for example.

In the memory device 370A, m word lines extending from the substrate 50 to the layer 41[1] to the layer 41[m] need to be provided; while in the memory device 370B, one word line extending from the substrate 50 to the layer 41[1] to the layer 41[m] is provided. Furthermore, in the memory device 370A, m buffers need to be provided in the substrate 50 to supply signals to the respective m word lines; while in the memory device 370B, a buffer is provided in each of the layer selection driver portion 373L[1] to the layer selection driver portion 373L[m] provided in the layer 41[1] to the layer 41[m], respectively. For example, the transistor ML2 and the transistor ML3 may have a function of a buffer in the layer selection driver 373Lbuf included in each of the layer selection driver portion 373L[1] to the layer selection driver portion 373L[m].

Thus, in the memory device 370B, it is possible to suppress an increase in the area of the word line driver portion 373 due to an increase in the number of layers 41[1] to 41[m] in which the memory cells 42 are provided. That is, in the memory device 370B, the number of layers 41[1] to 41[m] in which the memory cells 42 are provided can be increased without an increase in area overhead. In other words, in the memory device 370B, the density (memory density) of the memory cells 42 can be increased without an increase in area overhead.

### Structure Example of Memory Cell

The memory device of one embodiment of the present invention can include memory cells with a variety of structures.

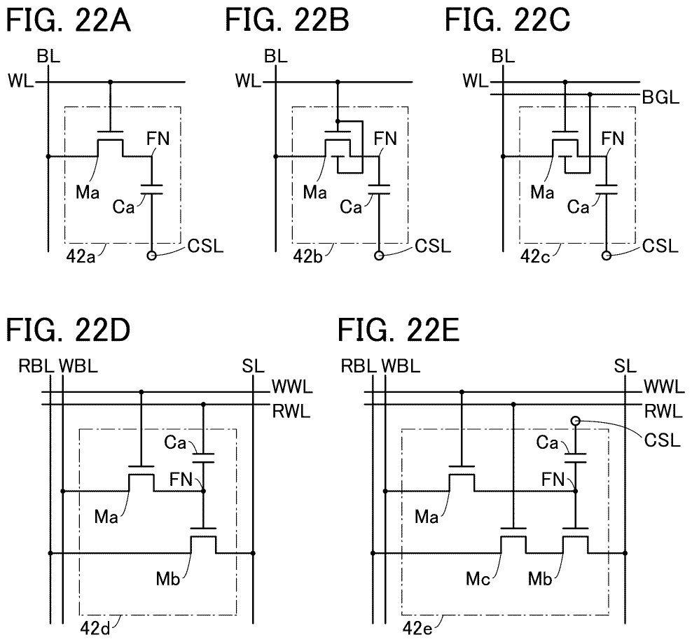

FIG. 22A to FIG. 22E are diagrams illustrating examples of a circuit structure that the memory cell 42 can have and that can be used in the memory device of one embodiment of the present invention.

A memory cell 42a illustrated in FIG. 22A includes a transistor Ma and a capacitor Ca. One of a source and a drain of the transistor Ma is electrically connected to one terminal of the capacitor Ca. The other of the source and the drain of the transistor Ma is electrically connected to the bit line BL. A gate of the transistor Ma is electrically connected to the word line WL. The other terminal of the capacitor Ca is electrically connected to the wiring CSL. The transistor Ma is an OS transistor. The OS transistor has a feature of an extremely low off-state current. Thus, bringing the transistor Ma into a non-conduction state allows a charge retention node FN to retain charge corresponding to data. Thus, the refresh rate of the data corresponding to the charge retained in the charge retention node FN can be reduced.

A memory cell 42b illustrated in FIG. 22B is a variation example of the memory cell 42a illustrated in FIG. 22A. The transistor Ma is different from the transistor Ma in FIG. 22A in that the transistor Ma includes a back gate, and the back gate and the gate are electrically connected to each other so that a potential of the word line WL is applied from both the back gate and the gate. Such a structure enables an increase in the amount of current flowing between the source and the drain when the transistor Ma is brought into a conduction state.

A memory cell 42c illustrated in FIG. 22C is a variation example of the memory cell 42a illustrated in FIG. 22A. The transistor Ma is different from the transistor Ma in FIG. 22A in that the transistor Ma includes a back gate, and the back gate and a back gate line BGL are electrically connected to each other so that a potential different from that of the gate is applied to the back gate. Such a structure enables control of the threshold voltage of the transistor Ma. Accordingly, the amount of current flowing between the source and the drain of the transistor Ma can be changed.

A memory cell 42d illustrated in FIG. 22D includes the transistor Ma, a transistor Mb, and the capacitor Ca. The one of the source and the drain of the transistor Ma is electrically connected to a gate of the transistor Mb and the one terminal of the capacitor Ca. The other of the source and the drain of the transistor Ma is electrically connected to a write bit line WBL. The gate of the transistor Ma is electrically connected to a write word line WWL. The other terminal of the capacitor Ca is electrically connected to a read word line RWL. One of a source and a drain of the transistor Mb is electrically connected to a read bit line RBL. The other of the source and the drain of the transistor Mb is electrically connected to the wiring SL. Although an n-channel transistor is illustrated as the transistor Mb, a p-channel transistor may also be employed. Bringing the transistor Ma into a non-conduction state allows the charge retention node FN to retain charge corresponding to data. The transistor Mb is an OS transistor. Note that the transistor Mb may be a Si transistor. Note that the transistor Ma can also have a structure similar to that of the above-described transistor Ma illustrated in FIG. 22B or FIG. 22C.

A memory cell 42e illustrated in FIG. 22E includes the transistor Ma, the transistor Mb, a transistor Mc, and the capacitor Ca. The one of the source and the drain of the transistor Ma is electrically connected to the gate of the transistor Mb and the one terminal of the capacitor Ca. The other of the source and the drain of the transistor Ma is electrically connected to the write bit line WBL. The gate of the transistor Ma is electrically connected to the write word line WWL. The other terminal of the capacitor Ca is electrically connected to the wiring CSL. The one of the source and the drain of the transistor Mb is electrically connected to one of a source and a drain of the transistor Mc. The other of the source and the drain of the transistor Mb is electrically connected to the wiring SL. A gate of the transistor Mc is electrically connected to the read word line RWL. The other of the source and the drain of the transistor Mc is electrically connected to the read bit line RBL. Although an n-channel transistor is illustrated as the transistor Mc, a p-channel transistor may also be employed. Bringing the transistor Ma into a non-conduction state allows the charge retention node FN to retain charge corresponding to data. The transistor Mb and the transistor Mc are each an OS transistor. Note that at least one of the transistor Mb and the transistor Mc may be a Si transistor. Note that the transistor Ma can also have a structure similar to that of the above-described transistor Ma illustrated in FIG. 22B or FIG. 22C.

Note that the structures of the memory cells illustrated in FIG. 22A to FIG. 22C are each referred to as a DOSRAM (registered trademark). The DOSRAM is an abbreviation for a Dynamic Oxide Semiconductor RAM (Random Access Memory). In the structure using the DOSRAM, when one of a source and a drain of an OS transistor and one terminal of a capacitor are electrically connected to each other, charge accumulated in the one terminal of the capacitor can be retained when the OS transistor is brought into a non-conduction state. A structure using the DOSRAM is particularly effective in the case where the stored data is increased. For example, as compared to a structure where memory cells in the memory circuit are formed with an SRAM (Static RAM), the structure using the DOSRAM can inhibit an increase in a circuit area. In particular, the structures of the memory cells illustrated in FIG. 22A to 22C are effective in inhibiting an increase in the circuit area.

The structures of the memory cells illustrated in FIG. 22D and FIG. 22E are each referred to as a NOSRAM (registered trademark). The NOSRAM is an abbreviation for a Nonvolatile Oxide Semiconductor RAM. In the structure using the NOSRAM, when one of a source and a drain of an OS transistor for writing and a gate of a transistor for reading are electrically connected to each other, charge accumulated in the gate of the transistor for reading can be retained when the OS transistor for writing is brought into a non-conduction state. The structure using the NOSRAM may be used as a nonvolatile memory. For example, by bringing the OS transistor for writing into a non-conduction state, the NOSRAM can retain data even in a power gating state.

Note that the circuit structures illustrated in FIG. 22A to FIG. 22E are merely examples, and any other structures can be employed as long as one embodiment of the present invention can be realized.

### Layout Example

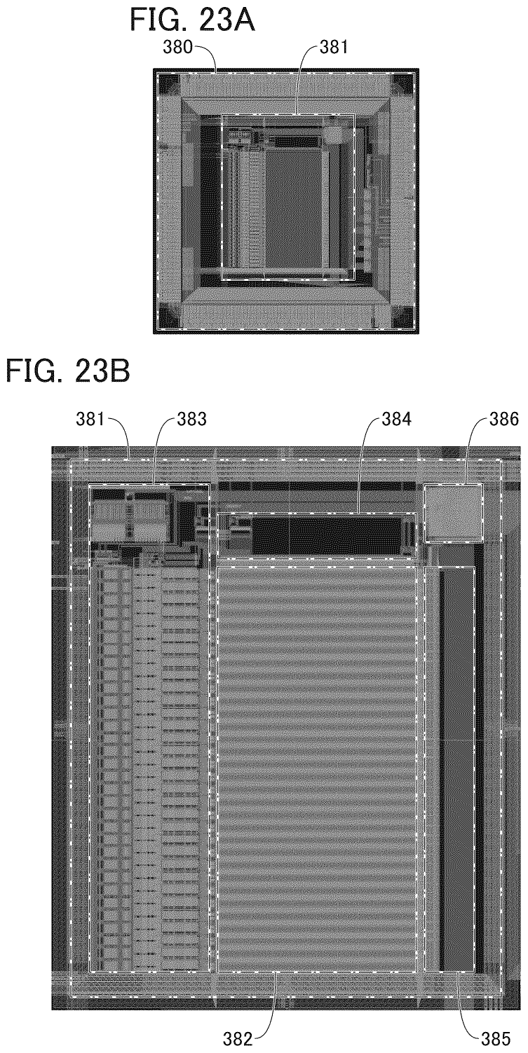

FIG. 23A and FIG. 23B are planar layout views illustrating a structure example of a memory device of one embodiment of the present invention.

In the planar layout view illustrated in FIG. 23A, a module 381 is placed in a 4 mm square chip 380, as an example. The module 381 can include the memory device 370A or the memory device 370B, for example. An interface for transmitting a signal between the module 381 and the outside of the chip 380 is placed around the module 381, for example. The interface is, for example, an I2C (Inter-Integrated Circuit) or an LVDS (Low voltage differential signaling).

The planar layout view in FIG. 23B illustrates an example of the module 381 including the memory device 370A or the memory device 370B, where a region 382, a region 383, a region 384, a region 385, and a region 386 are placed in the module 381. In the region 382, the memory array portion 371 including the memory cells 42, the sensing circuit 35, and the sense amplifier 55 is placed, for example. In the region 383, the word line driver portion 373, the sense amplifier driver portion 375, and the sensing circuit driver portion 376 are placed, for example. In the memory device 370B, the layer selection driver 373Lbuf is also placed in the region 383. The column driver portion 374 is placed in the region 384. The data sense amplifier portion 377 is placed in the region 385. The memory controller portion 378 is placed in the region 386.

In the region 382 of the memory device 370A or the memory device 370B, the plurality of memory cells 42 can be stacked. Thus, the density (memory density) of the memory cells 42 can be increased in the memory device 370A or the memory device 370B.

The memory device of one embodiment of the present invention is not limited to the memory device 370A and the memory device 370B described above. At least part of the structure examples, the operation examples, the drawings corresponding thereto, and the like described in this embodiment as an example can be combined with the other structure examples, the other operation examples, the other drawings, the other embodiments or example described in this specification and the like, and the like as appropriate.

### Embodiment 5

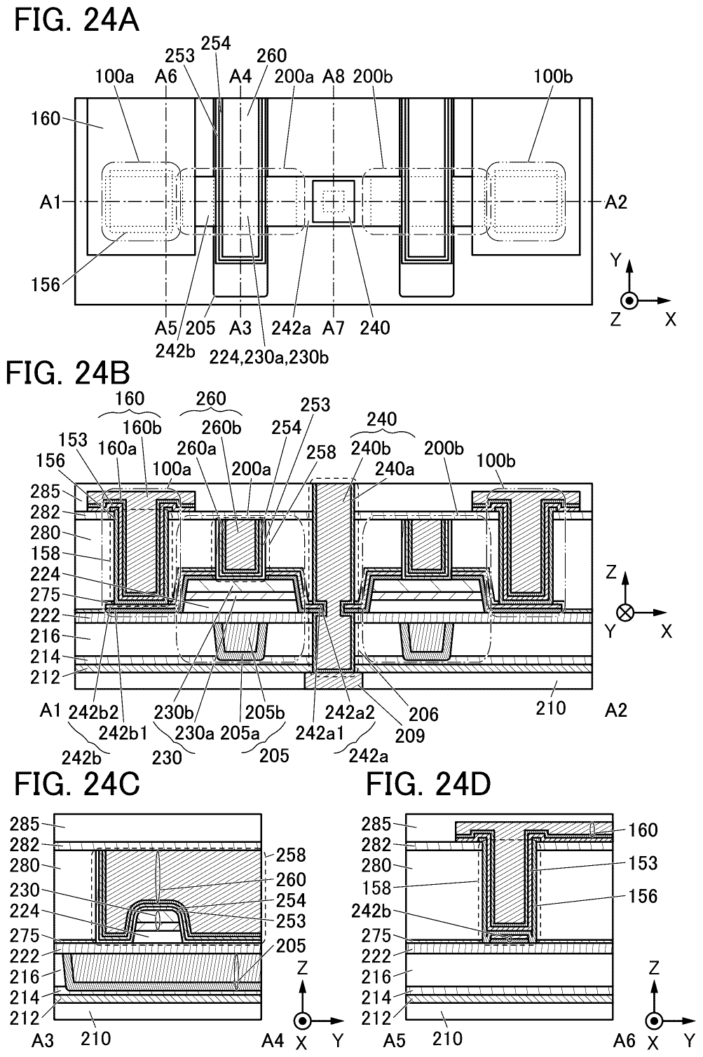

In this embodiment, an example of a semiconductor device of one embodiment of the present invention is described with reference to FIG. 24. The semiconductor device of one embodiment of the present invention includes a transistor and a capacitor.

Note that the semiconductor device described in this embodiment can be suitably used for the memory cell 42 described in Embodiment 1. That is, the transistor and the capacitor included in the semiconductor device respectively correspond to the transistor 43 and the capacitor 44 included in the memory cell 42.

A structure of the semiconductor device including the transistor and the capacitor is described with reference to FIG. 24. FIG. 24A to FIG. 24D are a top view and cross-sectional views of a semiconductor device including a transistor 200a, a transistor 200b, a capacitor 100a, and a capacitor 100b. FIG. 24A is a top view of the semiconductor device. FIG. 24B to FIG. 24D are cross-sectional views of the semiconductor device. Here, FIG. 24B is a cross-sectional view of a portion indicated by a dashed-dotted line A1-A2 in FIG. 24A, and is also a cross-sectional view of the transistor 200a, the transistor 200b, the capacitor 100a, and the capacitor 100b in the channel length direction. FIG. 24C is a cross-sectional view of a portion indicated by a dashed-dotted line A3-A4 in FIG. 24A, and is also a cross-sectional view of the transistor 200a in the channel width direction. FIG. 24D is a cross-sectional view of a portion indicated by a dashed-dotted line A5-A6 in FIG. 24A, and is also a cross-sectional view of the capacitor 100a in the channel width direction. Note that for clarity of the drawing, some components are omitted in the top view of FIG. 24A.

The X direction shown in FIG. 24A is parallel to the channel length direction of the transistor 200a and the channel length direction of the transistor 200b, the Y direction is perpendicular to the X direction, and the Z direction is perpendicular to the X direction and the Y direction. Note that the X direction, the Y direction, and the Z direction shown in FIG. 24A are also shown in FIG. 24B to FIG. 24D.

The semiconductor device of one embodiment of the present invention includes an insulator 214 over a substrate (not illustrated); the transistor 200a, the transistor 200b, the capacitor 100a, and the capacitor 100b over the insulator 214; an insulator 280 over an insulator 275 provided for the transistor 200a and the transistor 200b; an insulator 282 over the insulator 280; an insulator 285 over the capacitor 100a, the capacitor 100b, and the insulator 282; and a conductor 240 (a conductor 240a and a conductor 240b). The insulator 214, the insulator 280, the insulator 282, and the insulator 285 each function as an interlayer film. As illustrated in FIG. 24B, at least part of each of the transistor 200a, the transistor 200b, the capacitor 100a, and the capacitor 100b is placed to be embedded in the insulator 280.

Here, each of the transistor 200a and the transistor 200b includes an oxide 230 functioning as a semiconductor layer, a conductor 260 functioning as a first gate (also referred to as a top gate) electrode, a conductor 205 functioning as a second gate (also referred to as a back gate) electrode, a conductor 242b functioning as one of a source electrode and a drain electrode, and a conductor 242a functioning as the other of the source electrode and the drain electrode. An insulator 253 and an insulator 254 functioning as a first gate insulator are also included. An insulator 222 and an insulator 224 functioning as a second gate insulator are also included. Note that the gate insulator is also referred to as a gate insulating layer or a gate insulating film in some cases.

Note that each of the insulator 282 and the insulator 222 preferably has a function of capturing or fixing hydrogen, for example. Thus, hydrogen contained in the insulator 280, the insulator 224, the insulator 253, the insulator 254, and the like can be captured or fixed by the insulator 282 or the insulator 222, for example.

The transistor 200a and the transistor 200b have the same structure. Thus, hereinafter, in describing matters common to the transistor 200a and the transistor 200b, the alphabets are omitted from the reference numerals and the term “transistor 200” is used in some cases.

The first gate electrode and the first gate insulating film are placed inside an opening 258 formed in the insulator 280 and the insulator 275. That is, the conductor 260, the insulator 254, and the insulator 253 are placed inside the opening 258.

The capacitor 100a and the capacitor 100b each include a conductor 156 functioning as a lower electrode, an insulator 153 functioning as a dielectric, and a conductor 160 functioning as an upper electrode. In other words, the capacitor 100a and the capacitor 100b each form a MIM (Metal-Insulator-Metal) capacitor.

The capacitor 100a and the capacitor 100b have the same structure. Thus, hereinafter, in describing matters common to the capacitor 100a and the capacitor 100b, the alphabets are omitted from the reference numerals and the term “capacitor 100” is used in some cases.

Part of each of the upper electrode, the dielectric, and the lower electrode of the capacitor 100 are placed inside an opening 158 formed in the insulator 282, the insulator 280, and the insulator 275. That is, the conductor 160, the insulator 153, and the conductor 156 are placed inside the opening 158.

The semiconductor device of one embodiment of the present invention also includes the conductor 240 (the conductor 240a and the conductor 240b) that functions as a plug (can also be referred to as a connection electrode) by being electrically connected to the transistor 200. The conductor 240 is placed inside an opening 206 formed in the insulator 280 and the like, for example. The conductor 240 includes a region in contact with part of the top surface and part of the side surface of the conductor 242a.

The semiconductor device of one embodiment of the present invention includes an insulator 210 and a conductor 209 between the substrate (not illustrated) and the insulator 214. The conductor 209 is placed to be embedded in the insulator 210. The conductor 209 includes a region in contact with the conductor 240.

The semiconductor device of one embodiment of the present invention may include an insulator 212 between the insulator 214 and each of the insulator 210 and the conductor 209.

The semiconductor device including the transistor 200 and the capacitor 100 described in this embodiment can be used as a memory cell of the memory device. In that case, the conductor 240 may be electrically connected to a sense amplifier, and the conductor 240 functions as a bit line. Here, as illustrated in FIG. 24A, at least part of the capacitor 100 is provided to overlap with the conductor 242b included in the transistor 200. Thus, in the semiconductor device of this embodiment, the capacitor 100 can be provided without a significant increase in the area in a plan view; thus, the semiconductor device can be miniaturized or highly integrated.

Note that the semiconductor device described in this embodiment can be suitably used for the semiconductor device 10 or the memory device 300 described in Embodiment 1. That is, the transistor 200, the capacitor 100, and the conductor 240 included in the semiconductor device respectively correspond to the transistor 43, the capacitor 44, and the local bit line LBL. Furthermore, the sense amplifier electrically connected to the conductor 240 corresponds to the sensing circuit 35.

The semiconductor device described in this embodiment has a line-symmetric structure with respect to the dashed-dotted line A7-A8 illustrated in FIG. 24A. That is, it can be said that the transistor 200a and the transistor 200b are positioned line-symmetrically with respect to the conductor 240 as the symmetric axis. In addition, it can be said that the capacitor 100a and the capacitor 100b are positioned line-symmetrically with the conductor 240 as the symmetric axis. Here, in the semiconductor device described in this embodiment, the conductor 242a serves as both the other of the source electrode and the drain electrode of the transistor 200a and the other of the source electrode and the drain electrode of the transistor 200b. In addition, the transistor 200a and the transistor 200b share the conductor 240 functioning as a plug. Thus, when the two transistors, the two capacitors, and the plug are connected in the above-described manner in the semiconductor device described in this embodiment, miniaturization or high integration can be achieved.

### [Transistor 200]

As illustrated in FIG. 24A to FIG. 24C, the transistor 200 includes an insulator 216 over the insulator 214, the conductor 205 (a conductor 205a and a conductor 205b) placed to be embedded in the insulator 216, the insulator 222 over the insulator 216 and the conductor 205, the insulator 224 over the insulator 222, an oxide 230a over the insulator 224, an oxide 230b over the oxide 230a, the conductor 242a (a conductor 242al and a conductor 242a2) and the conductor 242b (a conductor 242b1 and a conductor 242b2) over the oxide 230b, the insulator 253 over the oxide 230b, the insulator 254 over the insulator 253, the conductor 260 (a conductor 260a and a conductor 260b) positioned over the insulator 254 and overlapping with part of the oxide 230b, and the insulator 275 placed over the insulator 222, the insulator 224, the oxide 230a, the oxide 230b, the conductor 242a, and the conductor 242b.

In this specification and the like, the oxide 230a and the oxide 230b are collectively referred to as the oxide 230 in some cases. The conductor 242a and the conductor 242b are collectively referred to as the conductor 242 in some cases.

The opening 258 reaching the oxide 230b is provided in the insulator 280 and the insulator 275. In other words, the opening 258 includes a region overlapping with the oxide 230b. It can also be said that the insulator 275 includes an opening overlapping with the opening included in the insulator 280. That is, the opening 258 includes an opening included in the insulator 280 and an opening included in the insulator 275. The insulator 253, the insulator 254, and the conductor 260 are placed inside the opening 258. That is, the conductor 260 includes a region overlapping with the oxide 230b with the insulator 253 and the insulator 254 therebetween. The conductor 260, the insulator 253, and the insulator 254 are provided between the conductor 242a and the conductor 242b in the channel length direction of the transistor 200. The insulator 254 includes a region in contact with a side surface of the conductor 260 and a region in contact with the bottom surface of the conductor 260. As illustrated in FIG. 24C, the top surface of the insulator 222 is exposed in a region of the opening 258 that does not overlap with the oxide 230.

For example, a material having a high capability of capturing or fixing hydrogen, such as aluminum oxide, is preferably used for the insulator 253, and a material having a high hydrogen barrier property, such as silicon nitride, is preferably used for the insulator 254. Thus, diffusion of impurities such as water or hydrogen into the oxide 230 can be inhibited, for example.

The oxide 230 preferably includes the oxide 230a placed over the insulator 224 and the oxide 230b placed over the oxide 230a. Including the oxide 230a under the oxide 230b makes it possible to inhibit diffusion of impurities into the oxide 230b from components formed below the oxide 230a.

Note that although the transistor 200 is illustrated to have a structure in which two layers, the oxide 230a and the oxide 230b, are stacked as the oxide 230, one embodiment of the present invention is not limited thereto. For example, the oxide 230 may have a single-layer structure of the oxide 230b. Alternatively, a stacked-layer structure of three or more layers may be employed. Alternatively, the oxide 230a and the oxide 230b may each have a stacked-layer structure.

The stacked-layer structure can be, for example, a three-layer structure in which the first layer is a semiconductor layer in which the atomic ratio of metal elements is In:Ga:Zn=1:1:1, the second layer is a semiconductor layer in which the atomic ratio of metal elements is In:Zn=4:1, and the third layer is a semiconductor layer in which the atomic ratio of metal elements is In:Ga:Zn=1:1:1. Note that the band gaps of the first-layer and third-layer semiconductor layers are preferably larger than the band gap of the second-layer semiconductor layer. With this structure, the main current path can be the second-layer semiconductor layer, so that what is called a buried channel structure can be obtained.

The conductor 260 functions as the first gate electrode and the conductor 205 functions as the second gate electrode. The insulator 253 and the insulator 254 function as a first gate insulator, and the insulator 222 and the insulator 224 function as a second gate insulator. The conductor 242b functions as one of a source electrode and a drain electrode, and the conductor 242a functions as the other of the source electrode and the drain electrode. At least part of a region of the oxide 230 overlapping with the conductor 260 functions as a channel formation region.

### [Capacitor 100]

As illustrated in FIG. 24A, FIG. 24B, and FIG. 24D, the capacitor 100 includes the conductor 156, the insulator 153, and the conductor 160 (a conductor 160a and a conductor 160b). The conductor 156 functions as one of a pair of electrodes of the capacitor 100 (also referred to as a lower electrode), the conductor 160 functions as the other of the pair of electrodes of the capacitor 100 (also referred to as an upper electrode), and the insulator 153 functions as a dielectric of the capacitor 100.

At least parts of the conductor 156, the insulator 153, the conductor 160a, and the conductor 160b are placed inside the opening 158 provided in the insulator 275, the insulator 280, and the insulator 282. The conductor 156 is provided over the conductor 242b, the insulator 153 is provided over the conductor 156, the conductor 160a is provided over the insulator 153, and the conductor 160b is provided over the conductor 160a.

The conductor 156 is placed along the opening 158 formed in the insulator 275, the insulator 280, and the insulator 282. The level of part of a top surface of the conductor 156 is preferably higher than the level of a top surface of the insulator 282. A top surface of the conductor 242b is in contact with a bottom surface of the conductor 156. The conductor 156 is preferably deposited by a deposition method that offers excellent coverage, such as an ALD method or a CVD method, for example. A conductor that can be used as the conductor 205, the conductor 260, or the conductor 242 can be used as the conductor 156. When the same conductive material as the conductor 242b is used for the conductor 156, for example, the contact resistance between the conductor 156 and the conductor 242b can be reduced. Titanium nitride or tantalum nitride deposited by an ALD method can be used as the conductor 156, for example.

The insulator 153 is placed to cover the conductor 156 and part of the insulator 282. For the insulator 153, a high dielectric constant (high-k) material (material with a high relative permittivity) is preferably used. The insulator 153 is preferably deposited by a deposition method that offers excellent coverage, such as an ALD method or a CVD method, for example.

As the insulator of high dielectric constant material, an oxide, an oxynitride, a nitride oxide, or a nitride containing one or more kinds of metal element selected from aluminum, hafnium, zirconium, gallium, and the like can be used, for example. The above-described oxide, oxynitride, nitride oxide, and nitride may contain silicon. As the insulator of high dielectric constant material, insulating layers each formed of any of the above-described materials can be stacked to be used.

As the insulator of high dielectric constant material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high dielectric constant material allows the insulator 153 to be thick enough to inhibit a leakage current and a sufficiently high electrostatic capacitance of the capacitor 100 to be ensured.

It is preferable to use stacked insulating layers each formed of any of the above-described materials. A stacked-layer structure using a high dielectric constant material and a material having higher dielectric strength than the high dielectric constant material is preferably used. For example, as the insulator 153, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. As another example, an insulating film in which hafnium zirconium oxide, aluminum oxide, hafnium zirconium oxide, and aluminum oxide are stacked in this order can be used. Using stacked insulators with relatively high dielectric strength, such as aluminum oxide, as the insulator 153 can increase the dielectric strength and inhibit electrostatic breakdown of the capacitor 100.

The conductor 160 is placed to fill the opening 158 formed in the insulator 275, the insulator 280, and the insulator 282. The conductor 160 is preferably deposited by an ALD method, a CVD method, or the like, for example. The conductor 160 may be formed using a conductor that can be used for the conductor 205 or the conductor 260. For example, titanium nitride deposited by an ALD method can be used for the conductor 160a, and tungsten deposited by a CVD method can be used for the conductor 160b. Note that in the case where the adhesion of tungsten to the insulator 153 is sufficiently high, a single-layer film of tungsten deposited by a CVD method may be used as the conductor 160.

The opening 158 is provided to reach the conductor 242b. That is, the opening 158 includes a region overlapping with the conductor 242b. The conductor 242b is one of the source electrode and the drain electrode of the transistor 200 and is in contact with the bottom surface of the conductor 156 provided in the opening 158; thus, the conductor 242b can electrically connect the transistor 200 and the capacitor 100 to each other.

In the plan view, the distance between the opening 158 and the oxide 230 is preferably short. Such a structure can reduce the area occupied by the memory cell including the capacitor 100 and the transistor 200. Note that the shape of the opening 158 in the plan view may be a tetragonal shape, a polygonal shape other than a tetragonal shape, a polygonal shape with rounded corners, or a circular shape including an elliptical shape.

As illustrated in FIG. 24B and FIG. 24D, the conductor 156 is provided in contact with a bottom surface and an inner wall of the opening 158. Thus, the conductor 156 is in contact with side surfaces of the insulator 275, the insulator 280, and the insulator 282, a side surface of the conductor 242b1, a side surface and a top surface of the conductor 242b2, and the top surface of the insulator 222. The insulator 153 is provided in contact with the top surface of the conductor 156, the conductor 160a is provided in contact with a top surface of the insulator 153, and the conductor 160b is provided in contact with a top surface of the conductor 160a.

When the capacitor 100 has the above-described structure, the capacitor 100 in which the conductor 156 and the conductor 160 face each other with the insulator 153 therebetween at the bottom surface and the side surface of the opening 158 can be formed, as illustrated in FIG. 24B and FIG. 24D. Thus, increasing the depth of the opening 158 (which can also be referred to as the thickness of the insulator 280) can increase the electrostatic capacitance of the capacitor 100. Increasing the electrostatic capacitance per unit area of the capacitor 100 in this manner enables a read operation of the memory device to be stabilized.

As illustrated in FIG. 24B, part of the conductor 156, part of the insulator 153, and part of the conductor 160 are provided to be exposed out from the opening 158. In other words, part of the conductor 156, part of the insulator 153, and part of the conductor 160 are formed above a top surface of the conductor 260 or the top surface of the insulator 282.

Part of the conductor 156 and part of the insulator 153 are in contact with the top surface of the insulator 282. That is, a side end portion of the conductor 156 is covered with the insulator 153. Furthermore, the conductor 160 preferably includes a region overlapping with the insulator 282 with the insulator 153 therebetween. Here, as illustrated in FIG. 24B, a side end portion of the conductor 160 and a side end portion of the insulator 153 are substantially aligned with each other. With such a structure, the conductor 160 and the conductor 156 can be separated from each other by the insulator 153, so that a short circuit between the conductor 160 and the conductor 156 can be inhibited.

Furthermore, a portion above the insulator 282 of the conductor 160 may be extended and formed as a wiring. For example, as illustrated in FIG. 24C, the conductor 160 can be provided to extend in the channel width direction of the transistor 200. Thus, in the case where the plurality of transistors 200 and the plurality of capacitors 100 are provided, the conductor 160 can also function as a wiring. In this case, the insulator 153 can also be provided to extend together with the conductor 160.

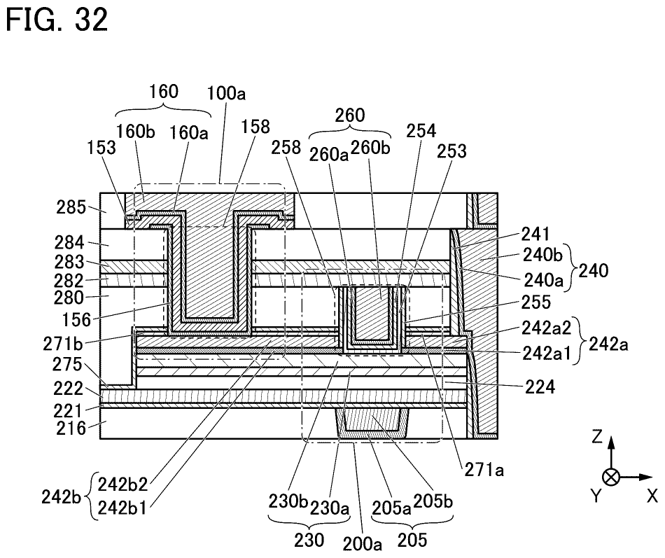

FIG. 32 is a cross-sectional view illustrating another structure example of the transistor 200a and the capacitor 100a included in the semiconductor device illustrated in FIG. 24B. Here, differences between the semiconductor device illustrated in FIG. 32 and the semiconductor device illustrated in FIG. 24B are mainly described.

The semiconductor device illustrated in FIG. 32 is different from the semiconductor device illustrated in FIG. 24B in that side end portions of the insulator 224, the oxide 230a, the oxide 230b, the conductor 242al, and the conductor 242a2 are formed to be substantially aligned with each other.

The semiconductor device illustrated in FIG. 32 includes an insulator 271a, an insulator 271b, an insulator 255, an insulator 241, an insulator 221, an insulator 283, and an insulator 284 in addition to the semiconductor device illustrated in FIG. 24B.

As illustrated in FIG. 32, the insulator 271a is provided between the conductor 242a2 and the insulator 275. The insulator 271b is provided between the conductor 242b2 and the insulator 275. Here, the insulator 271a and the insulator 271b preferably have a function of an etching stopper that protects the conductor 242a2 and the conductor 242b2 when the insulator 224, the oxide 230a, the oxide 230b, the conductor 242a1, the conductor 242a2, the insulator 271a, and the insulator 271b are collectively processed.

As illustrated in FIG. 32, the insulator 255 is provided between the insulator 253 and the conductor 242a2, the conductor 242b2, the insulator 271a, the insulator 271b, the insulator 275, and the insulator 280 and in contact with part of the top surface of the conductor 242al and part of the top surface of the conductor 242b1 in the opening 258. In other words, the insulator 255 is formed in a sidewall shape to be in contact with a sidewall of the opening 258. Here, the insulator 255 preferably has a function of a protective film that prevents excessive oxidation of the conductor 242a2 and the conductor 242b2 in the case where heat treatment is performed in an oxygen-containing atmosphere after separation into the conductor 242a1 and the conductor 242b1 is performed.

As illustrated in FIG. 32, the insulator 221 is provided in contact with the bottom surface of the insulator 222. The insulator 283 is provided in contact with the top surface of the insulator 282. Here, the insulator 221 preferably has a function of inhibiting diffusion of impurities such as water or hydrogen, for example, from an interlayer insulating film placed below the insulator 221 into the transistor 200a. The insulator 283 preferably has a function of inhibiting diffusion of impurities such as water or hydrogen, for example, from an interlayer insulating film placed above the insulator 283 into the transistor 200a.

As illustrated in FIG. 32, the insulator 284 is provided between the insulator 283 and the insulator 285. Here, the insulator 284 has a function of changing the electrostatic capacitance of the capacitor 100a in accordance with the thickness. That is, when the depth of the opening 158 in the capacitor 100a is large (e.g., the thickness of the insulator 284 is large), the electrostatic capacitance of the capacitor 100a can be increased.

As illustrated in FIG. 32, the insulator 241 is provided in contact with the side surface of the conductor 240. Specifically, the insulator 241 is formed in contact with an inner wall of an opening (corresponding to the opening 206 illustrated in FIG. 24B) in the insulator 216, the insulator 221, the insulator 222, the insulator 275, the insulator 280, the insulator 282, the insulator 283, the insulator 284, and the insulator 285. The insulator 241 that is formed to protrude in the opening is formed also on the side surfaces of the insulator 224, the oxide 230, and the conductor 242a. Here, at least part of the conductor 242a is exposed from the insulator 241 and is in contact with the conductor 240. That is, the conductor 240 is formed to fill the opening with the insulator 241 therebetween.

The uppermost portion of the insulator 241 formed below the conductor 242a is preferably positioned below the top surface of the conductor 242a. With this structure, the conductor 240 can be in contact with at least part of the side end portion of the conductor 242a. Note that the insulator 241 formed below the conductor 242a preferably includes a region in contact with the side surface of the oxide 230. With this structure, impurities such as water and hydrogen, for example, included in the insulator 280 and the like, for example, can be inhibited from entering the oxide 230 through the conductor 240. Note that the insulator 241 may have a stacked-layer structure of two or more layers.

Note that the semiconductor device of one embodiment of the present invention can have a structure in which the structure of the semiconductor device illustrated in FIG. 24B and the structure of the semiconductor device illustrated in FIG. 32 are combined as appropriate.

At least part of the structure, method, and the like described in this embodiment can be implemented in appropriate combination with any of the other embodiments, the other example, and the like described in this specification and the like.

### Embodiment 6

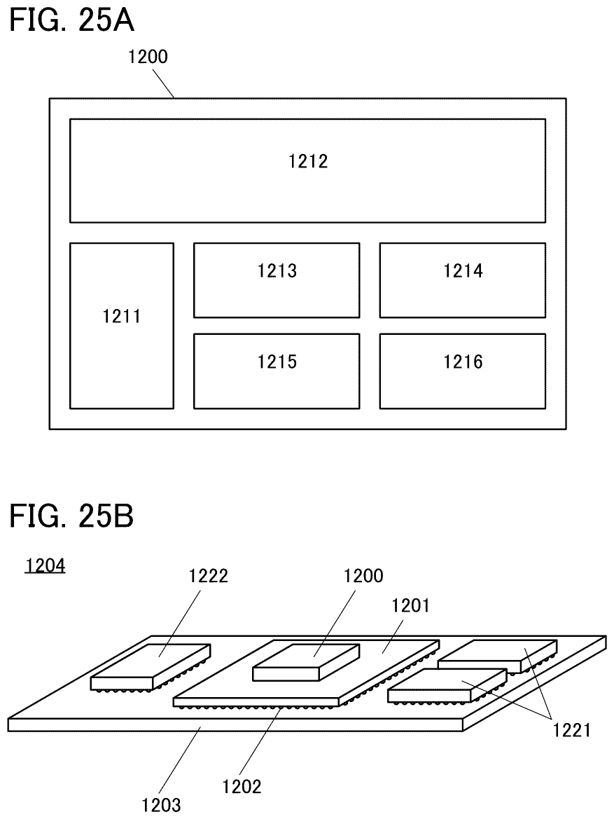

In this embodiment, an example of a chip 1200 on which the semiconductor device of the present invention is mounted is described with reference to FIG. 25A and FIG. 25B. A plurality of circuits (systems) are mounted on the chip 1200. A technology for integrating a plurality of circuits (systems) into one chip is referred to as system on chip (SoC) in some cases.

As illustrated in FIG. 25A, the chip 1200 includes a CPU 1211, a GPU 1212, one or more analog arithmetic units 1213, one or more memory controllers 1214, one or more interfaces 1215, one or more network circuits 1216, and the like.

The chip 1200 is provided with a bump (not illustrated) and is connected to a first surface of a package substrate 1201 through the bump as illustrated in FIG. 25B. In addition, a plurality of bumps 1202 are provided on a rear side of the first surface of the package substrate 1201, and the package substrate 1201 is connected to a motherboard 1203 with the plurality of bumps 1202.

Memory devices such as DRAMs 1221 and a flash memory 1222 may be provided over the motherboard 1203, for example. For example, the DOSRAM described in the above embodiment or the like can be used as each of the DRAMs 1221. This can make the DRAMs 1221 have low power consumption, operate at high speed, and have a large capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a number of data and can execute image processing or a product-sum operation. When an image processing circuit or a product-sum operation circuit using an oxide semiconductor of the present invention is provided in the GPU 1212, image processing or a product-sum operation can be executed with low power consumption.

In addition, since the CPU 1211 and the GPU 1212 are provided on the same chip, a wiring between the CPU 1211 and the GPU 1212 can be shortened. Thus, the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAMs 1221 and a circuit functioning as an interface of the flash memory 1222.

The interface 1215 includes an interface circuit for an external connection device such as a display apparatus, a speaker, a microphone, a camera, or a controller, for example. Examples of the controller include a mouse, a keyboard, and a game controller. As such an interface, a USB (Universal Serial Bus) and an HDMI (registered trademark) (High-Definition Multimedia Interface) can be used, for example.

The network circuit 1216 includes a network circuit for a LAN (Local Area Network) or the like, for example. The network circuit may further include a circuit for network security.

The above-described plurality of circuits (systems) can be formed in the chip 1200 through the same manufacturing process. Therefore, even when the number of circuits needed for the chip 1200 is increased, there is no need to increase the number of manufacturing processes. Thus, the chip 1200 can be manufactured at a low cost.

The motherboard 1203 provided with the package substrate 1201 on which the chip 1200 including the GPU 1212 is mounted, the DRAMs 1221, and the flash memory 1222 can be collectively referred to as a GPU module 1204.

The GPU module 1204 includes the chip 1200 formed using the SoC technology, and thus can be small in size. In addition, the GPU module 1204 is excellent in image processing, and thus is suitably used in a portable electronic appliance such as a smartphone, a tablet terminal, a laptop PC, or a portable (mobile) game machine, for example. The GPU module 1204 can execute a method such as a deep neural network (DNN), a convolutional neural network (CNN), a recurrent neural network (RNN), an autoencoder, a deep Boltzmann machine (DBM), or a deep belief network (DBN), for example, with the product-sum operation circuit using the GPU 1212. Thus, the chip 1200 can be used as an AI chip. The GPU module 1204 can be used as an AI system module.

At least part of the structure, method, and the like described in this embodiment can be implemented in appropriate combination with any of the other embodiments, the other example, and the like described in this specification and the like.

### Embodiment 7

In this embodiment, examples of electronic components and electronic appliances in which the memory device or the like described in the above embodiment or the like is incorporated are described. When the memory device described in the above embodiment or the like is used for the following electronic components and electronic appliances, the electronic components and electronic appliances can have lower power consumption and operate at higher speed.

### <Electronic Component>

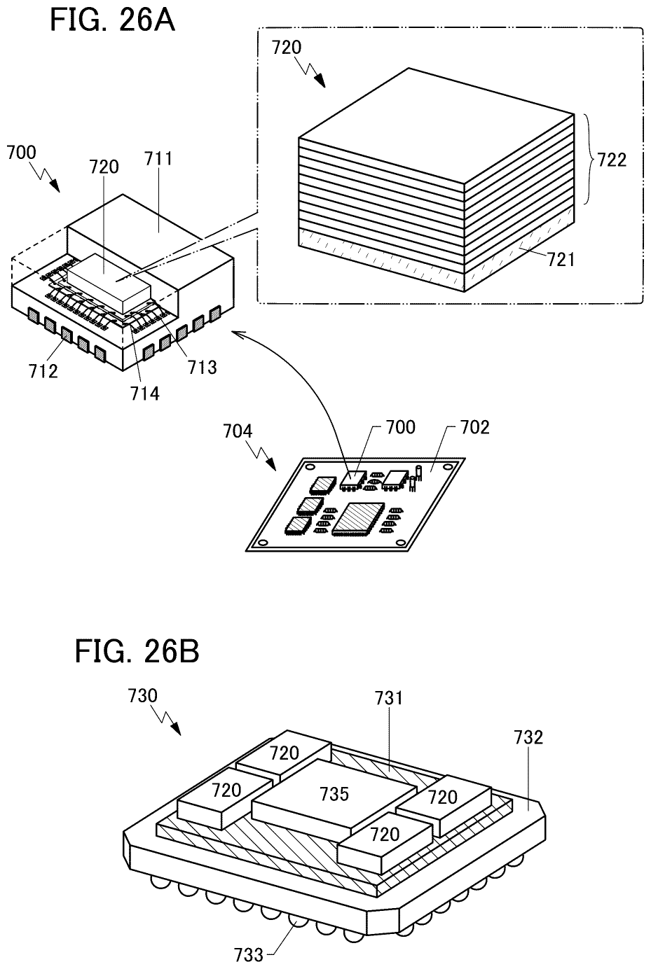

First, examples of an electronic component in which a memory device 720 is incorporated are described with reference to FIG. 26A and FIG. 26B.

FIG. 26A is a perspective view of an electronic component 700 and a substrate (circuit board 704) on which the electronic component 700 is mounted. The electronic component 700 illustrated in FIG. 26A includes the memory device 720 in a mold 711. FIG. 26A omits illustrations of some parts to show the inside of the electronic component 700. The electronic component 700 includes a land 712 outside the mold 711. The land 712 is electrically connected to an electrode pad 713. The electrode pad 713 is electrically connected to the memory device 720 through a wire 714. The electronic component 700 is mounted on a printed circuit board 702, for example. A plurality of such electronic components are combined and electrically connected to each other on the printed circuit board 702, whereby the circuit board 704 is completed.

The memory device 720 includes a driver circuit layer 721 and a memory circuit layer 722.

The memory circuit layer 722 has a structure where a plurality of memory cell arrays are stacked. A stacked-layer structure of the driver circuit layer 721 and the memory circuit layer 722 can be a monolithic stacked-layer structure. In the monolithic stacked-layer structure, layers can be connected to each other without using a through electrode technique such as a through silicon via (TSV) and a bonding technique such as Cu-to-Cu direct bonding. The monolithic stacked-layer structure of the driver circuit layer 721 and the memory circuit layer 722 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed, for example; thus, the number of connection pins can be increased. The increase in the number of connection pins enables parallel operations, which can improve the bandwidth of the memory (also referred to as a memory bandwidth).

It is preferable that the plurality of memory cell arrays included in the memory layer 722 be formed with OS transistors and be monolithically stacked. The monolithic stacked-layer structure of memory cell arrays can improve the bandwidth of the memory and/or the access latency of the memory. Note that the bandwidth refers to the data transfer volume per unit time. The access latency refers to a period of time from data access to the start of data transmission. Note that in the case where the memory circuit layer 722 is formed with Si transistors, the monolithic stacked-layer structure is difficult to form as compared with the case where the memory circuit layer 722 is formed with OS transistors. Therefore, an OS transistor has a structure superior to that of a Si transistor in the monolithic stacked-layer structure.

That is, an OS transistor has an excellent effect of achieving a wide memory bandwidth as compared with a Si transistor.

Note that the memory device 720 may be called a die. Note that in this specification and the like, a die refers to a chip obtained by, for example, forming a circuit pattern on a disc-like substrate (also referred to as a wafer) or the like and cutting the substrate into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 26B is a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of memory devices 720 are provided over the interposer 731.

In the electronic component 730, the memory device 720 can be used as a high bandwidth memory (HBM), for example. The semiconductor device 735 can be used as an integrated circuit (semiconductor device) such as a CPU (Central Processing Unit), a GPU (Graphics Processing Unit), or an FPGA (Field Programmable Gate Array), for example.

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches through the plurality of wirings. The plurality of wirings have a single-layer structure or a layered structure. The interposer 731 has a function of electrically connecting an integrated circuit provided on the interposer 731 to an electrode provided on the package substrate 732. Accordingly, the interposer 731 is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer as the interposer 731, a TSV can also be used as the through electrode.

A silicon interposer is preferably used as the interposer 731. The silicon interposer can be formed at lower cost than an integrated circuit because it is not necessary to provide an active element. Furthermore, since wirings of a silicon interposer can be formed through a semiconductor process, formation of minute wirings, which is difficult for a resin interposer, is easy.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

For example, in a SiP, an MCM, or the like using a silicon interposer, a decrease in reliability due to a difference in the coefficient of expansion between an integrated circuit and the interposer is less likely to occur. Furthermore, the surface of a silicon interposer has high planarity, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

For example, in the case where a plurality of integrated circuits with different terminal pitches are electrically connected with use of a silicon interposer, TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the monolithic stacked-layer structure using the OS transistors is suitable. A composite structure combining memory cell arrays stacked using a TSV and monolithically stacked memory cell arrays may be employed.

The substrate on which the electronic component 730 is mounted may be provided with a heat sink (a radiator plate) overlapping with the electronic component 730. In the case of providing a heat sink, the heights of integrated circuits provided on the interposer 731 are preferably equal to each other. In the electronic component 730 of this embodiment, the heights of the memory device 720 and the semiconductor device 735 are preferably the same, for example.

An electrode 733 may be provided on the bottom portion of the package substrate 732 to mount the electronic component 730 on another substrate. FIG. 26B illustrates an example in which the electrode 733 is formed of a solder ball. Solder balls are provided in a matrix on the bottom portion of the package substrate 732, whereby BGA (Ball Grid Array) mounting can be achieved in the electronic component 730. Note that the electrode 733 may be formed of a conductive pin. When conductive pins are provided in a matrix on the bottom portion of the package substrate 732, PGA (Pin Grid Array) mounting can be achieved in the electronic component 730.

The electronic component 730 can be mounted on another substrate by various mounting methods not limited to BGA or PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

When the memory device of one embodiment of the present invention is used for an electronic component, power consumption can be reduced. Although demand for energy will increase with increasing performance and integration degree of memory devices, the use of the memory device of one embodiment of the present invention can thus reduce the emission amount of greenhouse gas typified by carbon dioxide (CO₂). The memory device of one embodiment of the present invention is effective as a global warming countermeasure because of its low power consumption.

The structure, method, and the like described in this embodiment can be used in an appropriate combination with other structures, methods, and the like described in this embodiment or other structures, methods, and the like described in the other embodiments, the other example, or the like.

### Embodiment 8

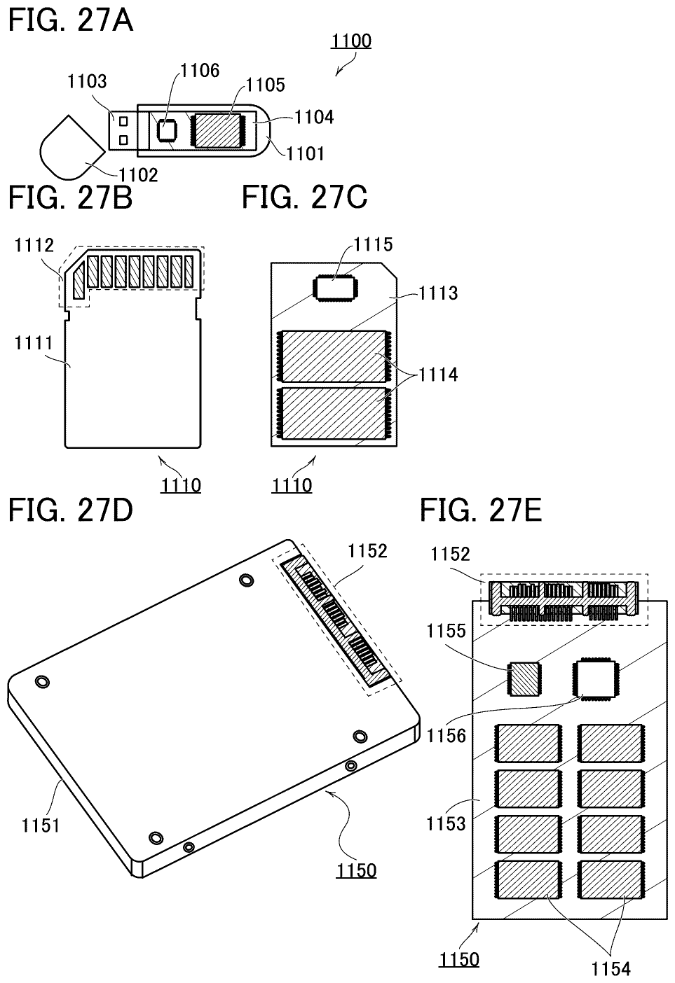

In this embodiment, application examples of the memory device using the memory device described in the above embodiment or the like will be described. The memory device described in the above embodiment or the like can be applied to, for example, memory devices of a variety of electronic appliances (e.g., information terminals, computers, smartphones, e-book readers, digital cameras (including video cameras), video recording/reproducing devices, or navigation systems). When the memory device described in the above embodiment or the like is used for the memory devices of the above-described electronic appliances, the electronic appliances can have lower power consumption and operate at higher speed. Here, the computers refer not only to tablet computers, laptop computers, and desktop computers, but also to large computers such as server systems. Alternatively, the memory device described in the above embodiment or the like is used as a variety of removable memory devices such as memory cards (e.g., SD cards), USB memories, and SSDs (solid state drives), for example. FIG. 27A to FIG. 27E are drawings schematically illustrating some structure examples of removable memory devices. The memory device described in the above embodiment or the like is processed into a packaged memory chip and used in a variety of storage devices or removable memories, for example.

FIG. 27A is a schematic view of a USB memory. A USB memory 1100 includes a housing 1101, a cap 1102, a USB connector 1103, and a substrate 1104. The substrate 1104 is stored in the housing 1101. The substrate 1104 is provided with a memory chip 1105 and a controller chip 1106, for example. The memory device described in the above embodiment or the like can be incorporated in the memory chip 1105 or the like, for example.

FIG. 27B is a schematic external diagram of an SD card. FIG. 27C is a schematic diagram illustrating the internal structure of the SD card. An SD card 1110 includes a housing 1111, a connector 1112, and a substrate 1113. The substrate 1113 is stored in the housing 1111. The substrate 1113 is provided with a memory chip 1114 and a controller chip 1115, for example. When the memory chip 1114 is provided also on the rear surface side of the surface of the substrate 1113 on which the controller chip 1115 is attached, the capacity of the SD card 1110 can be increased. In addition, in the SD card 1110, a wireless chip with a radio communication function may be provided on the substrate 1113. This enables data reading or writing of the memory chip 1114 by wireless communication between a host device and the SD card 1110. The memory device described in the above embodiment or the like can be incorporated in the memory chip 1114 or the like, for example.

FIG. 27D is a schematic external diagram of an SSD. FIG. 27E is a schematic diagram of the internal structure of the SSD. An SSD 1150 includes a housing 1151, a connector 1152, and a substrate 1153. The substrate 1153 is stored in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is provided also on the rear surface side of the surface of the substrate 1153 on which the controller chip 1156 is attached, the capacity of the SSD 1150 can be increased. The memory device described in the above embodiment or the like can be incorporated in the memory chip 1154 or the like, for example.

At least part of the structure, method, and the like described in this embodiment can be implemented in appropriate combination with any of the other embodiments, the other example, and the like described in this specification and the like.

### Embodiment 9

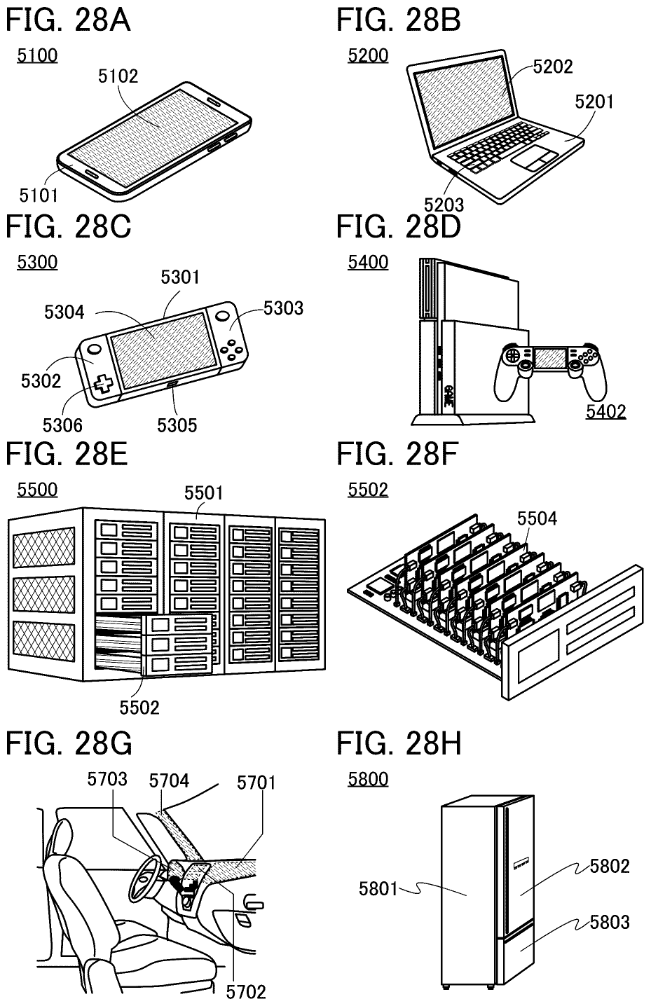

The memory device of one embodiment of the present invention can be used for a processor such as a CPU or a GPU or a chip, for example. When a processor such as a CPU or a GPU or a chip using the memory device of one embodiment of the present invention is, for example, used for an electronic appliance, the electronic appliance can achieve lower power consumption and higher speed. FIG. 28A to FIG. 28H illustrate specific examples of electronic appliances that are for example provided with a processor such as a CPU or a GPU or a chip using the memory device.

<Electronic appliance—System>

The GPU or the chip of one embodiment of the present invention can be mounted on a variety of electronic appliances. Examples of the electronic appliances include electronic appliances with a relatively large screen, such as a television device, a desktop or laptop information terminal, digital signage, and a large game machine (e.g., a pachinko machine). In addition, the examples also include a digital camera, a digital video camera, a digital photo frame, an e-book reader, a mobile phone device, a portable game machine, a portable information terminal, and an audio reproducing device. When the GPU or the chip of one embodiment of the present invention is provided in an electronic appliance, the electronic appliance can include artificial intelligence.

The electronic appliance of one embodiment of the present invention may include an antenna. When a signal is received by the antenna, the electronic appliance can display a video, information, or the like on a display portion, for example. When the electronic appliance includes an antenna and a secondary battery, the antenna may be used for contactless power transmission.

The electronic appliance of one embodiment of the present invention may include a sensor (e.g., a sensor having a function of measuring force, displacement, position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, a smell, infrared rays, or the like).

The electronic appliance of one embodiment of the present invention can have a variety of functions. For example, the electronic appliance can have a function of displaying a variety of information (e.g., a still image, a moving image, a text image, and the like) on the display portion, a touch panel function, a function of displaying a calendar, date, time, and the like, a function of executing a variety of software (programs), a wireless communication function, and a function of reading a program or data stored in a recording medium, for example. FIG. 28A to FIG. 28H illustrate examples of electronic appliances.

### [Information Terminal]

FIG. 28A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

Note that the information terminal 5100 may include a power button, an operation button, a speaker, a microphone, a camera, a light source, a control device, and the like, for example. As the control device, one or more selected from a CPU, a GPU, and a memory device may be included, for example. The memory device of one embodiment of the present invention is preferably used for the control device, in which case power consumption can be reduced.

When the chip of one embodiment of the present invention is used in the information terminal 5100, the information terminal 5100 can execute an application utilizing artificial intelligence. Examples of the application utilizing artificial intelligence include an application for recognizing a conversation and displaying the content of the conversation on the display portion 5102; an application for recognizing letters, figures, or the like input to the touch panel of the display portion 5102 by a user and displaying them on the display portion 5102; and an application for performing biometric authentication using fingerprints, voice prints, or the like.

FIG. 28B illustrates a notebook information terminal 5200. The notebook information terminal 5200 includes a main body 5201 of the information terminal, a display portion 5202, and a keyboard 5203.

Note that the notebook information terminal 5200 may include a pointing device, an external connection port, a control device, and the like, for example. As the control device, one or more selected from a CPU, a GPU, and a memory device may be included, for example. The memory device of one embodiment of the present invention is preferably used for the control device, in which case power consumption can be reduced.

Like the information terminal 5100 described above, when the chip of one embodiment of the present invention is used in the notebook information terminal 5200, the notebook information terminal 5200 can execute an application utilizing artificial intelligence. Examples of the application utilizing artificial intelligence include design-support software, text correction software, and software for automatic menu generation. Furthermore, a user of the notebook information terminal 5200 can develop novel artificial intelligence.

Note that although FIG. 28A and FIG. 28B illustrate a smartphone and a notebook information terminal, respectively, as examples of the electronic appliance in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machines]

FIG. 28C illustrates a portable game machine 5300 as an example of a game machine. The portable game machine 5300 includes a housing 5301, a housing 5302, a housing 5303, a display portion 5304, a connection portion 5305, an operation key 5306, and the like, for example. The housing 5302 and the housing 5303 can be detached from the housing 5301. When the connection portion 5305 provided in the housing 5301 of the portable game machine 5300 is attached to another housing (not illustrated), an image to be output to the display portion 5304 can be output to another video device (not illustrated). In this case, the housing 5302 and the housing 5303 can each function as an operation unit. Thus, with the portable game machine 5300, a plurality of players can play a game at the same time. For example, the chip described in the above embodiment or the like can be incorporated as the chip provided on a substrate in the housing 5301, the housing 5302 and the housing 5303.

FIG. 28D illustrates a stationary game machine 5400, which is an example of a game machine. A controller 5402 is wired or connected wirelessly to the stationary game machine 5400.

Using the GPU or the chip of one embodiment of the present invention in a game machine such as the portable game machine 5300 or the stationary game machine 5400, for example, enables a low-power-consumption game machine. Moreover, heat generation from a circuit can be reduced in the game machine owing to low power consumption; thus, the influence of heat generation on the circuit itself, a peripheral circuit, or a module can be reduced.

Furthermore, when the GPU or the chip of one embodiment of the present invention is used in the portable game machine 5300, the portable game machine 5300 including artificial intelligence can be achieved.

In general, the progress of a game, the actions and words of game characters, and expressions of an event and the like occurring in the game of a game machine are determined by the program in the game; however, the use of artificial intelligence in the portable game machine 5300 enables expressions not limited by the game program. For example, an expression in which the actions and words of game characters are changed depending on a question posed by a player, the progress of the game, time, or the like, for example, is possible in the portable game machine 5300.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated in FIG. 28C and FIG. 28D as examples of a game machine, the game machine using the GPU or the chip of one embodiment of the present invention is not limited thereto. Examples of the game machine in which the GPU or the chip of one embodiment of the present invention is used include an arcade game machine installed in entertainment facilities (e.g., a game center, an amusement park, and the like), and a throwing machine for batting practice installed in sports facilities.

### [Large Computer]

The GPU or the chip of one embodiment of the present invention can be used in a large computer.

FIG. 28E illustrates a supercomputer 5500, which is an example of a large computer. FIG. 28F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504. The GPU or the chip described in the above embodiment or the like can be mounted on the substrates 5504.

The supercomputer 5500 is a large computer mainly used for scientific computation. In scientific computation, the supercomputer 5500 needs to process an enormous amount of arithmetic operation at a high speed; hence, power consumption is large and chips generate a large amount of heat. Using the GPU or the chip of one embodiment of the present invention in the supercomputer 5500 enables a low-power-consumption supercomputer. Moreover, heat generation from a circuit can be reduced in the supercomputer 5500 owing to low power consumption; thus, the influence of heat generation on the circuit itself, a peripheral circuit, or a module can be reduced.

The supercomputer 5500 can also function as a parallel computer. When the supercomputer 5500 is used as a parallel computer, large-scale computation necessary for artificial intelligence learning and inference can be performed, for example.

Although a supercomputer is illustrated as an example of a large computer in FIG. 28E and FIG. 28F, a large computer in which the GPU or the chip of one embodiment of the present invention is used is not limited thereto. Other examples of the large computer in which the GPU or the chip of one embodiment of the present invention is used include a computer that provides service (a server) and a large general-purpose computer (a mainframe).

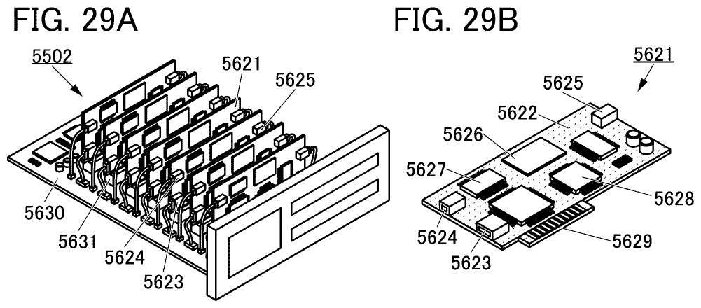

FIG. 29A is a perspective view illustrating a specific structure example of the computer 5502. In FIG. 29A, the computer 5502 includes a motherboard 5630. The motherboard 5630 includes a plurality of slots 5631 and a plurality of connection terminals (not illustrated). A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 29B is an example of a processing board provided with a CPU, a GPU, a memory device, and the like, for example. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 29B also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for those semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe (Peripheral Component Interconnect Express).

Each of the connection terminal 5623, the connection terminal 5624, and the connection terminal 5625 can serve as, for example, an interface for performing power supply, signal input, or the like to the PC card 5621. As another example, they can each serve as an interface for outputting a signal computed by the PC card 5621, for example. Examples of the standard for each of the connection terminal 5623, the connection terminal 5624, and the connection terminal 5625 include USB (Universal Serial Bus), SATA (Serial ATA), SCSI (Small Computer System Interface), and the like. In the case where video signals are output from the connection terminal 5623, the connection terminal 5624, and the connection terminal 5625, an example of the standard therefor is HDMI (registered trademark) (High-Definition Multimedia Interface).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the above-described electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the above-described electronic component 700 can be used, for example.

### [Moving Vehicle]

The GPU or the chip of one embodiment of the present invention can be used in an automobile, which is a moving vehicle, and the periphery of a driver's seat in the automobile.

FIG. 28G illustrates the periphery of a windshield inside an automobile, which is an example of a moving vehicle. FIG. 28G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like, for example. In addition, the content, layout, or the like, for example, of the display on the display panels can be changed as appropriate to suit the user's preference. Thus, the design quality of the display panels can be increased. The display panel 5701 to the display panel 5703 can also be used as lighting devices.

The display panel 5704 can compensate for view obstructed by the pillar (a blind spot) by showing an image taken by an imaging device (not illustrated) provided for the automobile. That is, the display panel 5704 displays an image taken by the imaging device provided outside the automobile to compensate for the blind spot and increase safety. In addition, the display panel 5704 displays an image to compensate for a portion that cannot be seen, so that the safety can be confirmed more naturally and comfortably. The display panel 5704 can also be used as a lighting device.

Since the GPU or the chip of one embodiment of the present invention can be used as a component of artificial intelligence, the chip can be used in an automatic driving system of the automobile, for example. The chip can also be used for a system for navigation, risk prediction, or the like, for example. A structure may be employed in which the display panel 5701 to the display panel 5704 display navigation information, risk prediction information, or the like, for example.

Although the automobile is described above as an example of a moving vehicle, the moving vehicle is not limited to the automobile. Examples of the moving vehicle include a train, a monorail train, a ship, and a flying object (a helicopter, an unmanned aircraft (a drone), an airplane, and a rocket). These moving vehicles can include a system utilizing artificial intelligence when equipped with the chip of one embodiment of the present invention.

### [Household Appliance]

FIG. 28H illustrates an electric refrigerator-freezer 5800, which is an example of a household appliance. The electric refrigerator-freezer 5800 includes a housing 5801, a refrigerator door 5802, a freezer door 5803, and the like, for example.

When the chip of one embodiment of the present invention is used in the electric refrigerator-freezer 5800, the electric refrigerator-freezer 5800 including artificial intelligence can be provided. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like, for example.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The use of the memory device of one embodiment of the present invention for one or more selected from an electronic appliance, an information terminal, a game machine, a large computer, a moving vehicle, and a household appliance enables a reduction of power consumption. Although demand for energy will increase with increasing performance and integration degree of memory devices, the use of the memory device of one embodiment of the present invention can reduce the emission amount of greenhouse gas typified by carbon dioxide (CO₂). The memory device of one embodiment of the present invention is effective as a global warming countermeasure because of its low power consumption.

The electronic appliances, the functions of the electronic appliances, the application examples of artificial intelligence, their effects, and the like described in this embodiment can be combined as appropriate with the description of another electronic appliance, for example.

At least part of the structure, method, or the like described in this embodiment can be implemented in appropriate combination with any of the other embodiments, the other example, and the like described in this specification and the like.

### Embodiment 10

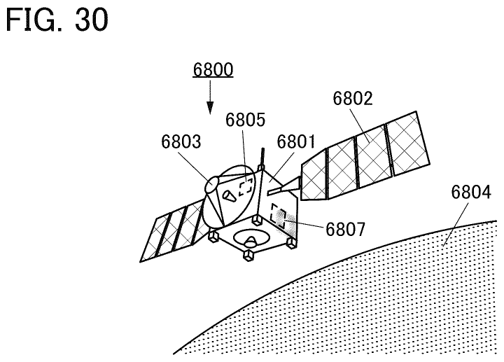

The semiconductor device of one embodiment of the present invention includes an OS transistor. A change in electrical characteristics of the OS transistor due to exposure to radiation is small. That is, the OS transistor is highly resistant to radiation, and thus can be suitably used even in an environment where radiation can enter. For example, the OS transistor can be suitably used in outer space. In this embodiment, a specific example of using the semiconductor device of one embodiment of the present invention in a device for space will be described with reference to FIG. 30.

FIG. 30 illustrates an artificial satellite 6800 as an example of a device for space. The artificial satellite 6800 includes a body 6801, a solar panel 6802, an antenna 6803, a secondary battery 6805, and a control device 6807. In FIG. 30, a planet 6804 in outer space is illustrated as an example. Note that outer space refers to, for example, space at an altitude greater than or equal to 100 km, and outer space described in this specification and the like may include thermosphere, mesosphere, and stratosphere.

Although not illustrated in FIG. 30, a battery management system (also referred to as BMS) or a battery control circuit may be provided in the secondary battery 6805. The battery management system or the battery control circuit preferably uses the OS transistor, in which case power consumption is low and high reliability is achieved even in outer space.

The amount of radiation in outer space is large and more than 100 times that on the ground. Note that examples of radiation include electromagnetic waves (electromagnetic radiation) typified by X-rays or gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel 6802 is not irradiated with sunlight or the amount of sunlight with which the solar panel 6802 is irradiated is small, the amount of electric power generated by the solar panel 6802 is small. Accordingly, a sufficient amount of electric power required for the operation of the artificial satellite 6800 might not be generated. In order to operate the artificial satellite 6800 even with a small amount of electric power generated by the solar panel 6802, the artificial satellite 6800 is preferably provided with the secondary battery 6805. Note that the solar panel 6802 is referred to as a solar cell module in some cases.

The artificial satellite 6800 can generate a signal. The signal is transmitted through the antenna 6803. The signal can be received by a ground-based receiver or another artificial satellite, for example. When the receiver receives the signal transmitted by the artificial satellite 6800, the position of the receiver can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor, which is one embodiment of the present invention, is suitably used for the control device 6807. A change in electrical characteristics due to exposure to radiation is smaller in the OS transistor than in a Si transistor. Accordingly, the OS transistor has high reliability and thus can be suitably used even in an environment where radiation can enter.

That is, the OS transistor has an excellent effect of being highly resistant to radiation as compared with a Si transistor.

Alternatively, the artificial satellite 6800 can include a sensor. For example, with a structure including a visible light sensor, the artificial satellite 6800 can have a function of sensing sunlight reflected by a ground-based object. With a structure including a thermal infrared sensor, the artificial satellite 6800 can have a function of sensing thermal infrared rays emitted from the surface of the earth. Thus, the artificial satellite 6800 can function as an earth observing satellite, for example.

The use of the semiconductor device of one embodiment of the present invention for a device for space can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

Although the artificial satellite is described as an example of a device for space in this embodiment, the present invention is not limited thereto. The semiconductor device of one embodiment of the present invention can be suitably used for a device for space such as a spacecraft, a space capsule, or a space probe, for example.

At least part of the structure, method, and the like described in this embodiment can be implemented in appropriate combination with any of the other embodiments, the other example, and the like described in this specification and the like.

### Embodiment 11

In this embodiment, a transistor including an oxide semiconductor in a channel formation region (OS transistor) is described. In the description of the OS transistor, comparison with a transistor including silicon in a channel formation region (also referred to as a Si transistor) is also described simply.

### [OS Transistor]

An oxide semiconductor having a low carrier concentration is preferably used in an OS transistor. For example, the carrier concentration of an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor, the impurity concentration in the oxide semiconductor is reduced so that the density of defect states in the oxide semiconductor can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that impurities in an oxide semiconductor refer to, for example, elements other than the main components of an oxide semiconductor. For example, an element with a concentration lower than 0.1 atomic % can be regarded as an impurity.

When impurities or oxygen vacancies are in a channel formation region of the oxide semiconductor included in an OS transistor, electrical characteristics of the OS transistor may vary easily and the reliability thereof may worsen. In some cases, a defect that is an oxygen vacancy into which hydrogen enters (hereinafter sometimes referred to as VoH) is formed in the oxide semiconductor of the OS transistor, which generates an electron serving as a carrier. Formation of VoH in the channel formation region may increase the donor concentration in the channel formation region of the OS transistor. An increase in the donor concentration in the channel formation region of the OS transistor may lead to a variation in threshold voltage. Thus, the oxygen vacancies in the channel formation region of the oxide semiconductor allow the OS transistor to easily have normally-on characteristics (to cause the drain current to flow at a gate voltage 0 V). Therefore, impurities, oxygen vacancies, and VoH are preferably reduced as much as possible in the channel formation region in the oxide semiconductor.

The band gap of the oxide semiconductor is preferably wider than the band gap of silicon (typically 1.1 eV), further preferably greater than or equal to 2 eV, still further preferably greater than or equal to 2.5 eV, yet still further preferably greater than or equal to 3.0 eV. With use of an oxide semiconductor having a wider band gap than silicon, the off-state current of the transistor (also referred to as Ioff) can be reduced.

In a Si transistor, a short-channel effect (also referred to as SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as S value), and an increase in leakage current. Here, the S value means the amount of change in gate voltage in the subthreshold region when the drain voltage is constant and the drain current is changed by one order of magnitude.

The characteristic length is widely used as an indicator of resistance to the short-channel effect. The characteristic length is an indicator of curving of a potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Thus, the OS transistor has a shorter characteristic length between the source region and the channel formation region and a shorter characteristic length between the drain region and the channel formation region than the Si transistor has. Accordingly, the OS transistor has higher resistance to the short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region each become an n⁺-type region in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be more suitably used as a short-channel transistor than the Si transistor. Note that the gate length refers to the length of a gate electrode in a direction in which carriers move inside a channel formation region during operation of the transistor and to the width of the bottom surface of the gate electrode in a top view of the transistor.

Miniaturization of the OS transistor can improve the high frequency characteristics of the transistor. Specifically, the cutoff frequency of the transistor can be improved. When the gate length of the OS transistor is within the above-described range, the cutoff frequency of the transistor can be greater than or equal to 50 GHz, preferably greater than or equal to 100 GHz, further preferably greater than or equal to 150 GHz at room temperature, for example.

The above-described comparison of the OS transistor with the Si transistor demonstrates that the OS transistor has an effect superior to the Si transistor, such as a low off-state current and capability of short-channel transistor formation.

The structures, configurations, methods, and the like described in this embodiment can be used in combination as appropriate with the structures, configurations, methods, and the like described in the other embodiments, the other example, and the like.

### Embodiment 12

A data center (also referred to as DC) for which the semiconductor device described in the above embodiments can be used is described in this embodiment. A data center using the semiconductor device of one embodiment of the present invention is effective in improving performance, for example, reducing power consumption.

The semiconductor device of one embodiment of the present invention can be suitably used for, for example, a storage system used in a data center or the like. Long-term management of data, such as guarantee of data immutability, is required for the data center, for example. In the case where data is managed for a long term, installation of storages and servers for storing an enormous amount of data, stable electric power for data retention, cooling equipment for data retention, or the like is necessary, for example. Therefore, for example, an increase in the scale of data center facility is necessary.

With use of the semiconductor device of one embodiment of the present invention for a storage system used in a data center, electric power used for retaining data can be reduced and a semiconductor device for retaining data can be downsized. Accordingly, downsizing of the storage system, downsizing of the power supply for retaining data, downscaling of the cooling equipment, and the like can be achieved, for example. Therefore, a space of the data center can be reduced.

In addition, since the semiconductor device according to one embodiment of the present invention has low power consumption, heat generation from a circuit can be reduced. Accordingly, it is possible to reduce adverse effects of the heat generation on the circuit itself, a peripheral circuit, and a peripheral module. Furthermore, the use of the semiconductor device of one embodiment of the present invention can achieve a data center that operates stably even in a high-temperature environment. Thus, the reliability of the data center can be increased.

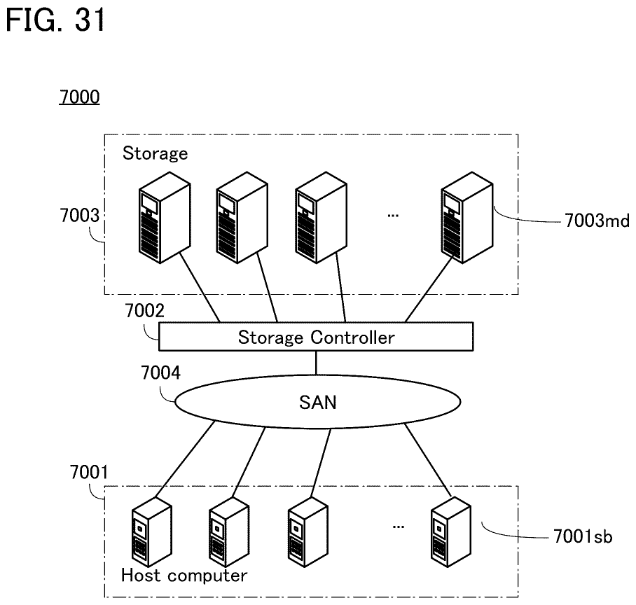

FIG. 31 illustrates a storage system that can be used in a data center. A storage system 7000 illustrated in FIG. 31 includes a plurality of servers 7001sb as a host 7001 (indicated as “Host Computer” in the diagram). The storage system 7000 includes a plurality of memory devices 7003md as a storage 7003 (indicated as “Storage” in the diagram). Furthermore, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for writing or reading data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for writing or reading data.

The above-described cache memory is used in the storage control circuit 7002 and the storage 7003. The data transmitted between the host 7001 and the storage 7003 is stored in the cache memory in the storage control circuit 7002 and the storage 7003 and then output to the host 7001 or the storage 7003.

The use of an OS transistor as a transistor for storing data in the above-described cache memory to retain a potential based on data can reduce the refresh frequency of the above-described cache memory, so that power consumption of the above-described cache memory can be reduced. Furthermore, with a structure in which memory cell arrays are stacked, the cache memory can be downsized.

Note that when the semiconductor device of one embodiment of the present invention is used in a data center, power consumption can be reduced. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

The structures, configurations, methods, and the like described in this embodiment can be used in combination as appropriate with the structures, configurations, methods, and the like described in the other embodiments, the other example, and the like.

### Example

In this example, results of estimating the write time, the read time, the memory density, and the retention time of the memory device of one embodiment of the present invention will be described.

The memory device subjected to estimation of the write time, the read time, the memory density, and the retention time had a structure that included a memory array where four layers (corresponding to the layer 41[1] to the layer 41[4]) that were each provided with memory cells (corresponding to the memory cells 42) including OS transistors were stacked over a layer (corresponding to the layer 30) provided with a reading circuit (corresponding to the sensing circuit 35) including OS transistors, as illustrated in FIG. 3B, FIG. 19A, and FIG. 19B. Furthermore, in the structure, a driver circuit (corresponding to the sense amplifier 55 or the like) such as a driver, a sense amplifier, or a controller, for example, was provided in a substrate including Si transistors (corresponding to the substrate 50).

Note that the memory device subjected to the estimation in this example has a structure where DOSRAM memory cells are stacked and may be referred to as a 3D DOSRAM.

Table 1 shows the results of estimating the write time, the read time, the memory density, and the retention time of the 3D DOSRAM (hereinafter simply referred to as the DOSRAM in some cases) having the above-described structure and a DRAM formed using Si transistors.

TABLE 1

| | DOSRAM | | | |
|---|---|---|---|---|
| | (30 nm Design rule) | | | |
| | Condi- | Condi- | Condi- | DRAM |
| | tion A | tion B | tion C | (14 nm Design rule) |
| Write time | 7 ns | 6 ns | 3 ns | Approximately 20 ns |
| Read time | 48 ns | 24 ns | 16 ns | |

| | | |
|---|---|---|
| Density | 77 cell/μm² (per layer) | 383 cell/μm² |
| Retention | Refreshing is performed more | Data in all the memory cells |
| | than once in every 6.4 s. | is refreshed once in every |
| | | 64 ms. |

As shown in Table 1, the 30 nm design rule was applied to the OS transistors in the estimation of the DOSRAM. In the estimation of the DRAM, the 14 nm design rule was applied to the Si transistors.

Table 1 shows estimation results of three cases with different DOSRAM structures (Condition A, Condition B, and Condition C).

In Condition A, the DOSRAM memory cell has the structure illustrated in FIG. 24B, and the semiconductor layer (corresponding to the oxide 230) of the OS transistor (corresponding to the transistor 200) is a semiconductor layer in which the atomic ratio of metal elements is In:Ga:Zn=1:1:1.

In Condition B, the DOSRAM memory cell has the structure illustrated in FIG. 32, and the semiconductor layer of the OS transistor is a semiconductor layer in which the atomic ratio of metal elements is In:Ga:Zn=1:1:1.

In Condition C, the DOSRAM memory cell has the structure illustrated in FIG. 24B, and the semiconductor layer of the OS transistor has a three-layer structure in which the first layer is a semiconductor layer in which the atomic ratio of metal elements is In:Ga:Zn=1:1:1, the second layer is a semiconductor layer in which the atomic ratio of metal elements is In:Zn=4:1, and the third layer is a semiconductor layer in which the atomic ratio of metal elements is In:Ga:Zn=1:1:1.

In the estimation of the DOSRAM shown in Table 1, the designed channel length of the OS transistor was 30 nm and the designed channel width thereof was 30 nm. The cell capacity (corresponding to the capacitor 100) was 1.5 fF.

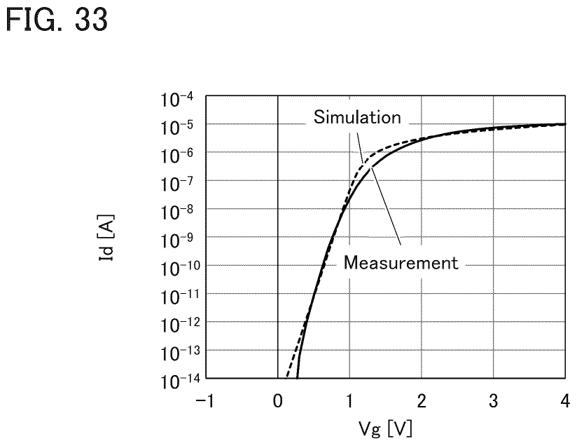

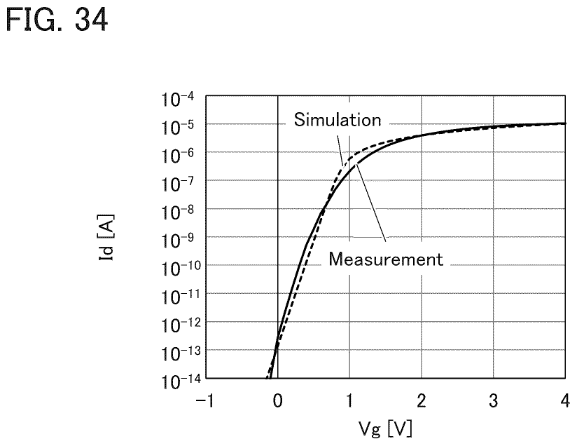

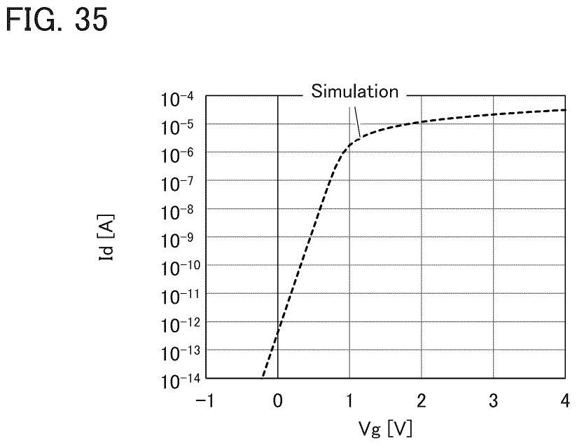

FIG. 33, FIG. 34, and FIG. 35 show the Id-Vg characteristics of the OS transistor used for the estimation under Condition A, Condition B, and Condition C, respectively. FIG. 33, FIG. 34, and FIG. 35 each show the drain current Id (a current flowing between a source and a drain) at gate voltages Vg (the voltage between the source and a gate) of −1 V to 4 V in the case where the drain voltage Vd (the voltage between the source and the drain) is 1.2 V and the back gate voltage Vb (the voltage between the source and a back gate) is 0 V in an environment at 27° C. Note that the Id-Vg characteristics indicated by solid lines (Measurement) are the Id-Vg characteristics of actually formed OS transistors, and the Id-Vg characteristics indicated by dashed lines (Simulation) are the Id-Vg characteristics of the OS transistors used for the estimation. Note that FIG. 35 shows only the Id-Vg characteristics indicated by dashed lines (Simulation).

The on-state current Ion of the OS transistor (the drain current Id per micrometer of the channel width in the case where the gate voltage Vg was 3.3 V in the Id-Vg characteristics indicated by solid lines (Measurement) in this example) was 272.6 μA/μm in the case of Condition A shown in FIG. 33, and 297.8 μA/μm in the case of Condition B shown in FIG. 34.

As shown in Table 1, the write time of the DOSRAM was estimated to be 7 ns, 6 ns, and 3 ns in Condition A, Condition B, and Condition C, respectively, and was shorter than 20 ns, which was the estimated write time of the DRAM, under each of the conditions. The read time of the DOSRAM was estimated to be 48 ns, 24 ns, and 16 ns in Condition A, Condition B, and Condition C, respectively, and the read time under Condition C was shorter than 20 ns, which was the estimated read time of the DRAM. That is, it was found that the DOSRAM can show higher performance in the write time and the read time than the DRAM depending on conditions.

In addition, in the density section showing the estimated memory density, the DOSRAM memory density was estimated to be 77 cells/μm² per layer. It was found that in the case of stacking five layers of DOSRAM memory cells, for example, the DOSRAM memory density becomes higher than 383 cells/μm², which is the estimated memory density of the DRAM. That is, it was found that the performance of the DOSRAM having a multilayer structure can exceed the performance of the DRAM in memory density.

Moreover, in the retention section showing the estimated data retention time, it was estimated that the DOSRAM needs to be refreshed more than once in every 6.4 s and that all the memory cells in the DRAM need to be refreshed once in every 64 ms. These results demonstrated that the power for refresh of the DOSRAM can be reduced to 1/100 of the power for refresh of the DRAM.

At least part of this example can be implemented in combination with the other embodiments and the like described in this specification and the like as appropriate.

### REFERENCE NUMERALS

10: semiconductor device, 20: layer, 30: layer, 40: layer, 41: layer, 50: substrate, 35: sensing circuit, 35_pre: sensing circuit, 37: switching circuit, 42: memory cell, 51: driver circuit, LBL: local bit line, LBL_pre: local bit line, GBL: global bit line, GBLB: global bit line, SA_GBL: global bit line, SA_GBLB: global bit line, BL: bit line, BLB: bit line, M0: transistor, M1: transistor, M2: transistor, M3: transistor, M4: transistor, SW0: signal, SW1: signal, SW2: signal, SW3: signal, VPRE2: potential, MUX: signal, WE: signal, RE: signal, SL: wiring, WL: word line, CSL: wiring, EQ: signal, EQB: signal, CSEL: signal, VPRE: potential, SAP: wiring, SAN: wiring, 31: transistor, 32: transistor, 33: transistor, 34: transistor, 43: transistor, 44: capacitor, MND: node, 52: switch circuit, 53: precharge circuit, 54: precharge circuit, 55: sense amplifier, 52_1: transistor, 52_2: transistor, 53_1: transistor, 53_2: transistor, 53_3: transistor, 54_1: transistor, 54_2: transistor, 54_3: transistor, 55_1: transistor, 55_2: transistor, 55_3: transistor, 55_4: transistor, T11: time, T12: time, T13: time, T14: time, T15: time, T16: time, T21: time, T22: time, T23: time, T24: time, 300: memory device, 21: memory array, 22: driver circuit, 62: PSW, 63: PSW, 71: peripheral circuit, 72: control circuit, 73: voltage generation circuit, 81: peripheral circuit, 82: row decoder, 83: row driver, 84: column decoder, 85: column driver, 87: input circuit, 88: output circuit, BW: signal, CE: signal, GW: signal, CLK: signal, WAKE: signal, ADDR: signal, WDA: signal, RDA: signal, PON1: signal, PON2: signal, VDD: potential, VHM: potential, GND: ground potential, Din: data, Dout: data, 90: electronic computer, 91: processor, 92: main memory, 93: core, 94: cache memory, 95: interface, S01: step, S02: step, S03: step, 10A: semiconductor device, 37A: switching circuit, C1: capacitor, C2: capacitor, BOOT1: signal, BOOT2: signal, 10B: semiconductor device, 37B: switching circuit, 51B: driver circuit, 56: precharge circuit, M5: transistor, M6: transistor, SW5: signal, SW6: signal, VPRE3: potential, 370A: memory device, 371: memory array portion, 372: memory portion, 373: word line driver portion, 374: column driver portion, 375: sense amplifier driver portion, 376: sensing circuit driver portion, 377: data sense amplifier portion, 378: memory controller portion, 370B: memory device, 373L: layer selection driver portion, 373Lbuf: layer selection driver, ML1: transistor, ML2: transistor, ML3: transistor, CL1: capacitor, BL1: node, LSEL: signal, LSELB: signal, VLD: potential, VLS: potential, WLin: word line, WLout: word line, TL1: time, TL2: time, 42a: memory cell, 42b: memory cell, 42c: memory cell, 42d: memory cell, 42e: memory cell, Ma: transistor, Mb: transistor, Mc: transistor, Ca: capacitor, FN: node, BGL: back gate line, WWL: word line, RWL: word line, WBL: bit line, RBL: bit line, 380: chip, 381: module, 382: region, 383: region, 384: region, 385: region, 386: region, 735: semiconductor device, 5626: semiconductor device, 5627: semiconductor device, 5628: semiconductor device, 1104: substrate, 1113: substrate, 1153: substrate, 5504: substrates, 200: transistor, 200a: transistor, 200b: transistor, 100: capacitor, 100a: capacitor, 100b: capacitor, 1200: chip, 720: memory device, 7003md: memory device

1. A semiconductor device comprising a first circuit, a second circuit, a third circuit, a fourth circuit, a first wiring, a second wiring, a third wiring, a fourth wiring, and a fifth wiring,
wherein the first circuit is electrically connected to the second circuit through the first wiring,
wherein the first circuit is electrically connected to the fourth circuit through each of the third wiring and the fourth wiring,
wherein the second circuit is electrically connected to the third circuit through the fifth wiring,
wherein the first circuit has a function of establishing or breaking electrical continuity among the first wiring, the second wiring, the third wiring, and the fourth wiring,
wherein the third circuit has a function of retaining a potential corresponding to first data,
wherein the second circuit has a function of supplying the potential corresponding to the first data from the first wiring to the fifth wiring, a function of retaining a potential corresponding to second data, and a function of amplifying a change in a potential of the fifth wiring and outputting the amplified change to the first wiring, and
wherein the fourth circuit has a function of outputting the potential corresponding to the first data or the second data in accordance with a potential difference between the third wiring and the fourth wiring.

2. The semiconductor device according to claim 1,
wherein the first circuit comprises a first transistor, a second transistor, a third transistor, a fourth transistor, and a fifth transistor,
wherein the first transistor has a function of establishing or breaking electrical continuity between the first wiring and the second wiring,
wherein the second transistor has a function of establishing or breaking electrical continuity between the first wiring and the third wiring,
wherein the third transistor has a function of establishing or breaking electrical continuity between the second wiring and the fourth wiring,
wherein the fourth transistor has a function of precharging the first wiring, and
wherein the fifth transistor has a function of precharging the second wiring.

3. The semiconductor device according to claim 1,
wherein the first circuit comprises a first transistor, a second transistor, a third transistor, a first capacitor, and a second capacitor,
wherein the first transistor has a function of establishing or breaking electrical continuity between the first wiring and the second wiring,
wherein the second transistor has a function of establishing or breaking electrical continuity between the first wiring and the third wiring,
wherein the third transistor has a function of establishing or breaking electrical continuity between the second wiring and the fourth wiring,
wherein the first capacitor has a function of changing a potential of the first wiring, and
wherein the second capacitor has a function of changing a potential of the second wiring.

4. The semiconductor device according to claim 1,
wherein the first circuit comprises a first transistor, a second transistor, and a third transistor,
wherein the first transistor has a function of establishing or breaking electrical continuity between the first wiring and the second wiring,
wherein the second transistor has a function of establishing or breaking electrical continuity between the first wiring and the third wiring,
wherein the third transistor has a function of establishing or breaking electrical continuity between the second wiring and the fourth wiring,
wherein the fourth circuit comprises a sixth transistor and a seventh transistor,
wherein the sixth transistor has a function of precharging the third wiring, and
wherein the seventh transistor has a function of precharging the fourth wiring.

5. The semiconductor device according to any one of claim 1 to claim 4,
wherein the fourth circuit is provided in a substrate,
wherein the first circuit and the second circuit are provided in a first layer placed over the substrate,
wherein the third circuit is provided in each of a plurality of second layers placed over the substrate,
wherein the substrate comprises a Si transistor, and
wherein each of the first layer and the plurality of second layers comprises an OS transistor.

6. A memory device comprising the semiconductor device according to claim 5 and a fifth circuit,
wherein the fifth circuit is provided in each of the plurality of second layers, and
wherein the fifth circuit has a function of outputting a signal that controls an operation of the third circuit.
